(19) United States
(12) Patent Application Publication
(10) Pub. No.: US 2024/0172461 A1
(43) Pub. Date: May 23, 2024

(54) LIGHT-EMITTING DEVICE, LIGHT-EMITTING APPARATUS, ELECTRONIC DEVICE, AND LIGHTING DEVICE

(71) Applicant: SEMICONDUCTOR ENERGY LABORATORY CO., LTD., Atsugi-shi (JP)

(72) Inventors: Harue OSAKA, Atsugi (JP); Satoshi SEO, Sagamihara (JP); Nobuharu OHSAWA, Zama (JP); Kazuki KAJIYAMA, Hadano (JP); Hiromitsu KIDO, Atsugi (JP)

(21) Appl. No.: 18/496,520

(22) Filed: Oct. 27, 2023

(30) Foreign Application Priority Data
Nov. 4, 2022 (JP) 2022-177394

(51) Int. Cl. H10K 50/11; C09K 11/06; H10K 85/60

(52) U.S. Cl. CPC H10K 50/11; C09K 11/06; H10K 85/6572; H10K 2101/10

(57) ABSTRACT

A highly efficient light-emitting device is provided. The light-emitting device includes a light-emitting layer between a first electrode and a second electrode. The light-emitting layer includes at least a light-emitting substance and a first substance, the half width of an emission spectrum of the light-emitting substance is 0.35 eV or less, the luminescence lifetime of delayed fluorescence caused by photoexcitation of the first substance is shorter at a first temperature than at a second temperature, the first temperature is lower than the second temperature, and the first temperature and the second temperature are each higher than or equal to 10 K and lower than or equal to 300 K.

### BACKGROUND OF THE INVENTION

### 1. Field of the Invention

One embodiment of the present invention relates to a light-emitting device, a light-emitting apparatus, an electronic device, and a lighting device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification and the like include a semiconductor device, a display apparatus, a liquid crystal display apparatus, a light-emitting apparatus, a lighting device, a power storage device, a memory device, an imaging device, a driving method thereof, and a manufacturing method thereof.

### 2. Description of the Related Art

A light-emitting device (also referred to as an organic EL element) including an organic compound that is a light-emitting substance between a pair of electrodes has characteristics such as being thin and light in weight, high-speed response, and low voltage driving. Thus, displays including such light-emitting devices have been developed. When a voltage is applied to this light-emitting device, electrons and holes injected from the electrodes recombine to put the light-emitting substance into an excited state. Light is emitted when the light-emitting substance returns to a ground state from the excited state. The excited state can be a singlet excited state (S*) and a triplet excited state (T*). Light emission from a singlet excited state is referred to as fluorescence, and light emission from a triplet excited state is referred to as phosphorescence. The formation ratio in the light-emitting device is considered to be S*:T*=1:3 according to the spin statistics.

As the above light-emitting substance, a compound capable of converting singlet excitation energy into light emission is called a fluorescent compound (fluorescent material), and a compound capable of converting triplet excitation energy into light emission is called a phosphorescent compound (phosphorescent material). In the phosphorescent material, intersystem crossing (energy transfer from a singlet excited state to a triplet excited state) easily occurs.

Accordingly, on the basis of the above formation ratio, the internal quantum efficiency (the ratio of the number of generated photons to the number of injected carriers) of a light-emitting device containing a fluorescent material is thought to have a theoretical limit of 25%, while the internal quantum efficiency of a light-emitting device containing a phosphorescent material is thought to have a theoretical limit of 100%.

That is, a highly efficient light-emitting device can be provided by using a phosphorescent material as a light-emitting substance. However, general phosphorescent materials are organometallic complexes containing a heavy atom of a noble metal such as iridium or platinum, and thus are costly unfortunately. Therefore, a method for using a light-emitting substance referred to as a thermally activated delayed fluorescence (TADF) material, which is a material that does not contain a heavy atom, has been considered in recent years. The TADF material can efficiently emit light by utilizing intersystem crossing from the triplet excited state to the singlet excited state; therefore, a highly efficient light-emitting device can be provided by using the TADF material.

Moreover, there is a report on a negative singlet-triplet energy gap material (hereinafter, referred to as a NEST material), which is considered to have inverted energy levels of singlet and triplet excited states (see Non-Patent Document 1). A general fluorescent material has a S₁ level higher than a T₁ level according to Hund's rules, while a NEST material has a feature of a lower S₁ level than a T₁ level. A light-emitting device including a NEST material as a light-emitting substance, which utilizes intersystem crossing from a triplet excited state to a singlet excited state, is a highly efficient light-emitting device, as compared with a general fluorescence light-emitting device (Non-Patent Document 2).

### REFERENCE

### Patent Document

[Patent Document 1] PCT International Publication No. WO2021/256446

### Non-Patent Document

[Non-Patent Document 1] Werner Leupin and Jakob Wirz, “Low-Lying Electronically Excited States of Cycl[3.3.3]azine, a Bridged 12π-Perimeter”, J. Am. Chem. Soc., V ol. 102, No. 19, pp. 6068-6075 (1980)
[Non-Patent Document 2] Naoya Aizawa et. al., “Delayed fluorescence from inverted singlet and triplet excited states”, Nature, vol. 609, pp. 502-506 (2022)
[Non-Patent Document 3] Nicholas J. Turro, V. Ramamurthy, J. C. Scaiano, “MODERN MOLECULAR PHOTOCHEMISTRY OF ORGANIC MOLECULES”, UNIVERSITY SCIENCE BOOKS, published on Feb. 10, 2010, pp. 204-208
[Non-Patent Document 4] Daisaku TANAKA et al., “Ultra High Efficiency Green Organic Light-Emitting Devices”, Japanese Journal of Applied Physics, Vol. 46, No. 1, 2007, pp. L10-L12

### SUMMARY OF THE INVENTION

However, the emission efficiency of the light-emitting device disclosed in Non-Patent Document 2 is lower than that of a general phosphorescent device. This is probably because the fluorescence quantum yield of the NEST material is not sufficiently increased.

In addition, the NEST material has a broad emission spectrum as compared with a condensed heteroaromatic compound containing nitrogen and boron that has a sharp emission spectrum, such as DABNA. In the case where the NEST material is used for displays, it is not so efficient for improvement of color purity and has insufficient characteristics.

In view of this, an object of one embodiment of the present invention is to provide a highly efficient light-emitting device. Another embodiment of the present invention is to provide a light-emitting device with high color purity.

Another object of one embodiment of the present invention is to provide a novel light-emitting device. Another object of one embodiment of the present invention is to provide a novel light-emitting apparatus. Another object of one embodiment of the present invention is to provide a novel electronic device. Another object of one embodiment of the present invention is to provide a novel lighting device.

Note that the description of the above objects does not preclude the existence of other objects. One embodiment of the present invention does not necessarily achieve all the objects listed above. Objects other than the above objects will be apparent from and can be derived from the description of the specification and the like.

One embodiment of the present invention is a light-emitting device including a light-emitting layer between a first electrode and a second electrode, in which the light-emitting layer includes at least a light-emitting substance and a first substance, a half width of an emission spectrum of the light-emitting substance is 0.35 eV or less, a luminescence lifetime of delayed fluorescence caused by photoexcitation of the first substance is shorter at a first temperature than at a second temperature, the first temperature is lower than the second temperature, and the first temperature and the second temperature are each higher than or equal to 10 K and lower than or equal to 300 K.

In the above light-emitting device, the half width of the emission spectrum of the light-emitting substance is preferably narrower than a half width of an emission spectrum of the first substance.

In the above light-emitting device, a luminescence quantum yield of the light-emitting substance is preferably higher than a luminescence quantum yield of the first substance.

In the above light-emitting device, the luminescence quantum yield of the light-emitting substance is preferably 60% or higher.

In the above light-emitting device, a Stokes shift of the light-emitting substance is preferably 0.35 eV or less.

In the above light-emitting device, the light-emitting substance preferably emits fluorescent light and an S₁ level of the first substance is preferably higher than an S₁ level of the light-emitting substance.

Another embodiment of the present invention is a light-emitting device including a light-emitting layer between a first electrode and a second electrode, in which the light-emitting layer includes at least a light-emitting substance and a first substance, the light-emitting substance emits phosphorescent light, a luminescence lifetime of delayed fluorescence caused by photoexcitation of the first substance is shorter at a first temperature than at a second temperature, the first temperature is lower than the second temperature, and the first temperature and the second temperature are each higher than or equal to 10 K and lower than or equal to 300 K.

In the above light-emitting device, a T₁ level of the first substance is preferably higher than a T₁ level of the light-emitting substance.

In the above light-emitting device, an S₁ level of the first substance is preferably higher than or equal to a T₁ level of the light-emitting substance.

Another embodiment of the present invention is a light-emitting device including a light-emitting layer between a first electrode and a second electrode, in which the light-emitting layer includes at least a light-emitting substance, a first substance, and a second substance, the light-emitting substance emits phosphorescent light, a luminescence lifetime of delayed fluorescence caused by photoexcitation of the first substance at a first temperature is shorter than at a second temperature, the first temperature is lower than the second temperature, and the first temperature and the second temperature are each higher than or equal to 10 K and lower than or equal to 300 K.

In the above light-emitting device, T₁ levels of the first substance and the second substance are preferably higher than a T₁ level of the light-emitting substance.

In the above light-emitting devices, a molar absorption coefficient of a maximum peak wavelength of a longest-wavelength absorption band of the light-emitting substance is preferably 1000 M⁻¹·cm⁻¹ or higher.

Another embodiment of the present invention is a light-emitting device including a light-emitting layer between a first electrode and a second electrode, in which the light-emitting layer includes at least a light-emitting substance, a first substance, a second substance, and a third substance, a luminescence lifetime of delayed fluorescence caused by photoexcitation of the first substance becomes shorter as a temperature decreases in a range of 10 K to 300 K, inclusive, and the second substance and the third substance form an exciplex.

In the above light-emitting device, a difference between a maximum peak wavelength energy of an emission spectrum of the exciplex and a wavelength energy at an absorption edge of an absorption spectrum of the first substance is preferably less than or equal to 0.20 eV.

In the above light-emitting device, a difference between a maximum peak wavelength energy of an emission spectrum of the exciplex and a maximum peak wavelength energy of a longest-wavelength absorption band of an absorption spectrum of the first substance is preferably less than or equal to 0.20 eV.

In the above light-emitting device, the luminescence lifetimes of the second substance, the third substance, and the exciplex are preferably longer than that of the first substance, and the luminescence lifetime of the first substance is preferably longer than that of the light-emitting substance.

In the above light-emitting device, an S₁ level of the exciplex is higher than an S₁ level or a T₁ level of the first substance.

In the above light-emitting devices, the first substance is preferably an organic compound having an azaphenalene ring. In the above light-emitting device, the second substance is preferably a substance having a high hole-transport property.

In the above light-emitting device, the azaphenalene ring is preferably any one of a pyridoquinolizine ring, a pyrimidoquilolizine ring, a triazaphenalene ring, a tetraazaphenalene ring, a pentaazaphenalene ring, a hexaazaphenalene ring, and a heptaazaphenalene ring.

In the above light-emitting device, the heptaazaphenalene ring is preferably a 1,3,4,6,7,9,9b-heptaazaphenalene ring.

In the above light-emitting devices, the first substance is preferably an organic compound represented by General Formula (G1).

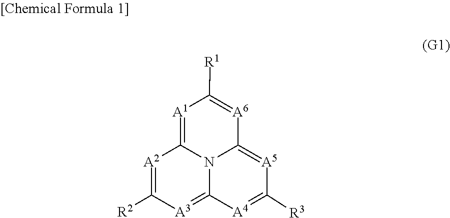

In General Formula (G1), A¹ to A⁶ each independently represent carbon or nitrogen, and A¹ to A⁶ each independently representing carbon are each independently bonded to any one of hydrogen (including deuterium), halogen, an alkyl group having 1 to 10 carbon atoms, a cycloalkyl group having 6 to 10 carbon atoms, a haloalkyl group having 1 to 10 carbon atoms, an alkoxy group having 1 to 10 carbon atoms, a haloalkoxy group having 1 to 10 carbon atoms, and a substituted or unsubstituted aryl group having 6 to 13 carbon atoms. R¹ to R³ each independently represent any one of hydrogen (including deuterium), halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 14 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group.

In the above light-emitting devices, the first substance is preferably an organic compound represented by General Formula (G2).

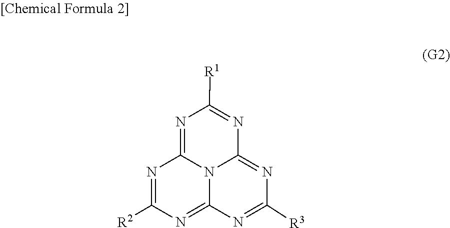

In General Formula (G2), R¹ to R³ each independently represent any one of hydrogen (including deuterium), halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 11 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group.

In the above light-emitting devices, the first substance is preferably an organic compound represented by General Formula (G3).

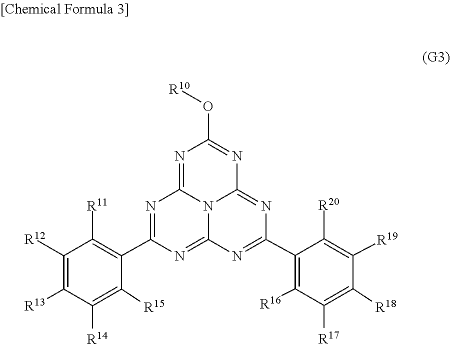

In General Formula (G3), R¹⁰ represents an alkyl group having 1 to 10 carbon atoms or a haloalkyl group having 1 to 10 carbon atoms, and R¹¹ to R²⁰ each independently represent any one of hydrogen (including deuterium), halogen, an alkyl group having 1 to 10 carbon atoms, a haloalkyl group having 1 to 10 carbon atoms, an alkoxy group having 1 to 10 carbon atoms, and a haloalkoxy group having 1 to 10 carbon atoms.

Another embodiment of the present invention is a light-emitting apparatus including the above light-emitting device, and a transistor or a substrate.

Another embodiment of the present invention is an electronic device including the above light-emitting apparatus and at least one of a detection unit, an input unit, and a communication unit.

Another embodiment of the present invention is a lighting device including the above light-emitting apparatus and a housing.

One embodiment of the present invention can provide a highly efficient light-emitting device. Another embodiment can provide a light-emitting device with high color purity.

Another embodiment of the present invention can provide a novel light-emitting device. Another embodiment of the present invention can provide a novel light-emitting apparatus. Another embodiment of the present invention can provide a novel electronic device. Another embodiment of the present invention can provide a novel lighting device.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIG. 1 illustrates a structure of a light-emitting device of an embodiment;

FIGS. 2A to 2E each illustrate a structure of a light-emitting device of an embodiment;

FIGS. 3A to 3D each illustrate a light-emitting apparatus of an embodiment;

FIGS. 4A to 4C illustrate a fabrication method of a light-emitting apparatus of an embodiment;

FIGS. 5A to 5C illustrate a fabrication method of a light-emitting apparatus of an embodiment;

FIGS. 6A to 6D illustrate a fabrication method of a light-emitting apparatus of an embodiment;

FIGS. 7A to 7C illustrate a light-emitting apparatus of an embodiment;

FIGS. 8A to 8F illustrate a light-emitting apparatus of an embodiment;

FIGS. 9A and 9B illustrate a light-emitting apparatus of an embodiment;

FIGS. 10A to 10E illustrate electronic devices of an embodiment;

FIGS. 11A to 11E illustrate electronic devices of an embodiment;

FIGS. 12A and 12B illustrate electronic devices of an embodiment;

FIGS. 13A and 13B illustrate a lighting device of an embodiment;

FIG. 14 illustrates lighting devices of an embodiment;

FIG. 15 shows luminance-current density characteristics of light-emitting devices 1 to 3 and a comparative light-emitting device 4;

FIG. 16 shows luminance-voltage characteristics of the light-emitting devices 1 to 3 and the comparative light-emitting device 4;

FIG. 17 shows current efficiency-luminance characteristics of the light-emitting devices 1 to 3 and the comparative light-emitting device 4;

FIG. 18 shows current density-voltage characteristics of the light-emitting devices 1 to 3 and the comparative light-emitting device 4;

FIG. 19 is a graph showing power efficiency-luminance characteristics of the light-emitting devices 1 to 3 and the comparative light-emitting device 4;

FIG. 20 shows external quantum efficiency (EQE)-luminance characteristics of the light-emitting devices 1 to 3 and the comparative light-emitting device 4;

FIG. 21 shows electroluminescence spectra of the light-emitting devices 1 to 3 and the comparative light-emitting device 4;

FIG. 22 shows an absorption spectrum of 4CzIPN in a solution;

FIG. 23 shows an absorption spectrum of CzDBA in a solution;

FIGS. 24A and 24B show an absorption spectrum and an emission spectrum, respectively, of CzDBA in a film state;

FIGS. 25A and 25B shows an absorption spectrum and an emission spectrum, respectively of Ir(tBumpypm)₂(acac) in a solution;

FIG. 26 shows a phosphorescent spectrum of PPO27 in a thin film;

FIG. 27 shows an absorption spectrum and an emission spectrum of HzTFEX₂;

FIG. 28 shows luminance-current density characteristics of a light-emitting device 5 and comparative light-emitting devices 6 and 7;

FIG. 29 shows luminance-voltage characteristics of the light-emitting device 5 and the comparative light-emitting devices 6 and 7;

FIG. 30 shows current efficiency-luminance characteristics of the light-emitting device 5 and the comparative light-emitting devices 6 and 7;

FIG. 31 shows current density-voltage characteristics of the light-emitting device 5 and the comparative light-emitting devices 6 and 7;

FIG. 32 is a graph showing power efficiency-luminance characteristics of the light-emitting device 5 and the comparative light-emitting devices 6 and 7;

FIG. 33 shows external quantum efficiency-luminance characteristics of the light-emitting device 5 and the comparative light-emitting devices 6 and 7;

FIG. 34 shows electroluminescence spectra of the light-emitting device 5 and the comparative light-emitting devices 6 and 7; and

FIGS. 35A and 35B show an absorption spectrum of CzDBA in a solution and an emission spectrum of 3,10tBu-ch3P2Qd in a solution.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those used to specify one embodiment of the present invention.

In the description of structures of the present invention in this specification and the like with reference to the drawings, the same components in different drawings are denoted by the same reference numeral in some cases.

In this specification and the like, the terms “film” and “layer” can be interchanged with each other. For example, the term “conductive layer” can be changed to the term “conductive film” in some cases. For another example, the term “insulating film” can be changed into the term “insulating layer” in some cases.

In this specification and the like, a singlet excited state (S*) refers to a singlet state having excitation energy. An S₁ level means the lowest level of the singlet excitation energy level, that is, the excitation energy level of the lowest singlet excited state. A triplet excited state (T*) refers to a triplet state having excitation energy. A T₁ level means the lowest level of the triplet excitation energy level, that is, the excitation energy level of the lowest triplet excited state.

In this specification and the like, a fluorescent material or a fluorescent compound refers to a material or a compound that emits light during the relaxation from the singlet excited state to the ground state. A phosphorescent material or a phosphorescent compound refers to a material or a compound that emits light in the visible light region at room temperature during the relaxation from the triplet excited state to the ground state. That is, a phosphorescent material or a phosphorescent compound refers to a material or a compound that can convert triplet excitation energy into visible light.

When the v=0→v=0 transition (0→0 band) between vibrational levels of the ground state and the excited state is clearly observed from a fluorescent spectrum or a phosphorescent spectrum, the S₁ level or the T₁ level of an organic compound is preferably calculated using the 0→0 band (see Non-Patent Document 3, for example). When the 0→0 band is unclear, the S₁ level can be energy of the intersection of the horizontal axis (wavelength) or the base line and a tangent to the fluorescent spectrum at a point where the slope of the spectrum at a peak on the shorter wavelength side has a maximum value, and the T₁ level can be energy of the intersection of the horizontal axis (wavelength) or the base line and a tangent to the phosphorescent spectrum at a point where the slope of the spectrum at a peak on the shorter wavelength side has a maximum value (see Non-Patent Document 4, for example). In the case where the levels are compared with each other, those calculated by the same method are used.

Note that in this specification and the like, “room temperature” refers to a temperature in the range of 0° C. to 40° C.

In this specification and the like, a blue wavelength range refers to a wavelength range of greater than or equal to 400 nm and less than 490 nm, and blue light emission has at least one emission spectrum peak in that range. A green wavelength range refers to a wavelength range of greater than or equal to 490 nm and less than 580 nm, and green light emission has at least one emission spectrum peak in that range. A red wavelength range refers to a wavelength range of greater than or equal to 580 nm and less than or equal to 680 nm, and red light emission has at least one emission spectrum peak in that range. A near infrared light wavelength range refers to a wavelength range of greater than or equal to 700 nm and less than or equal to 2500 nm, and near infrared light emission has at least one emission spectrum peak in that range.

In this specification and the like, when an aromatic ring (including a heteroaromatic ring) A is described, the description of the aromatic ring A can be applied to a condensed aromatic ring generated by condensation of the aromatic ring A and another aromatic ring or a heteroaromatic ring, unless otherwise specified. For example, in the case where an organic compound having a carbazole ring is described, the description of the organic compound having a carbazole ring can be applied to an organic compound having a condensed aromatic ring such as a benzocarbazole ring or a dibenzocarbazole ring, which is generated by condensation of a carbazole ring and a benzene ring, unless otherwise specified.

The values of HOMO and LUMO levels used in this specification can be obtained by electrochemical measurement. Typical examples of the electrochemical measurement include cyclic voltammetry (CV) measurement and differential pulse voltammetry (DPV) measurement.

In this specification and the like, a delayed fluorescence lifetime of an organic compound can be measured with a fluorescence (luminescence) life measurement apparatus.

In this specification and the like, intersystem crossing refers to a nonradiative transition between the states with different spin multiplicity.

The half width used in this specification refers to a full width at half maximum (FWHM) of a spectrum.

### Embodiment 1

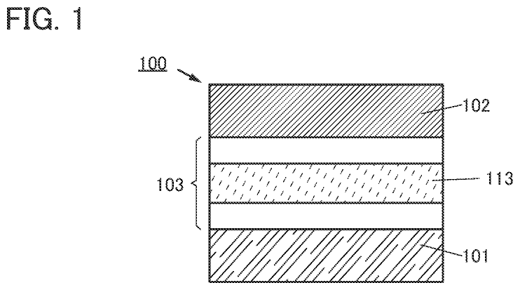

In this embodiment, a light-emitting device of one embodiment of the present invention will be described with reference to FIG. 1.

First, a structure of the light-emitting device of one embodiment of the present invention will be described with reference to FIG. 1. FIG. 1 is a schematic cross-sectional view illustrating a light-emitting device 100, which is an example of the light-emitting device of one embodiment of the present invention.

The light-emitting device 100 includes a pair of electrodes (a first electrode 101 and a second electrode 102) and an EL layer 103 between the pair of electrodes. The EL layer 103 includes at least a light-emitting layer 113.

Next, the structure of the light-emitting layer 113 is described.

The light-emitting layer 113 contains at least a first substance and a light-emitting substance.

It is preferable to use a material in which the T₁ level is higher than the S₁ level as the first substance. Here, in general light-emitting substances, the S₁ level is known to be higher than the T₁ level. In addition, an energy difference between the S₁ level and the T₁ level (i.e., a value obtained by subtracting the T₁ level from the S₁ level) is referred to as ΔE_{ST}. Therefore, a material having a T₁ level higher than an S₁ level is referred to as a negative singlet-triplet energy gap material (a negative ΔE_{ST} or NEST material).

In general fluorescent light-emitting devices, T* excitation energy cannot contribute to light emission, which means that 75% of all excitons is lost. In contrast, in a NEST material having a T₁ level higher than an S₁ level, intersystem crossing from T* to S* easily occurs. Therefore, the T* excitation energy can be extracted as delayed fluorescence, and thus 100% maximum of all excitons can be probably extracted. Therefore, devices using a NEST material can have higher external quantum efficiency than general fluorescent light-emitting devices.

Note that the TADF material is a material in which intersystem crossing from T* to S* (also referred to as upconversion or reverse intersystem crossing) can occur with a slight amount of thermal energy, and luminescence (fluorescence) from S* can be exhibited efficiently. Luminescence from the TADF material contains two fluorescent components, initial fluorescence from S* and delayed fluorescence from S* caused by intersystem crossing from T* to S*. In the TADF material, the S₁ level and the T₁ level are close to each other (in other words, ΔE_{ST} is small), and the S₁ level is slightly higher than the T₁ level. Therefore, the intersystem crossing from T* to S* occurs in an endothermic process in the TADF material, which is a characteristic of the TADF material.

The NEST material is similar to the TADF material in that the intersystem crossing from T* to S* can occur and luminescence (fluorescence) from S* is exhibited efficiently. Similarly, luminescence form the NEST material contains two fluorescent components, initial fluorescence from S* and delayed fluorescence from S* caused by intersystem crossing from T* to S*. However, the T₁ level is higher than the S₁ level in the NEST material. Thus, the intersystem crossing from T* to S* occurs in an exothermic process in the NEST material. Accordingly, the speed of the intersystem crossing from T* to S* is higher than that of the intersystem crossing from S* to T*.

This means that the delayed fluorescence lifetime of the NEST material becomes shorter as the temperature decreases. More specifically, it can be said that the lifetime of delayed fluorescence caused by photoexcitation in the NEST material becomes shorter as the temperature decreases in the range of 10 K to 300 K, inclusive. In other words, in the case where the first temperature is lower than the second temperature and the first and second temperatures are in the range of 10 K to 300 K, inclusive, the delayed fluorescence lifetime at the first temperature is shorter than that at the second temperature in the NEST material.

If oxygen is present in the light-emitting layer in a general light-emitting device, the intersystem crossing from S* to T* might be promoted in a host material to cause quenching, resulting in a decrease in emission efficiency in some cases. This can be estimated from the shortened luminescence lifetime of the host material in the presence of oxygen. However, as described above, since the T₁ level is higher than the S₁ level in the NEST material, the speed of the intersystem crossing from T* to S* is higher than that of the intersystem crossing from S* to T*. Therefore, even in the presence of oxygen, quenching due to the intersystem crossing from S* to T* is difficult to occur in the NEST material, so that the luminescence lifetime is less likely to be shortened. Thus, a light-emitting device including the NEST material is preferable in that the emission efficiency is less likely to be decreased even in the presence of oxygen in a light-emitting layer.

Note that a smaller absolute value of the difference between the S₁ level and the T₁ level of the NEST material, that is, a smaller |ΔE_{ST}|, is preferable because the intersystem crossing from T* to S* occurs with higher efficiency (at higher speed). Therefore, the |ΔE_{ST}| of the light-emitting substance is preferably greater than or equal to 0 eV and less than or equal to 0.1 eV, further preferably greater than or equal to 0 eV and less than or equal to 0.05 eV. Note that the S₁ level and the T₁ level of the |ΔE_{ST}| can be estimated from the temperature dependence of luminescence lifetime (Patent Document 1).

The S₁ level can be estimated from a wavelength of an absorption edge that is the intersection of the base line and a tangent at a point at which the negative slope of the spectrum has a maximum absolute value on the long wavelength side of the longest-wavelength peak or shoulder peak of the absorption spectrum. Alternatively, the S₁ level can also be estimated from a wavelength of an emission edge that is the intersection of the base line and a tangent at a point at which the slope of the spectrum has a maximum value on the short wavelength side of the shortest-wavelength peak or shoulder peak of a fluorescent spectrum. Furthermore, the T₁ level can also be estimated from a wavelength of an emission edge that is the intersection of the base line and a tangent at a point at which the slope of the spectrum has a maximum value on the short wavelength side of the shortest-wavelength peak or shoulder peak of a phosphorescent spectrum. Alternatively, the T₁ level may also be estimated from the S₁ level estimated from a rise on the short wavelength side of the fluorescent spectrum and ΔE_{ST}. When the spectrum contains noise, smoothed or fitted data may be used for the calculation.

When the NEST material is used as the first material, triplet excited state energy generated in the NEST material is converted into singlet excitation energy by intersystem crossing from T* to S* and transferred to the light-emitting substance, whereby the emission efficiency of the light-emitting device can be increased. Here, the NEST material functions as an energy donor, and the light-emitting substance functions as an energy acceptor. Therefore, the use of the NEST material as the first material is effective in the case where a fluorescent substance is used as the guest material. In that case, the S₁ level of the NEST material is preferably higher than that of the fluorescent substance in order that high emission efficiency be achieved. Furthermore, the T₁ level of the NEST material is preferably higher than the S₁ level of the fluorescent substance. Therefore, the T₁ level of the NEST material is preferably higher than the T₁ level of the fluorescent substance.

As the light-emitting substance, a light-emitting substance with a narrow half width of an emission spectrum is preferably used. Thus, alight-emitting device capable of efficiently emitting light with a desired wavelength can be provided. Note that although a microcavity structure is generally used for the purpose of increasing the color purity of alight-emitting device in some cases, a large half width of the emission spectrum of the light-emitting substance leads to a large loss of light due to attenuation. In view of the above, a light-emitting substance having a narrow half width of an emission spectrum is used, whereby light is less likely to be lost due to attenuation and can be amplified efficiently even in a light-emitting device employing a microcavity structure. Moreover, the use of a light-emitting substance having a narrow half width of an emission spectrum can reduce the loss of light due to cutting off of a wavelength by a color filter. Thus, the light-emitting layer 113 is suitable for a light-emitting device employing a microcavity structure. Specifically, a light-emitting substance whose half width of the emission spectrum is 0.35 eV or lower, preferably 0.30 eV or lower, further preferably 0.25 eV or lower can be used. In other words, for example, in a blue emission region, the half width of an emission spectrum is preferably 70 nm or less, further preferably 35 nm or less. In a green emission region, the half width of an emission spectrum is preferably 100 nm or less, further preferably 50 nm or less. In a red emission region, the half width of an emission spectrum is preferably 150 nm or less, further preferably 75 nm or less. In a near infrared light emission region of approximately 1000 nm, the half width of an emission spectrum is preferably 400 nm or less, further preferably 200 nm or less.

In addition, the half width of the emission spectrum of the light-emitting substance is further preferably narrower than the half width of the emission spectrum of the first substance. Accordingly, it is possible to provide a high color-purity light-emitting device that can emit light with an intended wavelength efficiently even when the half width of the emission spectrum of the first substance is large.

In addition, the luminescence quantum yield (fluorescence quantum yield in the case of a fluorescent light-emitting device and phosphorescence quantum yield in the case of a phosphorescent light-emitting device) of the light-emitting substance is preferably higher than that of the first substance. Thus, the light-emitting device can emit light efficiently. Specifically, the luminescence quantum yield of the light-emitting substance is preferably higher than or equal to 60%, further preferably higher than or equal to 70%, still further preferably higher than or equal to 80%. In addition, when the luminescence quantum yield of the light-emitting substance is lower than that of the first substance, the half width of the emission spectrum of the light-emitting substance is preferably narrower than that of the first substance, which can suppress a decrease in the emission efficiency of the light-emitting device.

Moreover, a small Stokes shift of the light-emitting substance is preferred. The Stokes shift can be small in the case where the structure change of the light-emitting substance before and after a transition is small. Accordingly, the half width of the emission spectrum can be narrowed. Specifically, the Stokes shift of the light-emitting substance is preferably less than or equal to 0.35 eV, further preferably less than or equal to 0.30 eV, still further preferably less than or equal to 0.25 eV.

Note that in the case where a light-emitting substance emitting phosphorescent light is used as the light-emitting substance, the T₁ level of the first substance is preferably higher than the T₁ level of the light-emitting substance. The S₁ level of the first substance is further preferably higher than the T₁ level of the light-emitting substance. Accordingly, the triplet excitation energy of the first substance can be efficiently transferred to the light-emitting substance, so that the light-emitting substance can emit light.

The light-emitting layer 113 may further include a second substance. That is, the light-emitting layer 113 may include the first substance, the second substance, and the light-emitting substance.

In the case of using a light-emitting substance emitting phosphorescent light as a light-emitting substance, the T₁ level of the first substance and the T₁ level of the second substance are preferably higher than the T₁ level of the light-emitting substance. The S₁ level of the first substance and the S₁ level of the second substance are each preferably higher than that of the light-emitting substance. Accordingly, the triplet excitation energy of each of the first substance and the second substance can be transferred to the light-emitting substance efficiently, and the light-emitting substance can emit light. Note that the T₁ level in this case can be estimated from a rise at a short wavelength side of a phosphorescent spectrum.

Note that it is preferable that an exciplex not be formed between the first substance and the second substance, in which case the T₁ excitation energy of the NEST material is transferred to the light-emitting substance efficiently, through efficient intersystem crossing to the S₁ level.

Note that the exciplex has an extremely small difference between the S₁ level and T₁ level, and can serve as a TADF material in which intersystem crossing from T* to S* can occur with a slight amount of thermal energy. In alight-emitting device utilizing an exciplex, the excited state can be formed with lower energy and thus the driving voltage of the light-emitting device can be reduced.

In the case where a light-emitting substance emitting phosphorescent light is used as a light-emitting substance and an exciplex is formed between the first substance and the second substance, the excitation energy of the exciplex is preferably designed to be higher than that of the light-emitting substance, so that a highly efficient device can be obtained.

In the case where a light-emitting substance emitting fluorescent light is used as a light-emitting substance and an exciplex is formed between the first substance and the second substance, the T₁ energy of the exciplex is transferred to the T₁ level of the light-emitting substance through Dexter energy transfer, leading to deactivation unfortunately. In that case, a substituent is preferably introduced into a light-emitting substance, a peripheral material, or the like so that a luminophore of the light-emitting substance can be apart from a luminophore (an element with T₁ spins) of the exciplex (the first and second substances) with a distance of approximately 10 nm or more. Considering a carrier-transport property, it is preferable to introduce a substituent to the light-emitting substance side in such a manner. As examples of the substituent, a substituent having a low carrier-transport property, such as an alkyl group such as a tert-butyl group or a cycloalkyl group such as a cyclohexyl group, can be given. Accordingly, the T₁ energy of the exciplex can be inhibited from being transferred to the T₁ level of the light-emitting substance through Dexter energy transfer and being deactivated.

The second substance is preferably a substance having a high carrier-transport property and is preferably any one of a substance having a high hole-transport property, a substance having a high electron-transport property, and a substance with a bipolar property (a substance having a high electron-transport property and a high hole-transport property).

Note that in the case where the first substance is a substance having a high hole-transport property, it is preferable to use a substance having a high electron-transport property as the second substance. Alternatively, when the second substance is a substance having a high electron-transport property, it is preferable to use a substance having a high hole-transport property as the second substance. Thus, a device having an excellent carrier balance can be obtained.

In addition, the molar absorption coefficient at the maximum peak wavelength of the longest-wavelength absorption band of the light-emitting substance is preferably greater than or equal to 500 M⁻¹·cm⁻¹, further preferably greater than or equal to 1000 M⁻¹·cm⁻¹. As a result, excitation energy is efficiently transferred from the first and second substances to the light-emitting substance, so that a highly efficient light-emitting device can be provided.

Note that the light-emitting layer 113 may further include a third substance. That is, the light-emitting layer 113 may include the first substance, the second substance, the third substance, and the light-emitting substance.

The third substance is preferably a substance having a high carrier-transport property, like the second substance. The mixing ratio of the second substance and the third substance in the light-emitting layer 113 can be adjusted to regulate the carrier balance of the light-emitting layer 113. Note that in the case where the second substance is a substance having a high hole-transport property, the third substance is preferably a substance having a high electron-transport property. In the case where the second substance is a substance having a high electron-transport property, the third substance preferably has a high hole-transport property.

In addition, an exciplex may be formed between the second substance and the third substance. The T₁ level of the third substance and the S₁ level of the exciplex formed between the second substance and the third substance are each preferably designed to be higher than the S₁ level of the NEST material as the first substance, in which case energy transfer efficiency is high and thus a highly efficient light-emitting device can be obtained.

Note that in general, the T₁ level of the exciplex cannot be observed. However, in the case where the T₁ level of the second substance and the T₁ level of the third substance are each higher than the T₁ level of the first substance as described above, the T₁ level of the second substance and the T₁ level of the third substance may be equivalent to or exceed the T₁ level of the exciplex, only in which case the T₁ level of the exciplex may be observed as a phosphorescent spectrum. It is acceptable that the T₁ level of the exciplex is higher or lower than the T₁ level of the first substance. This is because the T₁ energy of the exciplex can be transferred to the S₁ level of the first substance through the S₁ level of the exciplex by intersystem crossing.

In this case, the proportions of the light-emitting substance and the first substance in the light-emitting layer 113 are each preferably less than or equal to 15 wt %. This can suppress concentration quenching. In addition, the total amount of the second substance and the third substance is preferably 60 wt % or higher. This makes favorable carrier balance. In other words, the second substance and the third substance each serve as a carrier-transport host and the first substance serves as an energy donor of the light-emitting substance in this case. For example, in the case where analysis by high performance liquid chromatography (LC) is performed, the proportion of the maximum adsorption intensity ratio in the range of 190 nm to 800 nm of each of the light-emitting substance and the first substance in the light-emitting layer 113 is preferably 15% or less and the proportion of the maximum adsorption intensity ratio in the range of 190 nm to 800 nm of the total amount of the second substance and the third substance in the light-emitting layer 113 is preferably 60% or more.

In the above light-emitting device, the luminescence lifetimes of the second substance, the third substance, and the exciplex are preferably longer than that of the first substance, and the luminescence lifetime of the first substance is preferably longer than that of the light-emitting substance, which can enhance the transfer efficiency of excitation energy.

The formation of an exciplex can be confirmed, for example, in the following manners: when the emission spectra of the first substance, the second substance, and a mixed film of the first and second substances are compared, it is observed that the emission spectrum of the mixed film is shifted to the longer wavelength than the emission spectrum of each of the first substance and the second substance (or has another peak on the longer wavelength side). In addition, when the transient photoluminescence (PL) of the first substance, the second substance, and the mixed film of the first and second substances are compared, a difference in transient response is observed, for example, the transient PL lifetime of the mixed film has a longer lifetime component or has a delayed component at a higher proportion than that of each of the first substance and the second substance. The transient PL can be rephrased as transient electroluminescence (EL). That is, the formation of an exciplex can also be confirmed by comparing the transient EL of the first substance, the second substance, and the mixed film of the first and second substances and observing a difference in transient response.

Furthermore, it is preferable that the emission spectrum (the fluorescent spectrum in the case where energy transfer from a singlet excited state is discussed) of the exciplex largely overlap with the absorption spectrum (absorption corresponding to the transition from the singlet ground state to the triplet excited state) of the first substance. Specifically, an overlap of the emission spectrum of the exciplex with the longest-wavelength absorption band of the first substance is further preferably large. Moreover, the molar absorption coefficient of the first substance is preferably high. Specifically, the molar absorption coefficient at the maximum peak wavelength of the longest-wavelength absorption band of the first substance is preferably greater than or equal to 500 M⁻¹·cm⁻¹, further preferably greater than or equal to 1000 M⁻¹·cm⁻¹. As a result, excitation energy is efficiently transferred from the exciplex to the first substance, so that a highly efficient light-emitting device can be provided.

Note that the difference between energy at the maximum peak wavelength of the emission spectrum of the exciplex and energy at the absorption edge wavelength of the absorption spectrum of the first substance is preferably less than or equal to 0.20 eV. For example, in the case of a blue emission region, the difference between energy at the maximum peak wavelength of the emission spectrum of the exciplex and energy at the absorption edge wavelength of the absorption spectrum of the first substance is preferably less than or equal to 40 nm, further preferably less than or equal to 20 nm; in the case of a green emission region, the difference between energy at the maximum peak wavelength of the emission spectrum of the exciplex and energy at the absorption edge wavelength of the absorption spectrum of the first substance is preferably less than or equal to 50 nm, further preferably less than or equal to 25 nm; in the case of a red emission region, the difference between energy at the maximum peak wavelength of the emission spectrum of the exciplex and energy at the absorption edge wavelength of the absorption spectrum of the first substance is preferably less than or equal to 70 nm, further preferably less than or equal to 35 nm; and in the case of a near infrared light emission region of approximately 1000 nm, the difference between energy at the maximum peak wavelength of the emission spectrum of the exciplex and energy at the absorption edge wavelength of the absorption spectrum of the first substance is preferably less than or equal to 150 nm, further preferably less than or equal to 75 nm. With such a structure, the S₁ level and the T₁ level of the exciplex are close to the S₁ level and the T₁ level of the first substance, whereby energy loss in energy transfer from the exciplex to the light-emitting substance can be suppressed.

Note that the absorption edge of the absorption spectrum can be obtained from an onset (intersection of a tangent at a point where the gradient of a curve has a maximum value (inflection point) and an extended line of a base line) on the long wavelength side.

Note that the difference between energy at the maximum peak wavelength of the emission spectrum of the exciplex and energy at the maximum peak wavelength of the longest-wavelength absorption band of the absorption spectrum of the first substance is preferably less than or equal to 0.20 eV. For example, in the case of a blue emission region, the difference between energy at the maximum peak wavelength of the emission spectrum of the exciplex and energy at the maximum peak wavelength of the longest-wavelength absorption band of the absorption spectrum of the first substance is preferably less than or equal to 40 nm, further preferably less than or equal to 20 nm; in the case of a green emission region, the difference between energy at the maximum peak wavelength of the emission spectrum of the exciplex and energy at the maximum peak wavelength of the longest-wavelength absorption band of the absorption spectrum of the first substance is preferably less than or equal to 50 nm, further preferably less than or equal to 25 nm; and in the case of a red emission region, the difference between energy at the maximum peak wavelength of the emission spectrum of the exciplex and energy at the maximum peak wavelength of the longest-wavelength absorption band of the absorption spectrum of the first substance is preferably less than or equal to 70 nm, further preferably less than or equal to 35 nm; and in the case of a near infrared light emission region of approximately 1000 nm, the difference between energy at the maximum peak wavelength of the emission spectrum of the exciplex and energy at the maximum peak wavelength of the longest-wavelength absorption band of the absorption spectrum of the first substance is preferably less than or equal to 150 nm, further preferably less than or equal to 75 nm. With such a structure, the S₁ level and the T₁ level of the exciplex are close to the S₁ level and the T₁ level of the first substance, whereby energy loss in energy transfer from the exciplex to the first substance can be suppressed.

Next, specific examples of the light-emitting substance, the first substance, the second substance, and the third substance are described.

### <Specific Example of Light-Emitting Substance>

Although there is no particular limitation on the structure of the light-emitting substance, a material having a narrow half width of an emission spectrum is preferably used. For example, a condensed heteroaromatic compound containing nitrogen and boron, especially, an organic compound having a diaza-boranaphto-anthracene ring or an organic compound having a naphtho benzofuran ring can be suitably used. Such organic compounds have a narrow half width of a fluorescent spectrum and can emit blue light with high color purity; thus, the organic compounds are preferable.

Specific examples of the organic compound having a diaza-boranaphto-anthracene ring include 5,9-diphenyl-5,9-diaza-13b-boranaphtho[3,2,1-de]anthracene (abbreviation: DABNA1), 9-([1,1′-diphenyl]-3-yl)-N,N,5,11-tetraphenyl-5,9-dihydro-5,9-diaza-13b-boranaphtho[3,2,1-de]anthracene-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′: 4,5][1,4]benzazaborino[3,2-b]phenazaborin-7,13-diamine (abbreviation: v-DABNA), and 2-(4-tert-butylphenyl)benz[5,6]indolo[3,2,1-jk]benzo[b]carbazole (abbreviation: tBuPBibc).

Specific examples of the organic compound having a naphtho benzofuran ring include 3,10-bis[N-(dibenzofuran-3-yl)-N-phenylamino]naphtho[2,3-b;6,7-b′]bisbenzofuran (abbreviation: 3,10FrA2Nbf(IV)-02) and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02).

Examples of a material which can be used as the fluorescent substance are the following materials. Other fluorescent substances can also be used.

Examples of the fluorescent substance include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPm), N,N′-bis(3-methylphenyl)-N,N′-bis[3-(9-phenyl-9H-fluoren-9-yl)phenyl]-pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N″′,N″′-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N, 9-triphenylanthracen-9-amine (abbreviation: DPhAPhA), coumarin 545T, N,N′-diphenylquinacridone (abbreviation: DPQd), 3,10-di-tert-butyl-5,12-bis(2,4,6-tricyclohexylphenyl)-5,12-dihydroquino[2,3-b]acridine-7,14-dione (abbreviation: 3,10tBu-ch3P2Qd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and N,N′-diphenyl-N,N′-(1,6-pyrene-diyl)bis[(6-phenylbenzo[b]naphtho[1,2-d]furan)-8-amine] (abbreviation: 1,6BnfAPrn-03). Fused aromatic diamine compounds typified by pyrenediamine compounds such as 1,6FLPAPm, 1,6mMemFLPAPm, and 1,6BnfAPm-03 are particularly preferable because of their high hole-trapping properties, high emission efficiency, or high reliability.

A TADF material can be used as the light-emitting substance, and examples of the TADF material include a fullerene, a derivative thereof, an acridine, a derivative thereof, and an eosin derivative. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulas.

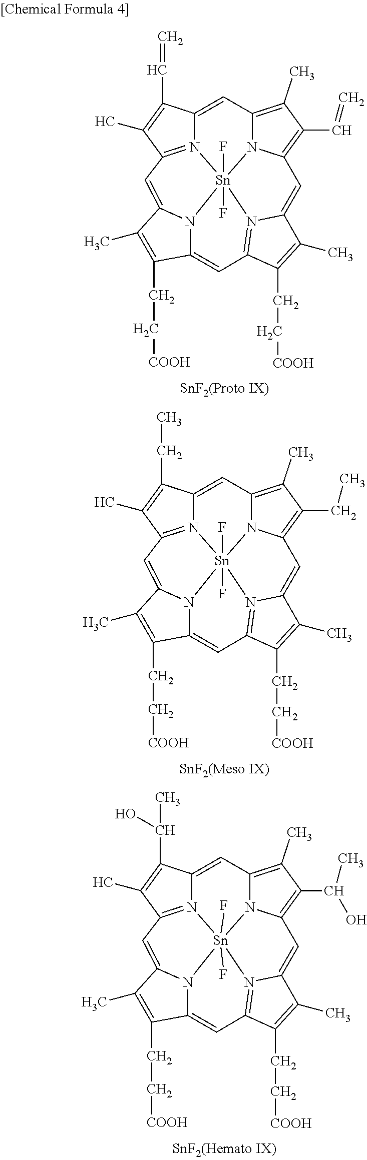

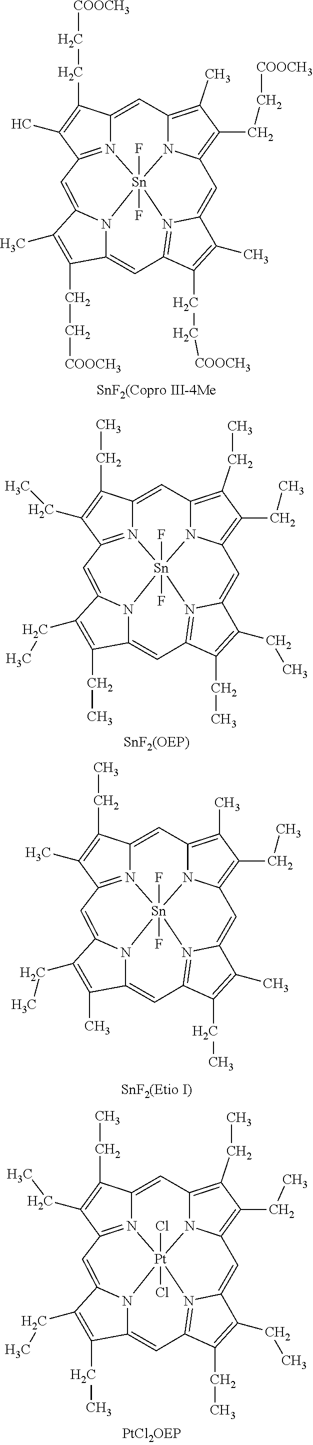

Alternatively, it is possible to use a heterocyclic compound having one or both of a π-electron rich heteroaromatic ring and a π-electron deficient heteroaromatic ring that is represented by the following structural formulas, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both enhanced, the energy difference between the S₁ level and the T₁ level becomes small, and thus thermally activated delayed fluorescence can be obtained with high efficiency. For example, instead of the π-electron deficient heteroaromatic ring, an aromatic ring to which an electron-withdrawing group such as a cyano group is bonded may be used, such as 2,4,5,6-tetra(9H-carbazol-9-yl)isophthalonitrile (abbreviation: 4CzIPN). In addition, an organic compound having a diboraanthracene skeleton, such as 9,10-bis(4-(9H-carbazol-9-yl)-2,6-dimethylphenyl)-9,10-diboraanthracene (abbreviation: CzDBA), may be used. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, atriazole skeleton, an imidazole skeleton, an anthraquinone skeleton, a skeleton containing boron such as phenylborane or boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

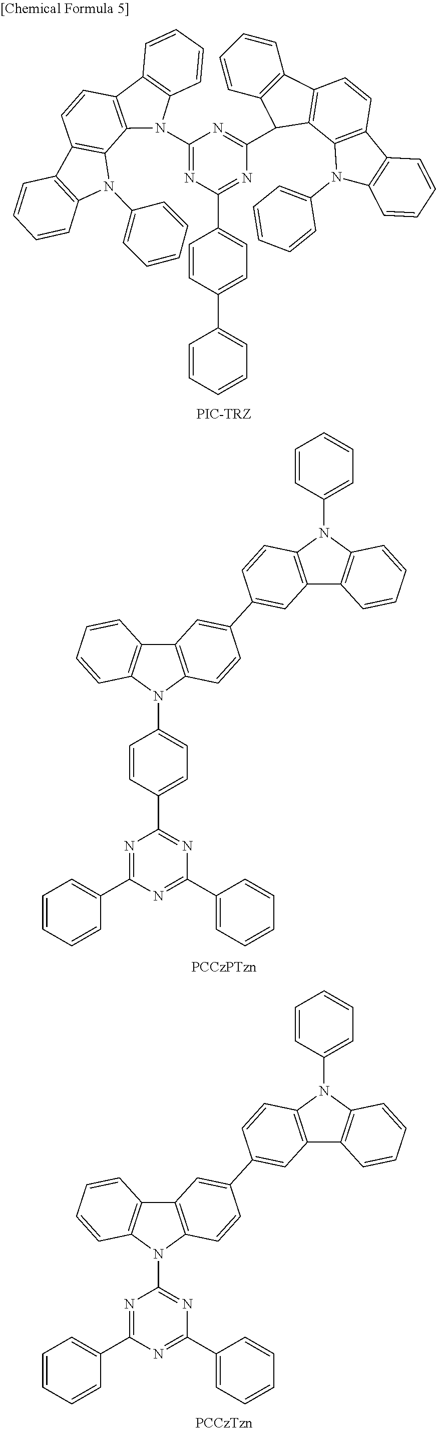 [SMILES: c1ccc(-c2ccc(-c3nc(C4c5ccccc5-c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

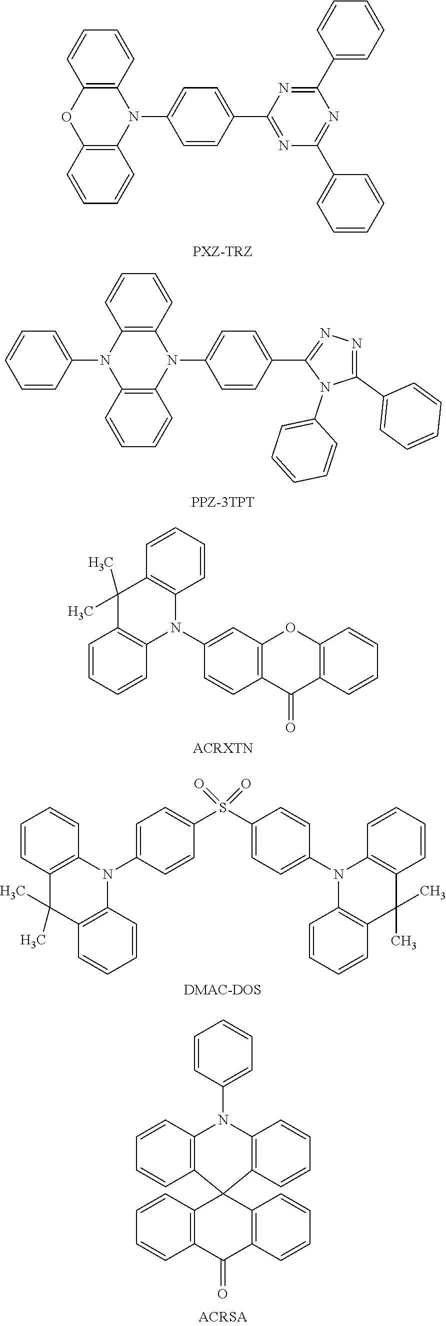 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

In addition to the above, a light-emitting substance which emits phosphorescent light (phosphorescent substance) can be used as a light-emitting substance. A phosphorescent substance is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably contains a metal element with large spin-orbit interaction, and can be an organometallic complex, a metal complex (platinum complex), or a rare earth metal complex, for example. Specifically, the phosphorescent substance preferably contains a transition metal element. It is particularly preferable that the phosphorescent substance contain a platinum group element (ruthenium (Ru), rhodium (Rh), Pd, osmium (Os), iridium (Ir), or Pt), especially iridium, in which case the probability of direct transition between the singlet ground state and the triplet excited state can be increased.

<<Phosphorescent Substance (from 450 nm to 570 nm, Blue or Green)>>

As examples of a phosphorescent substance which emits blue or green light and whose emission spectrum has a peak wavelength of greater than or equal to 450 nm and less than or equal to 570 nm, the following substances can be given.

Examples include organometallic complexes having a 4H-triazole ring, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organometallic complexes having a 1H-triazole ring, such as tris[3-methyl-1-(2-methylphenyl)-5-phenyl-TH-1,2,4-triazolato]iridium(III) (abbreviation: [Ir(Mptz1-mp)₃]) and tris(1-methyl-5-phenyl-3-propyl-TH-1,2,4-triazolato)iridium(III) (abbreviation: [Ir(Prptz1-Me)₃]); organometallic complexes having an imidazole ring, such as fac-tris[1-(2,6-diisopropylphenyl)-2-phenyl-1H-imidazole]iridium(III) (abbreviation: [Ir(iPrpim)₃]) and tris[3-(2,6-dimethylphenyl)-7-methylimidazo[1,2-f]phenanthridinato]iridium(III) (abbreviation: [Ir(dmpimpt-Me)₃]); organometallic complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), bis[2-(4′,6′-difluorophenyl)pyridinato-N,C^{2′}]iridium(III) acetylacetonate (abbreviation: FIr(acac)); and a platinum complex having a carbene structure such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI).

<<Phosphorescent Substance (from 495 nm to 590 nm, Green or Yellow)>>

As examples of a phosphorescent substance which emits green or yellow light and whose emission spectrum has a peak wavelength of greater than or equal to 495 nm and less than or equal to 590 nm, the following substances can be given.

Examples include organometallic iridium complexes having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine ring, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), bis[2-(2-pyridinyl-κN)phenyl-κC][2-(4-phenyl-2-pyridinyl-N)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κN)phenyl-κC], [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)), and bis[2-(6-tert-butyl-4-pyrimidinyl-κN3)-3-methylpyridinyl-κC](2,4-pentadionato-κ²O,O′)iridium(III) (abbreviation: Ir(tBumpypm)₂(acac)); organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C^{2′}}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and a rare earth metal complex such as tris(acetylacetonato) (monophenanthroline)terbium(III) (abbreviation: [Tb(acac)₃(Phen)]).

<<Phosphorescent Substance (from 570 nm to 750 nm, Yellow or Red)>>

As examples of a phosphorescent substance which emits yellow or red light and whose emission spectrum has a peak wavelength of greater than or equal to 570 nm and less than or equal to 750 nm, the following substances can be given.

Examples of the phosphorescent substance include organometallic complexes having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(d1npm)₂(dpm)]); organometallic complexes having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-N]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), bis[2-(5-(2,6-dimethylphenyl)-3-(3,5-dimethylphenyl)-2-pyrazinyl-κN)-4,6-dimethylphenyl-κC] (2,2′,6,6′-tetramethyl-3,5-heptanedionato-κ²O,O′)iridium(III) (abbreviation: [Ir(dmdppr-dmp)₂(dpm)]), (acetylacetonato)bis[2-methyl-3-phenylquinoxalinato-N,C^{2′}]iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine ring, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), and bis[4,6-dimethyl-2-(2-quinolinyl-κN)phenyl-κC] (2,4-pentanedionato-κ²O,O′)iridium(III) (abbreviation: [Ir(dmpqn)₂(acac)]); a platinum complex such as 2,3,7,8,12,13,17,18-octaethyl-21H,23H-porphyrin platinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato] (monophenanthroline)europium(III) (abbreviation: [Eu(TTA)₃(Phen)]).

### <Specific Example of First Substance>

A NEST material is preferably used as the first substance as described above. A specific example is an organic compound having an azaphenalene ring. The azaphenalene ring has a rigid skeleton; thus, a relatively sharp emission spectrum can be obtained by using an organic compound having an azaphenalene ring as the light-emitting substance.

Specific examples of the azaphenalene ring include a pyridoquinolizine ring such as pyrido[2,1,6-de]quinolizine; a pyrimidoquilolizine ring such as pyrimido[2,1,6-de]quinolizine; a triazaphenalene ring such as 1,4,9b-triazaphenalene, 1,6,9b-triazaphenalene, or 1,9,9b-triazaphenalene; a tetraazaphenalene ring such as 1,3,6,9b-tetraazaphenalene or 1,4,7,9b-tetraazaphenalene; a pentaazaphenalene ring such as 1,3,4,6,9b-pentaazaphenalene; a hexaazaphenalene ring such as 1,3,4,6,7,9b-hexaazaphenalene or 1,3,4,6,8,9b-hexaazaphenalene, and a heptaazaphenalene ring such as 1,3,4,6,7,9,9b-heptaazaphenalene. In other words, a preferred ring has a structure in which the 9b-poisition of a phenalene ring is substituted with nitrogen such that the S₁ level and the T₁ level can be closer to each other. The azaphenalene rings are represented by Structural Formulas (az-1) to (az-11) shown below.

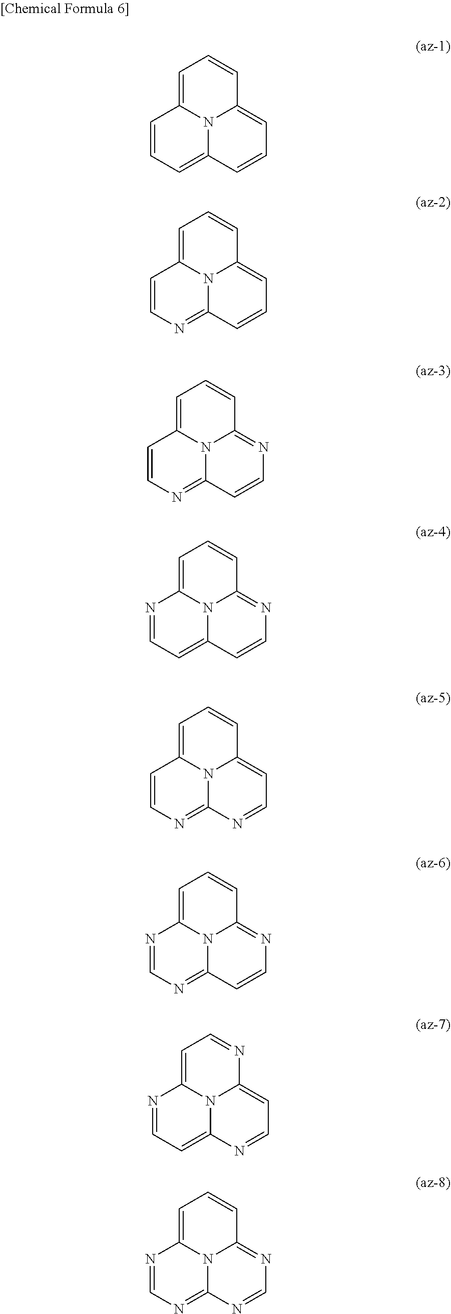

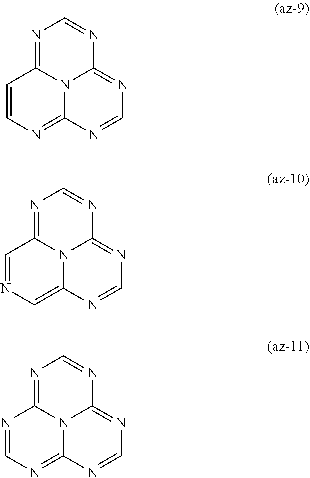 [SMILES: C1=CC2=NC=NC3=NC=NC(=N1)N23 ; C1=NC=C2N=CN=C3N=CN=C1N23 ; C1=NC2=NC=NC3=NC=NC(=N1)N23]

Among the above-described azaphenalene rings, chemically stable rings have structures in which nitrogen atoms are introduced at the 9b-position and three or more positions of 1-, 3-, 4-, 6-, 7-, and 9-positions (that is, at four or more positions in total) of the phenalene ring. As the light-emitting substance, any of the azaphenalene rings represented by Structural Formulas (az-6) to (az-9) and (az-11) is preferably used. Furthermore, more nitrogen atoms on it bonds can easily cause emission of light with a short wavelength. In particular, the 1,3,4,6,7,9,9b-heptaazaphenalene ring represented by Structural Formula (az-11) emits blue light and is suitable for a blue-light-emitting substance. Note that it is preferable that the 1,3,4,6,7,9,9b-heptaazaphenalene ring be not condensed with another aromatic ring. In addition, the 1,4,7,9b-tetraazaphenalene ring represented by Structural Formula (az-7) is suitable for a red-light-emitting substance. Note that it is preferable that the 1,4,7,9b-tetraazaphenalene ring be not condensed with another aromatic ring. Moreover, the pyrido[2,1,6-de]quinolizine ring represented by Structural Formula (az-1) is suitable for a near infrared-light-emitting substance. Note that it is preferable that pyrido[2,1,6-de]quinolizine ring be not condensed with another aromatic ring. Preferably, the symmetry of the whole molecular structure is broken by introduction of a substituent to these azaphenalene rings to make a partial overlap of HOMO and LUMO for high emission efficiency.

A further preferred molecular design is that one or more of halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, and an ester group having 1 to 10 carbon atoms are bonded to the azaphenalene ring. As described above, by introducing a substituent without a conjugation (it-bond), it is possible to inhibit a large overlap between HOMO and LUMO on the substituent, suppress a molecular interaction, and keep the absolute value of the difference between the S₁ level and the T₁ level, that is, |ΔE_{ST}|, small.

In a further preferred molecular design, the azaphenalene ring is bonded to a substituted or unsubstituted aryl group having 6 to 30 carbon atoms. In this manner, by introducing a substituent including a conjugation (π bond), the whole compound can be chemically stabilized.

The substituent is preferably a substituent having a higher T₁ level than the azaphenalene ring, in which case carrier recombination is made on the azaphenalene ring.

A specific example of the light-emitting substance is an organic compound represented by General Formula (GT) below.

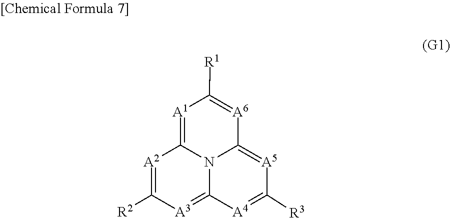

In General Formula (GT), A¹ to A⁶ each independently represent carbon or nitrogen, and A¹ to A⁶ each independently representing carbon are each independently bonded to any one of hydrogen (including deuterium), halogen, an alkyl group having 1 to 10 carbon atoms, a cycloalkyl group having 6 to 10 carbon atoms, a haloalkyl group having 1 to 10 carbon atoms, an alkoxy group having 1 to 10 carbon atoms, a haloalkoxy group having 1 to 10 carbon atoms, and a substituted or unsubstituted aryl group having 6 to 13 carbon atoms.

In General Formula (GT), R¹ to R³ each independently represent any one of hydrogen (including deuterium), halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 11 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group. Note that in General Formula (GT), hydrogen may be deuterium.

Among the azaphenalene rings, the 1,3,4,6,7,9,9b-heptaazaphenalene ring is superior in chemical stability as described above. For this reason, A¹ to A⁶ in General Formula (GT) are preferably nitrogen. This can further improve the stability of the organic compound.

Another specific example of the light-emitting substance is an organic compound represented by General Formula (G2).

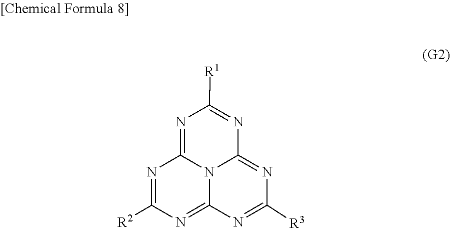

In General formula (G2), R¹ to R³ each independently represent any one of hydrogen (including deuterium), halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 11 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group. Note that in General formula (G2), hydrogen may be deuterium.

In a further preferred mode of General Formula (G2), any one of R¹ to R³ is an alkyl group or a haloalkyl group and the others thereof is a substituted or unsubstituted phenyl group. Accordingly, a NEST material that has high emission efficiency can be expected.

Another specific example of the light-emitting substance is an organic compound represented by General Formula (G3).

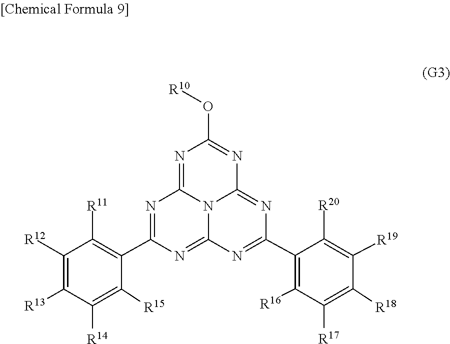

In General Formula (G3), R¹⁰ represents an alkyl group having 1 to 10 carbon atoms or a haloalkyl group having 1 to 10 carbon atoms, and R¹¹ to R²⁰ each independently represent any one of hydrogen (including deuterium), halogen, an alkyl group having 1 to 10 carbon atoms, a haloalkyl group having 1 to 10 carbon atoms, an alkoxy group having 1 to 10 carbon atoms, and a haloalkoxy group having 1 to 10 carbon atoms. Note that in General formula (G3), hydrogen may be deuterium.

As in the organic compound represented by General Formula (G3), the symmetry of the whole molecular structure is preferably broken by introduction of a plurality of different substituents to the azaphenalene ring to make a partial overlap of HOMO and LUMO for high emission efficiency.

Described next are specific examples of substituents (halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, an aryl group having 6 to 30 carbon atoms, an acyloxy group having 1 to 10 carbon atoms, an alkoxycarbonyl group having 1 to 10 carbon atoms, a haloalkoxylcarbonyl group having 1 to 10 carbon atoms, an aryloxycarbonyl group having 1 to 10 carbon atoms, and an azaphenalenyl group) that can be used for the above-described specific examples of the light-emitting substance. Note that in the specific examples of substituents described below, some or all of hydrogen atoms may be deuterium atoms. The substituent that can be used in a light-emitting substance is not limited to the following specific examples of substituents.

Specific examples of halogen include fluorine, chlorine, bromine, and iodine. In particular, fluorine, which is chemically stable, is preferable.

Specific examples of the alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

Specific examples of the cycloalkyl group having 6 to 10 carbon atoms include a cyclohexyl group, a 4-methylcyclohexyl group, a cycloheptyl group, a cyclooctyl group, a cyclononyl group, and a cyclodecyl group.

Specific examples of the haloalkyl group having 1 to 10 carbon atoms include a group in which one or more of hydrogen atoms contained in the alkyl group having 1 to 10 carbon atoms are substituted with halogen described above. More specifically, a fluoromethyl group, a difluoromethyl group, a difluorochloromethyl group, a trifluoromethyl group, a chloromethyl group, a dichloromethyl group, a bromomethyl group, a 1,1-difluoroethyl group, a 2,2,2-trifluoroethyl group, a 1,1,2,2-tetrafluoroethyl group, a pentafuoroethyl group, a 3,3,3-trifluoropropyl group, a 1,1,1,3,3,3-hexafluoroisopropyl group, a 1,1,2,2,3,3,3-heptafluoropropyl group, and the like can be given.

Specific examples of the alkoxy group having 1 to 10 carbon atoms include a methoxy group, an ethoxy group, a propoxy group, a tert-butoxy group, a pentyloxy group, an octyloxy group, and a cyclohexyloxy group.

Specific examples of the haloalkoxy group having 1 to 10 carbon atoms include a group in which one or more of hydrogen atoms contained in the alkoxy group having 1 to 10 carbon atoms are substituted with halogen described above. More specifically, a fluoromethoxy group, a difluoromethoxy group, a difluorochloromethoxy group, a trifluoromethoxy group, a chloromethoxy group, a dichloromethoxy group, a bromomethoxy group, a 1,1-difluoroethoxy group, a 2,2,2-trifluoroethoxy group, a 1,1,2,2-tetrafluoroethoxy group, a pentafluoroethoxy group, a 3,3,3-trifluoropropoxy group, a 1,1,1,3,3,3-hexafluoroisopropoxy group, a 1,1,2,2,3,3,3-heptafluoropropoxy group, and the like can be given.

Specific examples of the aryl group having 6 to 13 carbon atoms include a phenyl group, an o-tolyl group, an m-tolyl group, a p-tolyl group, a mesityl group, an o-biphenyl group, an m-biphenyl group, a p-biphenyl group, a 1-naphthyl group, a 2-naphthyl group, and a 9-fluorenyl group. Note that, in the case where the aryl group having 6 to 13 carbon atoms has a substituent, specific examples of the substituent include halogen, an alkyl group having 1 to 10 carbon atoms, a haloalkyl group having 1 to 10 carbon atoms, an alkoxy group having 1 to 10 carbon atoms, and a haloalkoxy group having 1 to 10 carbon atoms described above.

Specific examples of the aryloxy group having 6 to 13 carbon atoms include a phenoxy group, an o-tolyloxy group, an m-tolyloxy group, a p-tolyloxy group, a mesityloxy group, an o-biphenyloxy group, an m-biphenyloxy group, a p-biphenyoxyl group, a 1-naphthyloxy group, a 2-naphthyloxy group, and a 2-fluorenyloxy group.

Specific examples of the aryloxy group having 2 to 14 carbon atoms include an acetyloxy group, an ethylcarbonyloxy group, a butylcarbonyloxy group, an octylcarbonyloxy group, a dodecylcarbonyloxy group, and a phenylcarbonyloxy group.

A specific example of the alkoxycarbonyl group having 2 to 11 carbon atoms is a group in which one side of the carbonyl group is bonded to the above-described alkoxy group having 1 to 10 carbon atoms. More specific examples include a methoxycarbonyl group, an ethoxycarbonyl group, a propoxycarbonyl group, an isopropoxycarbonyl group, a butoxycarbonyl group, a sec-butoxycarbonyl group, an isobutoxycarbonyl group, and a tert-butoxycarbonyl group.

A specific example of the haloalkoxycarbonyl group having 2 to 11 carbon atoms is a group in which one side of the carbonyl group is bonded to the above-described haloalkoxy group having 1 to 10 carbon atoms. More specific examples include a fluoromethoxycarbonyl group, a difluoromethoxycarbonyl group, a difluorochloromethoxycarbonyl group, a trifluoromethoxycarbonyl group, a chloromethoxycarbonyl group, a dichloromethoxycarbonyl group, a bromomethoxycarbonyl group, a 1,1-difluoroethoxycarbonyl group, a 2,2,2-tirfluoroethoxycarbonyl group, a 1,1,2,2-tetrafluoroethoxycarbonyl group, a pentafluoroethoxycarbonyl group, a 3,3,3-trifluoropropoxycarbonyl group, a 1,1,1,3,3,3-hexafluoroisopropoxycarbonyl group, and a 1,1,2,2,3,3,3-heptafluoropropoxycarbonyl group.

A specific example of the aryloxycarbonyl group having 7 to 14 carbon atoms is a group in which one side of the carbonyl group is bonded to the above-described aryloxy group having 6 to 13 carbon atoms. More specific examples include a phenoxycarbonyl group, an o-tolyl oxycarbonyl group, an m-tolyl oxycarbonyl group, a p-tolyl oxycarbonyl group, a mesityloxycarbonyl group, an o-biphenyloxycarbonyl group, an m-biphenyloxycarbonyl group, a p-biphenyloxycarbonyl group, a 1-naphthyloxycarbonyl group, and a 2-naphthyloxycarbonyl group, and a fluorenyl oxycarbonyl group.

Specific examples of the azaphenalenyl group include the substituents including the azaphenalene ring described above. More specifically, a group having the 1,3,4,6,7,9,9b-heptaazaphenalene ring, which is chemically stable, is further preferable. The examples include a group to which an azaphenalene ring is bonded through a substituent such as a substituted or unsubstituted phenylene group. A group including an azaphenalene ring having the same structure as an azaphenalene ring as a main skeleton is preferably used as the azaphenalenyl group, leading to a reduction in synthesis cost.

More specific examples of the light-emitting substance include organic compounds represented by Structural Formulas (az-1), (az-11), and (100) to (108).

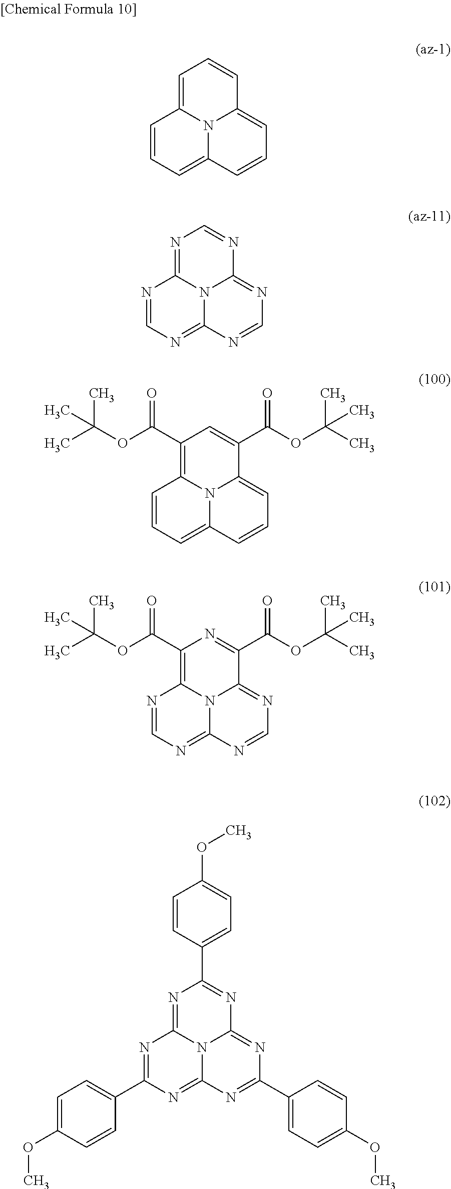

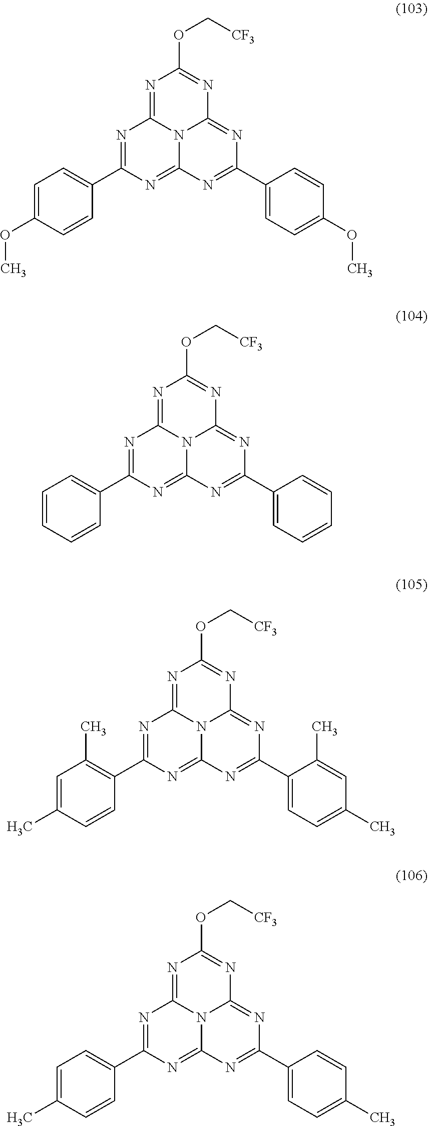

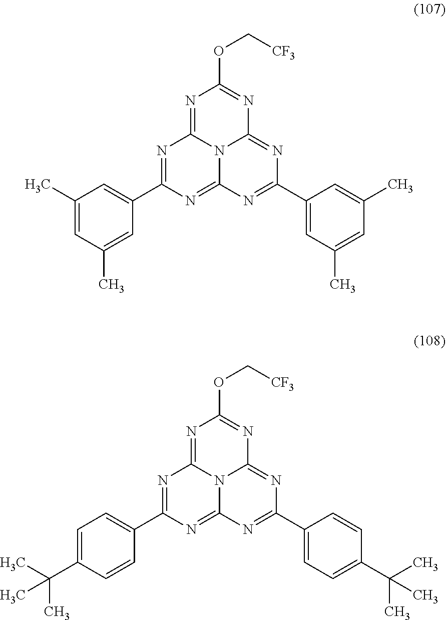

Although the organic compounds represented by Structural Formulas (az-1), (az-11), and (100) to (108) are each an example of the organic compound that can be used as a light-emitting substance, one embodiment of the present invention is not limited thereto.

Among the above-described specific examples, an organic compound having a property of a NEST material is preferably selected. Specifically, in the case where the first temperature is lower than the second temperature and the first temperature and the second temperature are in the range of 10 K to 300 K, inclusive, an organic compound that exhibits a delayed fluorescence lifetime at the first temperature shorter than that at the second temperature is the NEST material and can be preferably used. Note that the organic compound represented by Structural Formula (105) has a property of the NEST material and is further preferable, among the above described specific examples.

The structures described in this embodiment can be used in combination with any of the structures described in the other embodiments as appropriate.

### <Specific Example of Second Substance>

Although the structure of the second substance is not particularly limited, it is preferable to use a substance having a high carrier-transport property for the second substance, and any one of a substance having a high hole-transport property, a substance having a high electron-transport property, a substance having a bipolar property (a substance having a high electron-transport property and a high hole-transport property) is preferred.

In the case where the first substance is a compound having a π-electron deficient heteroaromatic ring, such as an organic compound having an azaphenalene ring, the second substance is preferably a compound having a high hole-transport property, that is, a compound having a π-electron rich heteroaromatic ring, in which case the device can have favorable carrier balance. The organic compound having an azaphenalene ring tends to have a low LUMO level (which is a negative value having a high absolute value), and thus when the HOMO level of the organic compound used as the second substance is high, an exciplex is easily formed between the first substance and the second substance. Therefore, the second substance is preferably a substance having a low HOMO level and a high hole-transport property, for example, a carbazole derivative, in which case an exciplex is unlikely to be formed between the first substance and the second substance.

The substance having a high hole-transport property is preferably a substance having a hole mobility higher than or equal to 1×10⁻⁶ cm²/Vs in the case where the square root of the electric field strength [V/cm] is 600. Note that any other substance can also be used as long as the substance has a hole-transport property higher than an electron-transport property.

Preferred examples of the substance having a high hole-transport property include a compound having a π-electron rich heteroaromatic ring (e.g., a carbazole derivative, a furan derivative, or a thiophene derivative) and an aromatic amine (an organic compound having an aromatic amine skeleton).

Examples of the carbazole derivative (an organic compound having a carbazole ring) include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) include 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: PNCCP).

Specific examples of the aromatic amine having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-[1,1′:3′,1″-terphenyl-4-yl]-9,9-dimethyl-9H-fluoren-2-amine, N-[4-(9-phenyl-9H-carbazol-3-yl)phenyl]-N-[1,1′:4′,1″-terphenyl-4-yl]-9,9-dimethyl-9H-fluoren-2-amine, N-[4-(9-phenyl-9H-carbazol-3-yl)phenyl]-N-[1,1′:3′,1″-terphenyl-4-yl]-9,9-dimethyl-9H-fluoren-4-amine, N-[4-(9-phenyl-9H-carbazol-3-yl)phenyl]-N-[1,1′:4′,1″-terphenyl-4-yl]-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), N-(9,9-spirobi[9H-fluoren]-2-yl)-N,9-diphenylcarbazol-3-amine (abbreviation: PCASF), N-[4-(9H-carbazol-9-yl)phenyl]-N-(4-phenyl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 9-[4-(9-phenyl-9H-carbazol-3-yl)-phenyl]phenanthrene (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), 9-(4-tert-butylphenyl)-3,4-bis(triphenylsilyl)-9H-carbazole (abbreviation: CzSi), and 2,7-bis(diphenylphosphoryl)-9-phenyl-9H-carbazole (abbreviation: PPO27).

Specific examples of the furan derivative (an organic compound having a furan ring) include 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II).

Specific examples of the thiophene derivative (an organic compound having a thiophene ring) include organic compounds having a thiophene ring, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the aromatic amine include 4,4′-bis[N-(1-naphthyl)-N-phenylamino]biphenyl (abbreviation: NPB or α-NPD), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), N-(9,9-spirobi[9H-fluoren]-2-yl)-N,N′,N′-triphenyl-1,4-phenylenediamine (abbreviation: DPASF), N,N′-diphenyl-N,N′-bis(4-diphenylaminophenyl)spirobi[9H-fluorene]-2,7-diamine (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), 1,3,5-tris[N-(4-diphenylaminophenyl)-N-phenylamino]benzene (abbreviation: DPA3B), N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N′-bis(4-biphenyl)benzo[b]naphtho[1,2-d]furan-8-amine (abbreviation: BBABnf(8)), N,N′-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAPNB), 4-[4-(2-naphthyl)phenyl]-4′,4″-diphenyltriphenylamine (abbreviation: BBAPNBi), 4,4′-diphenyl-4″-(6;1′-binaphthyl-2-yl)triphenylamine (abbreviation: BBAaNPNB), 4,4′-diphenyl-4″-(7;1′-binaphthyl-2-yl)triphenylamine (abbreviation: BBAaNPNB-03), 4,4′-diphenyl-4″-(7-phenyl)naphthyl-2-yltriphenylamine (abbreviation: BBAPPNB-03), 4,4′-diphenyl-4″-(6;2′-binaphthyl-2-yl)triphenylamine (abbreviation: BBA(PN2)B), 4,4′-diphenyl-4″-(7;2′-binaphthyl-2-yl)triphenylamine (abbreviation: BBA(PN2)B-03), 4,4′-diphenyl-4″-(4;2′-binaphthyl-1-yl)triphenylamine (abbreviation: BBAPNaNB), 4,4′-diphenyl-4″-(5;2′-binaphthyl-1-yl)triphenylamine (abbreviation: BBAPNaNB-02), 4-(4-biphenylyl)-4′-(2-naphthyl)-4″-phenyltriphenylamine (abbreviation: TPBiAPNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Other examples of the hole-transport material include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), and poly[N,N′-bis(4-butylphenyl)-N,N′-bis(phenyl)benzidine](abbreviation: Poly-TPD). Other examples include a high molecular compound to which acid is added, such as poly(3,4-ethylenedioxythiophene)/poly(styrenesulfonic acid) (abbreviation: PEDOT/PSS) and polyaniline/poly(styrenesulfonic acid) (abbreviation: PAni/PSS).

As the electron-transport material, a heteroaromatic compound can be used, for example. The heteroaromatic compound refers to a cyclic compound containing at least two different kinds of elements in a ring. Examples of cyclic structures include a three-membered ring, a four-membered ring, a five-membered ring, and a six-membered ring, among which a five-membered ring and a six-membered ring are preferable. The elements contained in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and an organic compound having a π-electron deficient heteroaromatic ring is preferably used.

Examples of the π-electron deficient heteroaromatic ring include an oxadiazole ring, a triazole ring, a benzimidazole ring, a quinoxaline ring, a dibenzoquinoxaline ring, a quinazoline ring, a phenanthroline ring, a pyridine ring, a diazine ring (a pyrimidine ring, a pyrazine ring, and a pyridazine ring), a triazine ring, and a furodiazine ring.

Examples of the organic compound having a π-electron deficient heteroaromatic ring include organic compounds having an oxadiazole ring such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), and 9-[4-(5-phenyl-1,3,4-oxadiazol-2-yl)phenyl]-9H-carbazole (abbreviation: CO11); an organic compound having a triazole ring such as 3-(4-biphenylyl)-4-phenyl-5-(4-tert-butylphenyl)-1,2,4-triazole (abbreviation: TAZ); organic compounds having a benzimidazole ring such as 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 2-{4-[9,10-di(2-naphthyl)-2-anthryl]phenyl}-1-phenyl-1H-benzimidazole (abbreviation: ZADN); an organic compound having a benzoxazole ring such as 4,4′-bis(5-methylbenzoxazol-2-yl)stilbene (abbreviation: BzOS); an organic compound having a phenanthroline ring such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), and 2,2′-(1,3-phenylene)bis[9-phenyl-1,10-phenanthroline] (abbreviation: mPPhen2P); organic compounds having a quinoxaline ring or a dibenzoquinoxaline ring such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), and 2-[4′-(9-phenyl-9H-carbazol-3-yl)-3,1′-biphenyl-1-yl]dibenzo[f,h]quinoxaline (abbreviation: 2mpPCBPDBq).

Specific examples of organic compounds having a pyridine ring, organic compounds having a diazine ring (including organic compounds having a pyrimidine ring, organic compounds having a pyrazine ring, and organic compounds having a pyridazine ring), organic compounds having a triazine ring, and organic compounds having a furodiazine ring, which are organic compounds having a π-electron deficient heteroaromatic ring, include 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)biphenyl-3-yl]-4,6-diphenyl-1,3,5-triazine (abbreviation: mFBPTzn), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 11-[(3′-dibenzothiophen-4-yl)bipheny-3-yl]phenanthro[9′,10′:4,5]furo[2,3-b]pyrazine (abbreviation: 11mDBtBPPnfpr), 11-[3′-(dibenzothiophen-4-yl)biphenyl-4-yl]phenanthro[9′,10′:4,5]furo[2,3-b]pyrazine, 11-[3′-(9H-carbazol-9-yl)biphenyl-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[(3′-9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-{(3′-[2,8-diphenyldibenzothiophen-4-yl)biphenyl-3-yl}naphtho[1′,2′:4,5]furo[2,3-b]pyrazine, 11-{(3′-[2,8-diphenyldibenzothiophen-4-yl)biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn), 6-(biphenyl-3-yl)-4-[3,5-bis(9H-carbazol-9-yl)phenyl]-2-phenylpyrimidine (abbreviation: 6mBP-4Cz2PPm), and 4-[3,5-bis(9H-carbazol-9-yl)phenyl]-2-phenyl-6-(biphenyl-4-yl)pyrimidine (abbreviation: 6BP-4Cz2PPm).

Furthermore, any of the following organic compounds having a diazine ring, which have a bipolar property having both a high hole-transport property and a high electron-transport property, can be used as the second substance: 9-phenyl-9′-(4-phenyl-2-quinazolinyl)-3,3′-bi-9H-carbazole (abbreviation: PCCzQz), 2mpPCBPDBq, mINc(II)PTzn, 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), and 7-[4-(9-phenyl-9H-carbazol-2-yl)quinazolin-2-yl]-7H-dibenzo[c,g]carbazole (abbreviation: PC-cgDBCzQz).

The above is the description of the light-emitting layer 113 included in the light-emitting device 100. With such a structure, the light-emitting device can have high efficiency. Furthermore, the light-emitting device can exhibit high color purity.

The structures described in this embodiment can be used in combination with any of the structures described in the other embodiments as appropriate.

### Embodiment 2

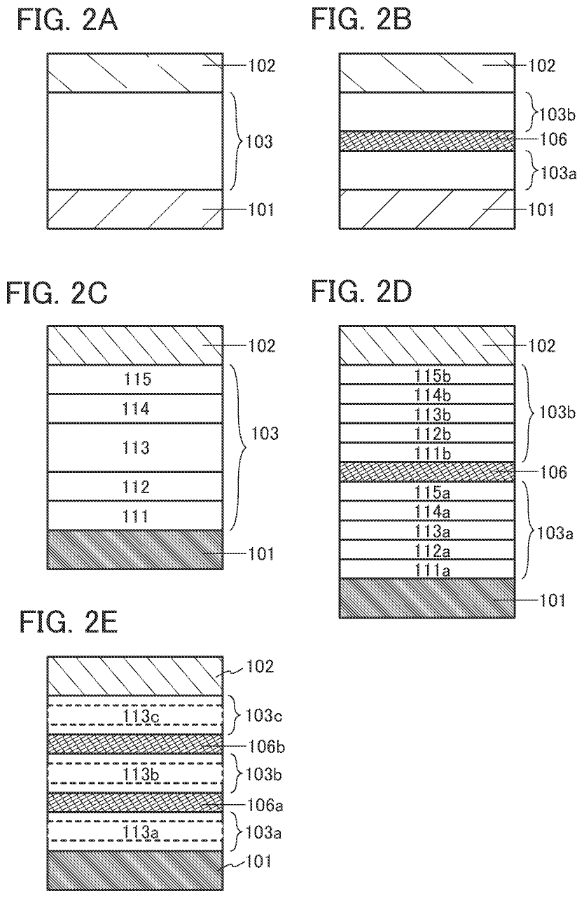

In this embodiment, structures of other layers than the light-emitting layer in the light-emitting device described in Embodiment 1 will be described with reference to FIGS. 2A to 2E.

### <<Basic Structure of Light-Emitting Device>>

Basic structures of the light-emitting device are described. As described in Embodiment 1, FIG. 2A illustrates a light-emitting device including the EL layer 103 including a light-emitting layer between a pair of electrodes.

FIG. 2B illustrates a light-emitting device having a structure where a plurality of EL layers (two EL layers of 103a and 103b in FIG. 2B) are provided between a pair of electrodes and a charge generation layer 106 is provided between the EL layers (such a structure is also referred to as a tandem structure). A light-emitting device having a tandem structure enables a light-emitting apparatus that has high efficiency without changing the amount of current.

The charge-generation layer 106 has a function of injecting electrons into one of the EL layers 103a and 103b and injecting holes into the other of the EL layers 103a and 103b when a potential difference is generated between the first electrode 101 and the second electrode 102. Thus, when a voltage is applied in FIG. 2B such that the potential of the first electrode 101 can be higher than that of the second electrode 102, electrons are injected into the EL layer 103a from the charge-generation layer 106 and holes are injected into the EL layer 103b from the charge-generation layer 106.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 2C illustrates a stacked-layer structure of the EL layer 103 in the light-emitting device. In this case, the first electrode 101 serves as an anode and the second electrode 102 serves as a cathode. The EL layer 103 has a structure where a hole-injection layer 111, a hole-transport layer 112, a light-emitting layer 113, an electron-transport layer 114, and an electron-injection layer 115 are sequentially stacked over the first electrode 101. Note that, the first electrode 101 may serve as a cathode, and the second electrode 102 may serve as an anode. In that case, the stacking order of the layers in the EL layer 103 is preferably reversed; specifically, it is preferable that the layer 111 over the first electrode 101 serving as the cathode be an electron-injection layer, the layer 112 be an electron-transport layer, the layer 113 be a light-emitting layer, the layer 114 be a hole-transport layer, and the layer 115 be a hole-injection layer.

The light-emitting layer 113 contains an appropriate combination of a light-emitting substance and a plurality of substances, so that fluorescent light or phosphorescent light of a desired color can be obtained. The light-emitting layer included in the light-emitting device of one embodiment of the present invention preferably employs the structure of the light-emitting layer described in Embodiment 1.

Note that the light-emitting layer 113 may have a stacked-layer structure of a plurality of light-emitting layers that emit light of different colors. When a plurality of light-emitting layers are provided, the use of different light-emitting substances for the light-emitting layers enables a structure that exhibits different emission colors (for example, complementary emission colors are combined to obtain white light emission). For example, a light-emitting layer containing a light-emitting substance that emits red light, a light-emitting layer containing a light-emitting substance that emits green light, and a light-emitting layer containing a light-emitting substance that emits blue light may be stacked with or without a layer containing a carrier-transport material therebetween. Alternatively, a light-emitting layer containing a light-emitting substance that emits yellow light and a light-emitting layer containing a light-emitting substance that emits blue light may be used in combination. In this case, the combination of the light-emitting substance and other substances are preferably different between the stacked light-emitting layers. Alternatively, the plurality of EL layers (103a and 103b) in FIG. 2B may exhibit their respective emission colors. Also in this case, the combination of the light-emitting substance and other substances may be different between the stacked light-emitting layers.

Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer containing a light-emitting substance that emits blue light and a second light-emitting layer containing a light-emitting substance that emits blue light may be stacked with or without a layer containing a carrier-transport material therebetween. Alternatively, the plurality of EL layers (103a and 103b) in FIG. 2B may exhibit the same emission color. The structure where a plurality of light-emitting layers that emit light of the same color are stacked can sometimes achieve higher reliability than a single-layer structure.

In the case where the light-emitting layer 113 has a structure where a plurality of light-emitting layers are stacked, at least one of the plurality of light-emitting layers preferably employs the structure of the light-emitting layer described in Embodiment 1.

The light-emitting device can have a micro optical resonator (microcavity) structure when, for example, the first electrode 101 is a reflective electrode and the second electrode 102 is a transflective electrode in FIG. 2C. Thus, light from the light-emitting layer 113 in the EL layer 103 can be resonated between the electrodes and intensified light can be emitted through the second electrode 102.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is λ, the optical path length between the first electrode 101 and the second electrode 102 (the product of the thickness and the refractive index) is preferably adjusted to be mλ/2 (m is an integer of 1 or more) or close to mλ/2.

To amplify desired light (wavelength: λ) obtained from the light-emitting layer 113, it is preferable to adjust each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) to be (2m′+1)λ/4 (m′ is an integer of 1 or more) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

FIG. 2D illustrates a stacked-layer structures of the EL layers (103a and 103b) of the light-emitting device having a tandem structure. In this case, the first electrode 101 serves as an anode and the second electrode 102 serves as a cathode. The EL layer 103a has a structure where a hole-injection layer 111a, a hole-transport layer 112a, alight-emitting layer 113a, an electron-transport layer 114a, and an electron-injection layer 115a are sequentially stacked over the first electrode 101. The EL layer 103b has a structure where a hole-injection layer 111b, a hole-transport layer 112b, alight-emitting layer 113b, an electron-transport layer 114b, and an electron-injection layer 115b are sequentially stacked over the charge-generation layer 106. Note that the first electrode 101 may serve as a cathode and the second electrode 102 may serve as an anode; in that case, the stacking order of the layers in the EL layer 103 is preferably reversed.

For example, when the light-emitting device in FIG. 2D has a microcavity structure, the first electrode 101 is formed as a reflective electrode and the second electrode 102 is formed as a transfective electrode. Thus, a single-layer structure or a stacked-layer structure can be formed using one or more kinds of desired electrode materials. Note that the second electrode 102 is formed after formation of the EL layer 103b, with the use of a material selected as appropriate.

In the case where the light-emitting device illustrated in FIG. 2D has a microcavity structure and light-emitting layers that emit light of different colors are used in the EL layers (103a and 103b), light (monochromatic light) with a desired wavelength derived from any of the light-emitting layers can be extracted owing to the microcavity structure. Thus, when such a light-emitting device is used for the light-emitting apparatus and the microcavity structure is adjusted in order to extract light with wavelengths which differ among pixels, separate formation of EL layers for obtaining different emission colors (e.g., R, G, and B) for each pixel is unnecessary. Therefore, higher resolution can be easily achieved. A combination with coloring layers (color filters) is also possible. Furthermore, the emission intensity of light with a specific wavelength in the front direction can be increased, whereby power consumption can be reduced.

The light-emitting device illustrated in FIG. 2E is an example of the light-emitting device having the tandem structure illustrated in FIG. 2B, and includes three EL layers (103a, 103b, and 103c) stacked with charge-generation layers (106a and 106b) therebetween, as illustrated in FIG. 2E. The three EL layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light. For another example, the light-emitting layer 113a can emit red light, the light-emitting layer 113b can emit blue light, green light, or yellow light, and the light-emitting layer 113c can emit red light.

In the light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity less than or equal to 1×10⁻² Ωcm.

When one of the first electrode 101 and the second electrode 102 is a reflective electrode in the light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity less than or equal to 1×10⁻² Ωcm.

### <<Specific Structure of Light-Emitting Device>>

Next, specific structures of layers in the light-emitting device of one embodiment of the present invention will be described. Note that for simplicity, reference numerals are sometimes omitted in the description of the layers.

### <First Electrode and Second Electrode>

As materials for the first electrode and the second electrode, any of the following materials can be used in an appropriate combination as long as the above functions of the electrodes can be fulfilled. For example, a metal, an alloy, an electrically conductive compound, a mixture of these, and the like can be used as appropriate. Specifically, an In—Sn oxide (also referred to as ITO), an In—Si—Sn oxide (also referred to as ITSO), an In—Zn oxide, or an In—W—Zn oxide can be used. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing any of these metals in an appropriate combination. It is also possible to use an element belonging to Group 1 or Group 2 of the periodic table that is not described above (e.g., lithium (Li), cesium (Cs), calcium (Ca), or strontium (Sr)), a rare earth metal such as europium (Eu) or ytterbium (Yb), an alloy containing any of these elements in an appropriate combination, graphene, or the like.

In the light-emitting device illustrated in FIG. 2D, when the first electrode 101 is the anode, the hole-injection layer 111a and the hole-transport layer 112a of the EL layer 103a are sequentially stacked over the first electrode 101 by a vacuum evaporation method. After the EL layer 103a and the charge-generation layer 106 are formed, the hole-injection layer 1l1b and the hole-transport layer 112b of the EL layer 103b are sequentially stacked over the charge-generation layer 106 in a similar manner.

### <Hole-Injection Layer>

The hole-injection layer injects holes from the first electrode serving as an anode and the charge-generation layer to the EL layer, and includes an organic acceptor material and a material having a high hole-injection property.

The organic acceptor material allows holes to be generated in another organic compound whose HOMO level is close to the LUMO level of the organic acceptor material when charge separation is caused between the organic acceptor material and the organic compound. Thus, as the organic acceptor material, a compound having an electron-withdrawing group (e.g., a halogen group or a cyano group), such as a quinodimethane derivative, a chloranil derivative, and a hexaazatriphenylene derivative, can be used. For example, any of the following materials can be used: 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F₆-TCNNQ), and 2-(7-dicyanomethylene-1,3,4,5,6,8,9,10-octafluoro-7H-pyren-2-ylidene)malononitrile. Note that among organic acceptor materials, a compound in which electron-withdrawing groups are bonded to a condensed aromatic ring having a plurality of heteroatoms, such as HAT-CN, is particularly preferred because it has a high acceptor property and stable film quality against heat. Besides, a [3]radialene derivative having an electron-withdrawing group (particularly a cyano group or a halogen group such as a fluoro group), which has a very high electron-accepting property, is preferred; specific examples are α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

As the material having a high hole-injection property, an oxide of a metal belonging to Group 4 to Group 8 of the periodic table (e.g., a transition metal oxide such as molybdenum oxide, vanadium oxide, ruthenium oxide, tungsten oxide, or manganese oxide) can be used. Specific examples are molybdenum oxide, vanadium oxide, niobium oxide, tantalum oxide, chromium oxide, tungsten oxide, manganese oxide, and rhenium oxide. Among the above oxides, molybdenum oxide is preferable because it is stable in the air, has a low hygroscopic property, and is easily handled. Other examples are phthalocyanine (abbreviation: H₂Pc) and a phthalocyanine-based compound such as copper phthalocyanine (abbreviation: CuPc).

Other examples include aromatic amine compounds, which are low molecular compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N-phenylamino}phenyl)methacrylamide] (abbreviation: PTPDMA), and poly[N,N′-bis(4-butylphenyl)-N,N′-bis(phenyl)benzidine] (abbreviation: Poly-TPD). Other examples include high-molecular compounds to which acid is added, such as poly(3,4-ethylenedioxythiophene)/poly(styrenesulfonic acid) (abbreviation: PEDOT/PSS) and polyaniline/poly(styrenesulfonic acid) (abbreviation: PAni/PSS).

As the material having a high hole-injection property, a mixed material containing a hole-transport material and the above-described organic acceptor material (electron-accepting material) can be used. In this case, the organic acceptor material extracts electrons from the hole-transport material, so that holes are generated in the hole-injection layer 111 and injected into the light-emitting layer 113 through the hole-transport layer 112. Note that the hole-injection layer 111 may be formed to have a single-layer structure using a mixed material containing a hole-transport material and an organic acceptor material (electron-accepting material), or a stacked-layer structure of a layer containing a hole-transport material and a layer containing an organic acceptor material (electron-accepting material).

### <<Hole-Transport Material>>

The hole-transport material preferably has a hole mobility higher than or equal to 1×10⁻⁶ cm²/Vs in the case where the square root of the electric field strength [V/cm] is 600. Note that any other substance can also be used as long as the substance has a hole-transport property higher than an electron-transport property.

Preferred examples of the hole-transport material include a compound having a π-electron rich heteroaromatic ring such as a carbazole derivative, a furan derivative, or a thiophene derivative, and an aromatic amine (an organic compound having an aromatic amine skeleton), which are each a material having a high hole-transport property.

Specific examples of the compound having a π-electron rich heteroaromatic ring and the aromatic amine include the organic compounds listed in the foregoing embodiment.

Note that the hole-transport material is not limited to the above examples, and any of a variety of known materials may be used alone or in combination as the hole-transport material.

The hole-injection layer can be formed by any of known deposition methods such as a vacuum evaporation method.

### <Hole-Transport Layer>

The hole-transport layer transports holes, which are injected from the first electrode by the hole-injection layer, to the light-emitting layer. The hole-transport layer includes a hole-transport material. Thus, the hole-transport layer can be formed using a hole-transport material that can be used for the hole-injection layer. Furthermore, the hole-transport layer can function even with a single-layer structure, but may have a stacked structure of two or more layers. For example, one of two hole-transport layers that is in contact with the light-emitting layer may also function as an electron-blocking layer.

Note that in the light-emitting device of one embodiment of the present invention, the same organic compound can be used for the hole-transport layer and the light-emitting layer. Using the same organic compound for the hole-transport layer and the light-emitting layer is preferable because holes can be efficiently transported from the hole-transport layer to the light-emitting layer. In other words, the hole-transport layer is preferably a layer in contact with the light-emitting layer, in which case the driving voltage can be reduced.

### <Electron-Transport Layer>

The electron-transport layer transports electrons, which are injected from the second electrode and the charge-generation layer by the electron-injection layer to be described later, to the light-emitting layer. The material used for the electron-transport layer is preferably a substance having an electron mobility higher than or equal to 1×10⁻⁶ cm²/Vs in the case where the square root of the electric field strength [V/cm] is 600. Note that any other substance can also be used as long as the substance has an electron-transport property higher than a hole-transport property. Furthermore, the electron-transport layer can function even with a single-layer structure, but may have a stacked structure of two or more layers. For example, one of two electron-transport layers which is in contact with the light-emitting layer may also function as a hole-blocking layer. Moreover, when the electron-transport layer has a stacked-layer structure, heat resistance can be increased in some cases. A photolithography process performed over the electron-transport layer including the above-described mixed material, which has heat resistance, can reduce an adverse effect of thermal process on the device characteristics.

Note that in the light-emitting device of one embodiment of the present invention, the same organic compound can be used for the electron-transport layer and the light-emitting layer. Using the same organic compound for the electron-transport layer and the light-emitting layer is preferable because electrons can be efficiently transported from the electron-transport layer to the light-emitting layer. That is, the electron-transport layer is preferably a layer in contact with the light-emitting layer, in which case the driving voltage can be reduced.

### <<Electron-Transport Material>>

As the electron-transport material that can be used for the electron-transport layer, an organic compound having a high electron-transport property can be used, and for example, a heteroaromatic compound can be used. The heteroaromatic compound refers to a cyclic compound containing at least two different kinds of elements in a ring. Examples of cyclic structures include a three-membered ring, a four-membered ring, a five-membered ring, and a six-membered ring, among which a five-membered ring and a six-membered ring are particularly preferable. The elements contained in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used.

Note that the electron-transport material can be different from the materials used for the light-emitting layer. Not all excitons formed by recombination of carriers in the light-emitting layer can contribute to light emission and some excitons might be diffused into a layer in contact with the light-emitting layer or a layer in the vicinity of the light-emitting layer. In order to avoid this phenomenon, the energy level (the lowest singlet excitation energy level or the lowest triplet excitation energy level) of a material used for the layer in contact with the light-emitting layer or the layer in the vicinity of the light-emitting layer is preferably higher than that of a material used for the light-emitting layer. Therefore, when a material different from the material of the light-emitting layer is used as the electron-transport material, an element with high efficiency can be obtained.

The heteroaromatic compound is an organic compound having at least one heteroaromatic ring.

The heteroaromatic ring has any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a condensed heteroaromatic ring having a fused ring structure. Examples of the condensed heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound containing carbon and one or more of nitrogen, oxygen, sulfur, and the like, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of the heteroaromatic compound having a six-membered ring structure, which is a heteroaromatic compound containing carbon and one or more of nitrogen, oxygen, sulfur, and the like, include a heteroaromatic compound having a heteroaromatic ring, such as a pyridine ring, a diazine ring (including a pyrimidine ring, a pyrazine ring, a pyridazine ring, or the like), or a triazine ring. Other examples include a heteroaromatic compound having a bipyridine structure and a heteroaromatic compound having a terpyridine structure, although they are included in examples of a heteroaromatic compound in which pyridine rings are bonded.

Examples of the heteroaromatic compound having a fused ring structure including the above six-membered ring structure as a part include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure where an aromatic ring is condensed to a furan ring of a furodiazine ring), or a benzimidazole ring.

Specific examples of the heteroaromatic compound having a 5-membered ring structure (e.g., a polyazole ring (including an imidazole ring, a triazole ring, and an oxadiazole ring), an oxazole ring, a thiazole ring, or a benzimidazole ring) are PBD, OXD-7, COl1, TAZ, 3-(4-tert-butylphenyl)-4-(4-ethylphenyl)-5-(4-biphenylyl)-1,2,4-triazole (abbreviation: p-EtTAZ), TPBI, mDBTBIm-II, and BzOS.

Specific examples of the heteroaromatic compound having a 6-membered ring structure (including a heteroaromatic ring having a pyridine ring, a diazine ring, a triazine ring, or the like) are a heteroaromatic compound including a heteroaromatic ring having a pyridine ring, such as 35DCzPPy or TmPyPB; a heteroaromatic compound including a heteroaromatic ring having a triazine ring, such as PCCzPTzn, mPCCzPTzn-02, mINc(II)PTzn, mTpBPTzn, BP-SFTzn, 2,4NP-6PyPPm, PCDBfTzn, mBP-TPDBfTzn, 2-{3-[3-(dibenzothiophen-4-yl)phenyl]phenyl}-4,6-diphenyl-1,3,5-triazine (abbreviation: mDBtBPTzn), or mFBPTzn; and a heteroaromatic compound including a heteroaromatic ring having a diazine (pyrimidine) ring, such as 4,6mPnP2Pm, 4,6mDBTP2Pm-II, 4,6mCzP2Pm, 4,6mCzBP2Pm, 6mBP-4Cz2PPm, 6BP-4Cz2PPm, 8-(naphthalen-2-yl)-4-[3-(dibenzothiophen-4-yl)phenyl]-[1]benzofuro[3,2-d]pyrimidine (abbreviation: 8PN-4mDBtPBfpm), 8BP-4mDBtPBfpm, 9mDBtBPNfpr, 9pmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), and 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm). Note that the above aromatic compounds including a heteroaromatic ring include a heteroaromatic compound having a condensed heteroaromatic ring.

Other examples include a heteroaromatic compound including a heteroaromatic ring having a diazine (pyrimidine) ring, such as 2,2′-(pyridine-2,6-diyl)bis(4-phenylbenzo[h]quinazoline) (abbreviation: 2,6(P-Bqn)2Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine} (abbreviation: 2,6(NP-PPm)2Py), or 6mBP-4Cz2PPm, and a heteroaromatic compound including a heteroaromatic ring having a triazine ring, such as 2,4,6-tris[3′-(pyridin-3-yl)biphenyl-3-yl]-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridyl)-5-(9-phenanthryl)phenyl]-4,6-diphenyl-1,3,5-triazine (abbreviation: mPn-mDMePyPTzn).

Specific examples of the heteroaromatic compound with a fused structure that partly has a 6-membered ring structure are heteroaromatic compounds each having a quinoxaline ring, such as BPhen, bathocuproine (abbreviation: BCP), NBPhen, mPPhen2P, 2,6(P-Bqn)2Py, 2mDBTPDBq-II, 2mDBTBPDBq-II, 2mCzBPDBq, 2CzPDBq-III, 7mDBTPDBq-II, 6mDBTPDBq-II, and 2mpPCBPDBq.

For the electron-transport layer, any of the metal complexes given below as well as the heteroaromatic compounds given above can be used. Examples of the metal complexes include a metal complex having a quinoline ring or a benzoquinoline ring, such as tris(8-quinolinolato)aluminum(III) (abbreviation: Alq₃), Almq₃, 8-quinolinolato-lithium (abbreviation: Liq), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

High-molecular compounds such as poly(2,5-pyridinediyl) (abbreviation: PPy), poly[(9,9-dihexylfluorene-2,7-diyl)-co-(pyridine-3,5-diyl)] (abbreviation: PF-Py), and poly[(9,9-dioctylfluorene-2,7-diyl)-co-(2,2′-bipyridine-6,6′-diyl)] (abbreviation: PF-BPy) can be used as an electron-transport material.

### <Electron-Injection Layer>

The electron-injection layer is a layer containing a substance having a high electron-injection property. The electron-injection layer is a layer for increasing the efficiency of electron injection from the second electrode and is preferably formed using a material whose value of the LUMO level has a small difference (0.5 eV or less) from the work function of a material used for the second electrode. Thus, the electron-injection layer can be formed using an alkali metal, an alkaline earth metal, or a compound thereof, such as lithium, cesium, lithium fluoride (LiF), cesium fluoride (CsF), calcium fluoride (CaF₂), Liq, 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), an oxide of lithium (LiOₓ), or cesium carbonate. A rare earth metal such as Yb or a rare earth metal compound such as erbium fluoride (ErF₃) can also be used. To form the electron-injection layer, a plurality of kinds of materials given above may be mixed or stacked. For example, the electron-injection layer may be a stack of layers with different electric resistances. Electride may also be used for the electron-injection layer. Examples of the electride include a substance in which electrons are added at high concentration to calcium oxide-aluminum oxide. Any of the above-described substances used for the electron-transport layer can also be used.

A mixed material in which an organic compound and an electron donor (donor) are mixed may also be used for the electron-injection layer. Such a mixed material is excellent in an electron-injection property and an electron-transport property because electrons are generated in the organic compound by the electron donor. The organic compound here is preferably a material excellent in transporting the generated electrons; specifically, for example, electron-transport materials used for an electron-transport layer described above (e.g., a metal complex and a heteroaromatic compound) can be used. As the electron donor, a substance showing an electron-donating property with respect to an organic compound is used. Specifically, an alkali metal, an alkaline earth metal, and a rare earth metal are preferable, and Li, Cs, Mg, Ca, erbium (Er), Yb, and the like are given. In addition, an alkali metal oxide and an alkaline earth metal oxide are preferable, and lithium oxide, calcium oxide, barium oxide, and the like are given. Alternatively, a Lewis base such as magnesium oxide can be used. Further alternatively, an organic compound such as tetrathiafulvalene (abbreviation: TTF) can be used. Alternatively, a stack of two or more of these materials may be used.

Alternatively, the electron-injection layer may be formed using a mixed material in which an organic compound and a metal are mixed. The organic compound used here preferably has a lowest unoccupied molecular orbital (LUMO) level that is higher than or equal to −3.6 eV and lower than or equal to −2.3 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, or the like), a triazine ring, a bipyridine ring, or a terpyridine ring), and a heteroaromatic compound having a fused ring structure including a six-membered ring structure as a part (e.g., a quinoline ring, a benzoquinoline ring, a quinoxaline ring, a dibenzoquinoxaline ring, or a phenanthroline ring). Specific materials have been mentioned above and are not described here.

As a metal used for the above mixed material, a transition metal that belongs to Group 5, Group 7, Group 9, or Group 11 or a material that belongs to Group 13 in the periodic table is preferably used, and Ag, Cu, Al, In, or the like can be given. Here, the organic compound forms a singly occupied molecular orbital (SOMO) with the transition metal.

For example, in the case where light emitted from the light-emitting layer 113b is amplified in the light-emitting device illustrated in FIG. 2D, the optical path length between the second electrode 102 and the light-emitting layer 113b is preferably less than one fourth of the wavelength λ of light emitted from the light-emitting layer 113b. In this case, the optical path length can be adjusted by changing the thickness of the electron-transport layer 114b or the electron-injection layer 115b.

### <Charge-Generation Layer>

The charge-generation layer has a function of injecting electrons into one of the EL layers and injecting holes into the other of the EL layers when a voltage is applied between the first electrode and the second electrode of the light-emitting device having a tandem structure. The charge-generation layer may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Note that forming the charge-generation layer with the use of any of the above materials can suppress an increase in driving voltage caused by the stack of the EL layers.

In the case where the charge-generation layer is a p-type layer in which an electron acceptor is added to a hole-transport material, which is an organic compound, any of the materials described in this embodiment can be used as the hole-transport material. Furthermore, F₄-TCNQ, chloranil, and the like can be given as examples of the electron acceptor. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films containing the respective materials may be used.

In the case where the charge-generation layer is an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, Li, Cs, Mg, calcium (Ca), Yb, In, lithium oxide (Li₂O), cesium carbonate, or the like is preferably used. An organic compound such as tetrathianaphthacene may be used as the electron donor.

When an electron-relay layer is provided between a p-type layer and an electron-injection buffer layer in the charge-generation layer, the electron-relay layer contains at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

### <Cap Layer>

Although not illustrated in FIGS. 2A to 2E, a cap layer may be provided over the second electrode 102 of the light-emitting device. For example, a material with a high refractive index can be used for the cap layer. When the cap layer is provided over the second electrode 102, extraction efficiency of light emitted from the second electrode 102 can be improved.

Specific examples of a material that can be used for the cap layer include 5,5′-diphenyl-2,2′-di-5H-[1]benzothieno[3,2-c]carbazole (abbreviation: BisBTc) and DBT3P-II.

### <Substrate>

The light-emitting device described in this embodiment can be formed over any of a variety of substrates. Note that the type of substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, and paper or a base material film including a fibrous material.

Examples of the glass substrate include a barium borosilicate glass substrate, an aluminoborosilicate glass substrate, and a soda lime glass substrate. Examples of the flexible substrate, the attachment film, and the base material film include plastics typified by polyethylene terephthalate (PET), polyethylene naphthalate (PEN), and polyether sulfone (PES), a synthetic resin such as acrylic resin, polypropylene, polyester, polyvinyl fluoride, polyvinyl chloride, polyamide, polyimide, aramid, an epoxy resin, an inorganic vapor deposition film, and paper.

For fabrication of the light-emitting device of this embodiment, a gas phase method such as an evaporation method or a liquid phase method such as a spin coating method or an ink-jet method can be used. When an evaporation method is used, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the layers having various functions (the hole-injection layer 111, the hole-transport layer 112, the light-emitting layer 113, the electron-transport layer 114, and the electron-injection layer 115) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

In the case where a film formation method such as the coating method or the printing method is employed, a high molecular compound (e.g., an oligomer, a dendrimer, or a polymer), a middle molecular compound (a compound between a low molecular compound and a high molecular compound with a molecular weight of 400 to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

Note that in this specification and the like, the terms “layer” and “film” can be interchanged with each other as appropriate.

The structures described in this embodiment can be used in combination with any of the structures described in the other embodiments as appropriate.

### Embodiment 3

This embodiment will describe a light-emitting and light-receiving apparatus 700 as a specific example of a light-emitting apparatus of one embodiment of the present invention and an example of the fabrication method. Note that the light-emitting and light-receiving apparatus 700 includes both a light-emitting device and a light-receiving device, and can also be referred to as a light-emitting apparatus including a light-receiving device or a light-receiving apparatus including a light-emitting device. In addition, the light-emitting and light-receiving apparatus 700 can be used for a display portion of an electronic device or the like, and thus can also be referred to as a display panel or a display apparatus.

### <Structure Example of Light-Emitting and Light-Receiving Apparatus 700>

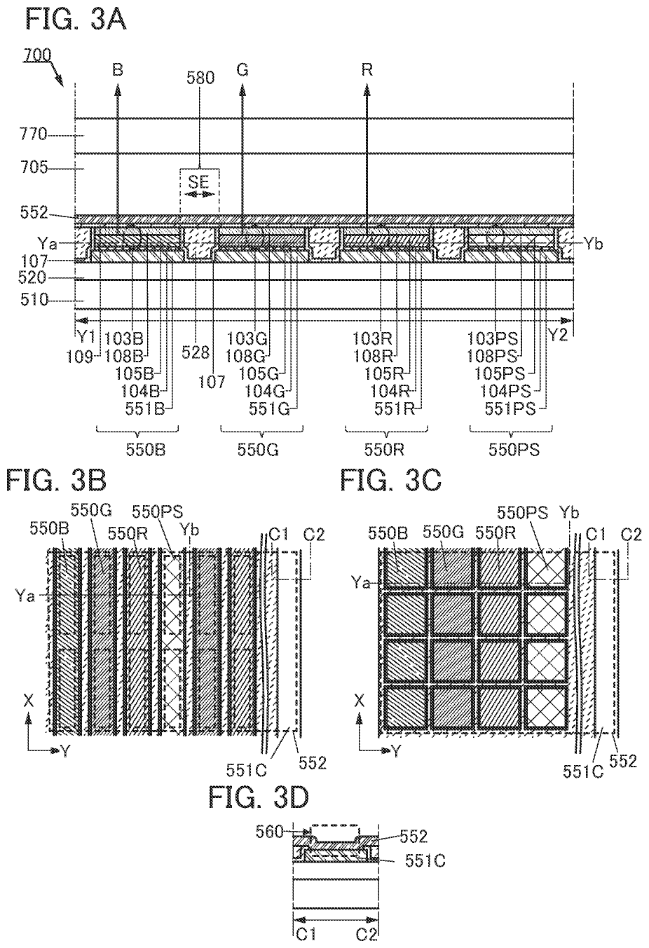

The light-emitting and light-receiving apparatus 700 illustrated in FIG. 3A includes a light-emitting device 550B, a light-emitting device 550G, a light-emitting device 550R, and a light-receiving device 550PS that are formed over a functional layer 520 over a first substrate 510. The functional layer 520 includes, for example, driver circuits such as a gate driver and a source driver that are composed of a plurality of transistors, and wirings that electrically connect these components. Note that these driver circuits are electrically connected to the light-emitting device 550B, the light-emitting device 550G, the light-emitting device 550R, and the light-receiving device 550PS, for example, to drive them. The light-emitting and light-receiving apparatus 700 includes an insulating layer 705 over the functional layer 520 and the devices (the light-emitting devices and the light-receiving device), and the insulating layer 705 has a function of attaching a second substrate 770 and the functional layer 520.

At least one of the light-emitting devices 550B, 550G, and 550R has the device structure described in the foregoing embodiment. In addition, the structure of the EL layer 103 (see FIG. 2A) differs between the light-emitting devices; for example, a light-emitting layer 105B of an EL layer 103B can emit blue light, a light-emitting layer 105G of an EL layer 103G can emit green light, and a light-emitting layer 105R of an EL layer 103R can emit red light.

Note that although in this embodiment, the case where the devices (a plurality of light-emitting devices and a light-receiving device) are formed separately is described, part of an EL layer of a light-emitting device (a hole-injection layer, a hole-transport layer, and an electron-transport layer) and part of an active layer of a light-receiving device (the hole-injection layer, the hole-transport layer, and the electron-transport layer) may be formed using the same material at the same time in the fabrication process.

In this specification and the like, a structure where light-emitting layers in light-emitting devices of different colors (for example, blue (B), green (G), and red (R)) and a light-receiving layer in a light-receiving device are separately formed or separately patterned is sometimes referred to as a side-by-side (SBS) structure. Although the light-emitting device 550B, the light-emitting device 550G, the light-emitting device 550R, and the light-receiving device 550PS are arranged in this order in the light-emitting and light-receiving apparatus 700 illustrated in FIG. 3A, one embodiment of the present invention is not limited to this structure.

In FIG. 3A, the light-emitting device 550B includes an electrode 551B, an electrode 552, and the EL layer 103B interposed between the electrode 551B and the electrode 552. The light-emitting device 550G includes an electrode 551G, the electrode 552, and the EL layer 103G interposed between the electrode 551G and the electrode 552. The light-emitting device 550R includes an electrode 551R, the electrode 552, and the EL layer 103R interposed between the electrode 551R and the electrode 552. The EL layers (103B, 103G, and 103R) each have a stacked-layer structure of layers having different functions including their respective light-emitting layers (105B, 105G, and 105R). Note that a specific structure of each layer of the light-emitting device is described in the foregoing embodiment, but is not limited.

In FIG. 3A, the light-receiving device 550PS includes an electrode 551PS, the electrode 552, and a light-receiving layer 103PS provided between the electrode 551PS and the electrode 552. The light-receiving layer 103PS has a stacked-layer structure of layers having different functions including an active layer 105PS. The active layer 105PS contains a semiconductor. Examples of the semiconductor are inorganic semiconductors such as silicon and organic semiconductors such as organic compounds. Specific structures of other layers in the light-receiving device can be similar to the structures of the corresponding layers in the light-emitting device.

FIG. 3A illustrates a case where the EL layer 103B includes a hole-injection/transport layer 104B, the light-emitting layer 105B, an electron-transport layer 108B, and an electron-injection layer 109; the EL layer 103G includes a hole-injection/transport layer 104G, the light-emitting layer 105G, an electron-transport layer 108G, and the electron-injection layer 109; the EL layer 103R includes a hole-injection/transport layer 104R, the light-emitting layer 105R, an electron-transport layer 108R, and the electron-injection layer 109; and the light-receiving layer 103PS includes a hole-injection/transport layer 104PS, the active layer 105PS, an electron-transport layer 108PS, and the electron-injection layer 109. However, the present invention is not limited thereto.

In FIG. 3A, the electron-injection layer 109 and the electrode 552 are layers (common layers) shared by the devices (the light-emitting device 550B, the light-emitting device 550G, the light-emitting device 550R, and the light-receiving device 550PS).

Hereinafter, for simplicity, the light-emitting device 550B, the light-emitting device 550G, and the light-emitting device 550R are collectively referred to as a light-emitting device 550; the electrode 551B, the electrode 551G, and the electrode 551R are collectively referred to as an electrode 551; the EL layer 103B, the EL layer 103G, and the EL layer 103R are collectively referred to as an EL layer 103; the hole-injection/transport layer 104B, the hole-injection/transport layer 104G, and the hole-injection/transport layer 104R are collectively referred to as a hole-injection/transport layer 104; the light-emitting layer 105B, the light-emitting layer 105G, and the light-emitting layer 105R are collectively referred to as a light-emitting layer 105; and the electron-transport layer 108B, the electron-transport layer 108G, and the electron-transport layer 108R are collectively referred to as an electron-transport layer 108, in some cases.

As illustrated in FIG. 3A, an insulating layer 107 may be formed on side surfaces (or end portions) of the hole-injection/transport layer 104, the light-emitting layer 105, and the electron-transport layer 108 included in the EL layer 103, and side surfaces (or end portions) of the hole-injection/transport layer 104PS, the active layer 105PS, and the electron-transport layer 108PS included in the light-receiving layer 103PS. The insulating layer 107 is formed in contact with the side surfaces (or the end portions) of the EL layer 103 and the light-receiving layer 103PS. This can inhibit entry of oxygen, moisture, or constituent elements thereof into the inside through the side surfaces of the EL layer 103 and the light-receiving layer 103PS. Note that the insulating layer 107 continuously covers the side surfaces (or the end portions) of part of the EL layer 103 and part of the light-receiving layer 103PS of adjacent devices. For example, in FIG. 3A, the side surfaces of parts of the EL layer 103B of the light-emitting device 550B and the EL layer 103G of the light-emitting device 550G are covered with the continuous insulating layer 107.

As illustrated in FIG. 3A, a partition 528 is provided between the devices. Note that the electron-injection layer 109 and the electrode 552 that are common layers shared by the devices are provided continuously without being divided by the partition 528. Thus, it can be said that the partition 528 is provided in a region surrounded by the electron-injection layer 109 and the insulating layer 107. In addition, the partitions 528 are positioned along side surfaces (or end portions) of the electrode 551, part of the EL layer 103 (the hole-injection/transport layer 104, the light-emitting layer 105, and the electron-transport layer 108), and part of the light-receiving layer 103PS (the hole-injection/transport layer 104, the active layer 105PS, and the electron-transport layer 108) with the insulating layer 107 therebetween.

In each of the EL layer 103 and the light-receiving layer 103PS, particularly the hole-injection layer, which is included in the hole-transport region between the anode and the light-emitting layer and between the anode and the active layer, often has high conductivity; thus, a hole-injection layer formed as a layer shared by adjacent devices might cause crosstalk. Thus, as described in this structure example, part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108) are separated, and the insulating layer 107 and the partition 528 are provided therebetween, so that crosstalk between adjacent devices can be inhibited.

Providing the partition 528 can flatten the surface by reducing a depressed portion formed between adjacent devices. When the depressed portion is reduced, disconnection of the electron-injection layer 109 and the electrode 552 formed over the EL layer 103 and the light-receiving layer 103PS can be inhibited.

For the insulating layer 107, aluminum oxide, magnesium oxide, hafnium oxide, gallium oxide, indium gallium zinc oxide, silicon nitride, or silicon nitride oxide can be used, for example. Some of the above-described materials may be stacked to form the insulating layer 107. The insulating layer 107 can be formed by a sputtering method, a CVD method, an MBE method, a PLD method, an ALD method, or the like and is formed preferably by an ALD method, which achieves favorable coverage.

Examples of an insulating material used to form the partition 528 include organic materials such as an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. Other examples include organic materials such as polyvinyl alcohol (PVA), polyvinyl butyral, polyvinyl pyrrolidone, polyethylene glycol, polyglycerin, pullulan, water-soluble cellulose, and alcohol-soluble polyamide resin. A photosensitive resin such as a photoresist can also be used. Examples of the photosensitive resin include positive-type materials and negative-type materials.

With the use of the photosensitive resin, the partition 528 can be fabricated by only light exposure and developing steps. The partition 528 may be fabricated using a negative photosensitive resin (e.g., a resist material). In the case where an insulating layer containing an organic material is used as the partition 528, a material absorbing visible light is suitably used. When such a material absorbing visible light is used for the partition 528, light emission from the EL layer can be absorbed by the partition 528, leading to a reduction in light leakage (stray light) to an adjacent EL layer or light-receiving layer. Thus, a light-emitting and light-receiving apparatus having high display quality can be provided.

For example, the difference between the top-surface level of the partition 528 and the top-surface level of the EL layer 103 and the light-receiving layer 103PS is preferably 0.5 times or less, further preferably 0.3 times or less the thickness of the partition 528. The partition 528 may be provided such that the top-surface level of the EL layer 103 or the light-receiving layer 103PS is higher than the top-surface level of the partition 528, for example. Alternatively, the partition 528 may be provided such that the top-surface level of the partition 528 is higher than the top-surface level of the light-emitting layer of the EL layer 103 and the active layer of the light-receiving layer 103PS, for example.

When crosstalk occurs between devices in a high-resolution light-emitting and light-receiving apparatus with a pixel density exceeding 1000 ppi, a color gamut that the light-emitting and light-receiving apparatus can reproduce is narrowed. In a high resolution light-emitting and light-receiving apparatus with 1000 ppi or more, a high resolution light-emitting and light-receiving apparatus with preferably 2000 ppi or more, or a super high resolution light-emitting and light-receiving apparatus with further preferably 5000 ppi or more, the insulating layer 107 and the partition 528 are provided between part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108), whereby the light-emitting and light-receiving apparatus can display bright colors.

FIGS. 3B and 3C are each a schematic top view of the light-emitting and light-receiving apparatus 700 taken along the dashed-dotted line Ya-Yb in the cross-sectional view of FIG. 3A. That is, the devices are arranged in a matrix. Note that FIG. 3B illustrates what is called a stripe arrangement, in which the light-emitting devices of the same color or the light-receiving devices are arranged in the X-direction. FIG. 3C illustrates a structure where the light-emitting devices of the same color or the light-receiving devices are arranged in the X-direction and separated by patterning for each pixel. Note that the arrangement method of the light-emitting devices is not limited thereto; another method such as a delta, zigzag, PenTile, or diamond arrangement can also be used.

Note that part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108) are processed by patterning using a lithography method for separation of the layers, so that a high-resolution light-emitting and light-receiving apparatus (display panel) can be fabricated. End portions (side surfaces) of the layers of the EL layer 103 and the layers of the light-receiving layer 103PS processed by patterning using a photolithography method have substantially one surface (or are positioned on substantially the same plane). In this case, the widths (SE) of spaces 580 between the EL layers and between the EL layer and the light-receiving layer are each preferably 5 μm or less, further preferably 1 μm or less.

FIG. 3D is a schematic cross-sectional view taken along the dashed-dotted line C1-C2 in FIGS. 3B and 3C. FIG. 3D illustrates a connection portion 560 where a connection electrode 551C and the electrode 552 are electrically connected to each other. In the connection portion 560, the electrode 552 is provided over and in contact with the connection electrode 551C. The partition 528 is provided to cover an end portion of the connection electrode 551C.

### <Fabrication Method Example of Light-Emitting and Light-Receiving Apparatus>

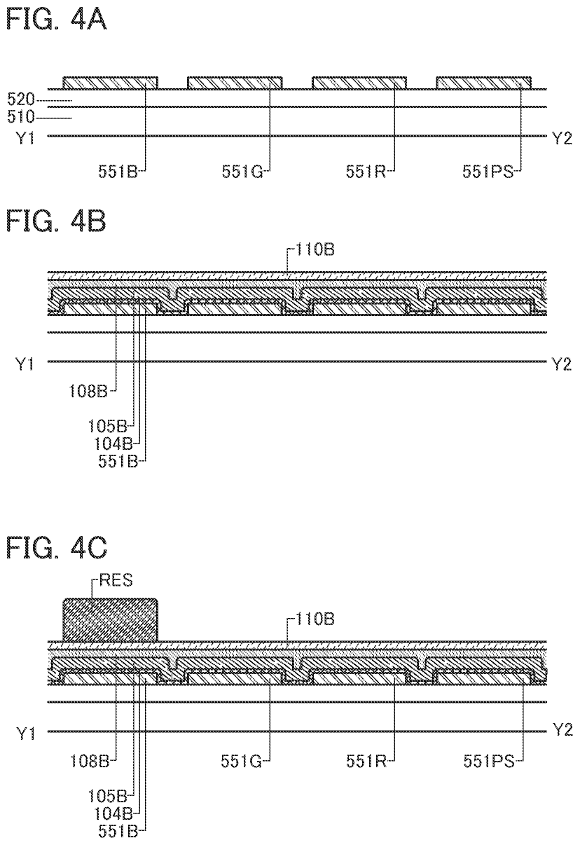

The electrode 551B, the electrode 551G, the electrode 551R, and the electrode 551PS are formed as illustrated in FIG. 4A. For example, a conductive film is formed over the functional layer 520 over the first substrate 510 and processed into predetermined shapes by a photolithography method.

The conductive film can be formed by any of a sputtering method, a chemical vapor deposition (CVD) method, a molecular beam epitaxy (MBE) method, a vacuum evaporation method, a pulsed laser deposition (PLD) method, an atomic layer deposition (ALD) method, and the like. Examples of the CVD method include a plasma-enhanced chemical vapor deposition (PECVD) method and a thermal CVD method. An example of a thermal CVD method is a metal organic CVD (MOCVD) method.

The conductive film may be processed by a nanoimprinting method, a sandblasting method, a lift-off method, or the like as well as a photolithography method described above. Alternatively, island-shaped thin films may be directly formed by a deposition method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development. The former method involves heat treatment steps such as pre-applied bake (PAB) after resist application and post-exposure bake (PEB) after light exposure. In one embodiment of the present invention, a lithography method is used not only for processing of a conductive film but also for processing of a thin film used for an EL layer (a film made of an organic compound or a film partly including an organic compound).

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. It is preferable to use EUV, X-rays, or an electron beam because extremely minute processing can be performed. Note that a photomask is not needed when light exposure is performed by scanning with a beam such as an electron beam.

For etching of a thin film using a resist mask, a dry etching method, a wet etching method, a sandblast method, or the like can be used.

Subsequently, as illustrated in FIG. 4B, the hole-injection/transport layer 104B, the light-emitting layer 105B, and the electron-transport layer 108B are formed over the electrode 551B, the electrode 551G, the electrode 551R, and the electrode 551PS. Note that the hole-injection/transport layer 104B, the light-emitting layer 105B, and the electron-transport layer 108B can be formed using a vacuum evaporation method, for example. Furthermore, a sacrificial layer 1101B is formed over the electron-transport layer 108B. For the formation of the hole-injection/transport layer 104B, the light-emitting layer 105B, and the electron-transport layer 108B, any of the materials described in the foregoing embodiments can be used.

For the sacrificial layer 110B, it is preferable to use a film highly resistant to etching treatment performed on the hole-injection/transport layer 104B, the light-emitting layer 105B, and the electron-transport layer 108B, i.e., a film having high etching selectivity with respective to the hole-injection/transport layer 104B, the light-emitting layer 105B, and the electron-transport layer 108B. The sacrificial layer 1101B preferably has a stacked-layer structure of a first sacrificial layer and a second sacrificial layer which have different etching selectivities. For the sacrificial layer 1101B, it is possible to use a film that can be removed by a wet etching method, which causes less damage to the EL layer 103B. In wet etching, oxalic acid or the like can be used as an etching material. Note that in this specification and the like, a sacrificial layer may be called a mask layer.

For the sacrificial layer 1101B, an inorganic film such as a metal film, an alloy film, a metal oxide film, a semiconductor film, or an inorganic insulating film can be used, for example. The sacrificial layer 110B can be formed by any of a variety of deposition methods such as a sputtering method, an evaporation method, a CVD method, and an ALD method.

For the sacrificial layer 110B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

A metal oxide such as indium gallium zinc oxide (also referred to as In—Ga—Zn oxide or IGZO) can be used for the sacrificial layer 110B. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti-Zn oxide), indium gallium tin zinc oxide (In—Ga—Sn—Zn oxide), or the like. Alternatively, indium tin oxide containing silicon can also be used, for example.

An element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. In particular, M is preferably one or more of gallium, aluminum, and yttrium.

For the sacrificial layer 110B, an inorganic insulating material such as aluminum oxide, hafnium oxide, or silicon oxide can be used.

The sacrificial layer 1101B is preferably formed using a material that can be dissolved in a solvent chemically stable with respect to at least the electron-transport layer 108B that is in the uppermost position. Specifically, a material that can be dissolved in water or alcohol can be suitably used for the sacrificial layer 110B. In formation of the sacrificial layer 110B, it is preferable that application of such a material dissolved in a solvent such as water or alcohol be performed by a wet process and followed by heat treatment for evaporating the solvent. At this time, the heat treatment is preferably performed under a reduced-pressure atmosphere, in which case the solvent can be removed at a low temperature in a short time and thermal damage to the hole-injection/transport layer 104B, the light-emitting layer 105B, and the electron-transport layer 108B can be accordingly reduced.

In the case where the sacrificial layer 1101B having a stacked-layer structure is formed, the stacked-layer structure can include the first sacrificial layer formed using any of the above-described materials and the second sacrificial layer thereover.

The second sacrificial layer in that case is a film used as a hard mask for etching of the first sacrificial layer. In processing the second sacrificial layer, the first sacrificial layer is exposed. Thus, the combination of films having high etching selectivity therebetween is selected for the first sacrificial layer and the second sacrificial layer. Thus, a film that can be used for the second sacrificial layer can be selected in accordance with the etching conditions of the first sacrificial layer and those of the second sacrificial layer.

For example, in the case where the second sacrificial layer is etched by dry etching involving a fluorine-containing gas (also referred to as a fluorine-based gas), the second sacrificial layer can be formed using silicon, silicon nitride, silicon oxide, tungsten, titanium, molybdenum, tantalum, tantalum nitride, an alloy containing molybdenum and niobium, an alloy containing molybdenum and tungsten, or the like. Here, a film of a metal oxide such as IGZO or ITO can be given as an example of a film having a high etching selectivity to the second sacrificial layer (i.e., a film with a low etching rate) in the dry etching involving the fluorine-based gas, and can be used for the first sacrificial layer.

Note that the material for the second sacrificial layer is not limited to the above and can be selected from a variety of materials in accordance with the etching conditions of the first sacrificial layer and those of the second sacrificial layer. For example, any of the films that can be used for the first sacrificial layer can be used for the second sacrificial layer.

For the second sacrificial layer, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

Alternatively, an oxide film can be used for the second sacrificial layer. Typically, it is possible to use a film of an oxide or an oxynitride such as silicon oxide, silicon oxynitride, aluminum oxide, aluminum oxynitride, hafnium oxide, or hafnium oxynitride.

Next, as illustrated in FIG. 4C, a resist is applied onto the sacrificial layer 110B, and the resist having a desired shape (a resist mask RES) is formed by a photolithography method. Such a method involves heat treatment steps such as pre-applied bake (PAB) after the resist application and post-exposure bake (PEB) after light exposure. The temperature reaches approximately 100° C. during the PAB, and approximately 120° C. during the PEB, for example. Therefore, the light-emitting device should be resistant to such high treatment temperatures.

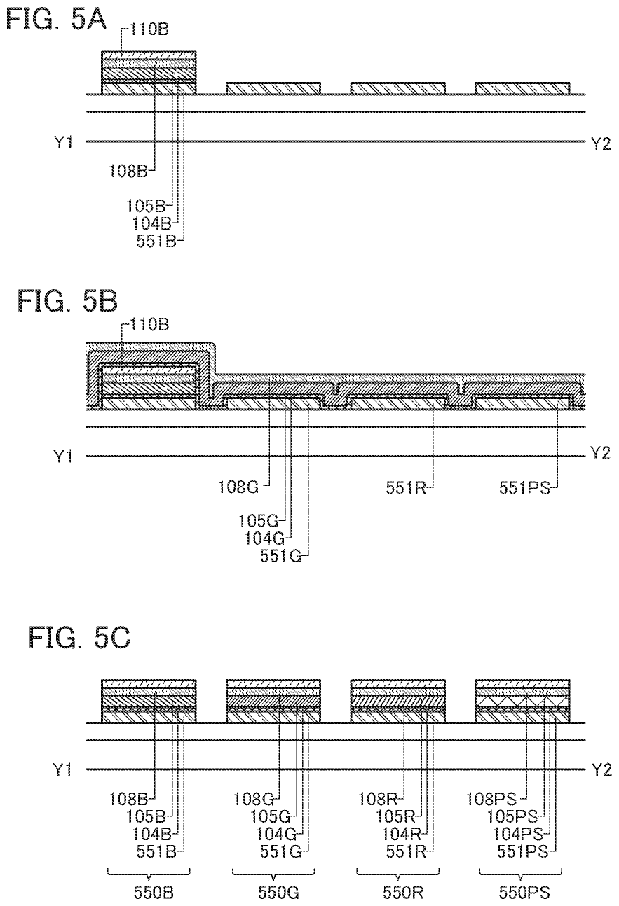

Next, part of the sacrificial layer 1101B that is not covered with the resist mask RES is removed by etching using the resist mask RES, the resist mask RES is removed, and then the hole-injection/transport layer 104B, the light-emitting layer 105B, and the electron-transport layer 108B that are not covered with the sacrificial layer 110B are removed by etching, so that the hole-injection/transport layer 104B, the light-emitting layer 105B, and the electron-transport layer 108B are processed to have side surfaces (or have their side surfaces exposed) over the electrode 551B or have belt-like shapes extending in the direction intersecting the sheet of the diagram. Note that dry etching is preferably employed for the etching. Note that in the case where the sacrificial layer 110B has the aforementioned stacked-layer structure of the first sacrificial layer and the second sacrificial layer, the hole-injection/transport layer 104B, the light-emitting layer 105B, and the electron-transport layer 108B may be processed into a predetermined shape in the following manner: part of the second sacrificial layer is etched with use of the resist mask RES, the resist mask RES is then removed, and part of the first sacrificial layer is etched using the second sacrificial layer as a mask. The structure illustrated in FIG. 5A is obtained through these etching steps.

Subsequently, as illustrated in FIG. 5B, the hole-injection/transport layer 104G, the light-emitting layer 105G, and the electron-transport layer 108G are formed over the sacrificial layer 110B, the electrode 551G, the electrode 551R, and the electrode 551PS. The hole-injection/transport layer 104G, the light-emitting layer 105G, and the electron-transport layer 108G can be formed using any of the materials described in the foregoing embodiments. Note that the hole-injection/transport layer 104G, the light-emitting layer 105G, and the electron-transport layer 108G can be formed by a vacuum evaporation method, for example.

Hereinafter, in a manner similar to formation of the hole-injection/transport layer 104B, the light-emitting layer 105B, the electron-transport layer 108B, and the sacrificial layer 1101B, the hole-injection/transport layer 104G, the light-emitting layer 105G, the electron-transport layer 108G, and a sacrificial layer 110G are formed over the electrode 551G; the hole-injection/transport layer 104R, the light-emitting layer 105R, the electron-transport layer 108R, and a sacrificial layer 110R are formed over the electrode 551R; and the hole-injection/transport layer 104PS, the active layer 105PS, the electron-transport layer 108PS, and a sacrificial layer 110PS are formed over the electrode 551PS, whereby the shape illustrated in FIG. 5C is obtained.

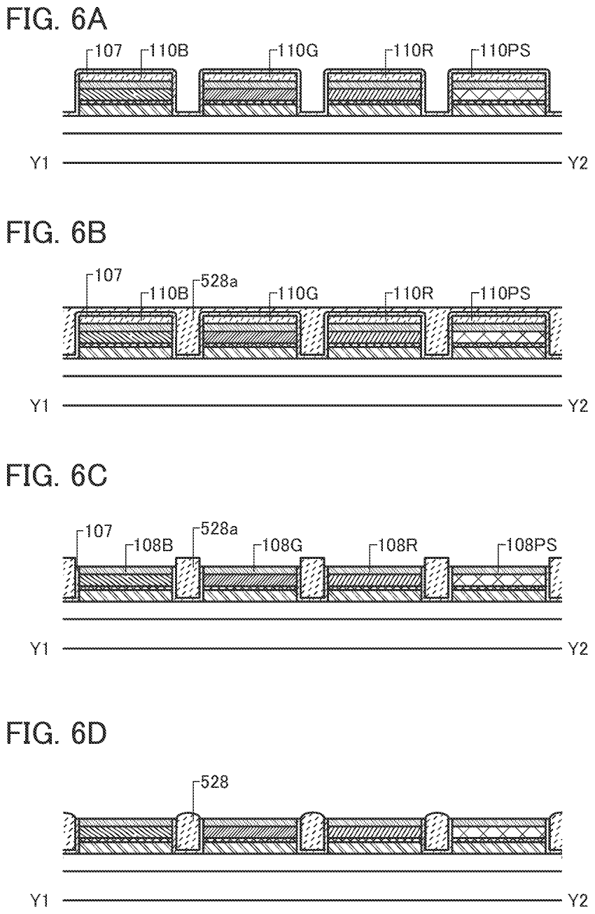

Next, as illustrated in FIG. 6A, the insulating layer 107 is formed over the sacrificial layers 110B, 110G, 110R, and 110PS.

Note that the insulating layer 107 can be formed by an ALD method, for example. In this case, as illustrated in FIG. 6A, the insulating layer 107 is formed to be in contact with the side surfaces (end portions) of the hole-injection/transport layers (104B, 104G, 104R, and 104PS), the light-emitting layers (105B, 105G, and 105R), the active layer 105PS, and the electron-transport layers (108B, 108G, 108R, and 108PS) of the devices. This can inhibit entry of oxygen, moisture, or constituent elements thereof into the inside through the side surfaces of the layers.

Next, as illustrated in FIG. 6B, a resin film 528a is formed over the insulating layer 107. As the resin film 528a, for example, a negative photosensitive resin or a positive photosensitive resin can be used.

Then, as illustrated in FIG. 6C, part of the resin film 528a, part of the insulating layer 107, and the sacrificial layers (110B, 110G, 110R, and HOPS) are removed to expose the top surfaces of the electron-transport layers (108B, 108G, 108R, and 108PS).

Next, heat treatment is performed to process an upper edge portion of the resin film 528a into a curved shape, so that the partition 528 is formed, as illustrated in FIG. 6D. When the upper edge portion of the partition 528 has a curved shape, the coverage with the electron-injection layer 109 to be formed later can be favorable. For example, in the case of using a positive photosensitive acrylic resin for the resin film 528a, the partition 528 is preferably formed so as to have a curved surface with a curvature radius (0.2 μm to 3 μm) at the upper edge portion.

Next, the electron-injection layer 109 is formed over the insulating layer 107, the electron-transport layers (108B, 108G, 108R, and 108PS), and the partition 528. The electron-injection layer 109 can be formed using any of the materials described in the foregoing embodiment. The electron-injection layer 109 is formed by a vacuum evaporation method, for example.

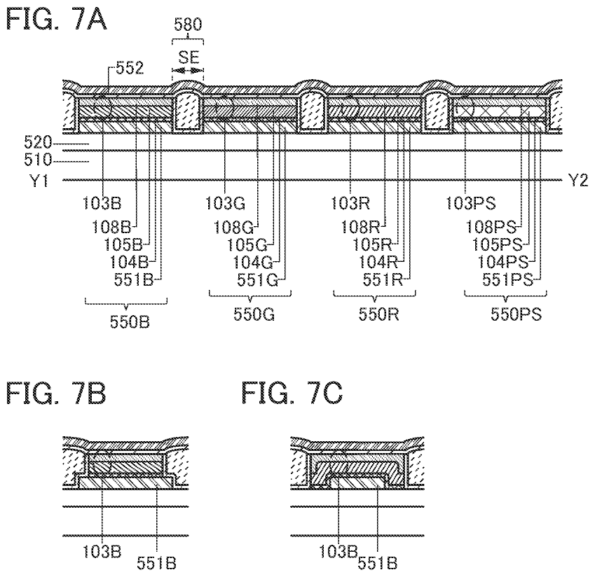

Next, as illustrated in FIG. 7A, the electrode 552 is formed over the electron-injection layer 109. The electrode 552 is formed by a vacuum evaporation method, for example.

Through the above steps, the EL layer 103B, the EL layer 103G, the EL layer 103R, and the light-receiving layer 103PS in the light-emitting device 550B, the light-emitting device 550G, the light-emitting device 550R, and the light-receiving device 550PS can be processed to be separated from each other.

Note that pattern formation by a photolithography method is performed in separate processing of the EL layer 103 and the light-receiving layer 103PS, so that a high-resolution light-emitting and light-receiving apparatus (display panel) can be fabricated. End portions (side surfaces) of the layers of the EL layer and the light-receiving layer processed by patterning using a photolithography method have substantially one surface (or are positioned on substantially the same plane). The pattern formation using a photolithography method can reduce crosstalk between adjacent light-emitting devices and between the light-emitting device and the light-receiving device. In addition, the space 580 is provided between adjacent devices processed by patterning using a photolithography method. In FIG. 7C, when the space 580 is denoted by a distance SE between the EL layers of adjacent light-emitting devices, decreasing the distance SE can increase the aperture ratio and the resolution. By contrast, as the distance SE is increased, the effect of the difference in the fabrication process between the adjacent light-emitting devices becomes permissible, which leads to an increase in manufacturing yield. Since the light-emitting device fabricated according to this specification is suitable for a miniaturization process, the distance SE between the EL layers of adjacent light-emitting devices can be longer than or equal to 0.5 μm and shorter than or equal to 5 μm, preferably longer than or equal to 1 μm and shorter than or equal to 3 μm, further preferably longer than or equal to 1 μm and shorter than or equal to 2.5 μm, and still further preferably longer than or equal to 1 μm and shorter than or equal to 2 μm. Typically, the distance SE is preferably longer than or equal to 1 μm and shorter than or equal to 2 μm (e.g., 1.5 μm or a neighborhood thereof).

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure. Since a light-emitting and light-receiving apparatus having the MML structure is formed without using a metal mask, the pixel arrangement, the pixel shape, and the like can be designed more flexibly than in a light-emitting and light-receiving apparatus having the FMM structure or the MM structure.

Note that the island-shaped EL layers of the light-emitting and light-receiving apparatus having the MML structure are formed by not patterning using a metal mask but processing after formation of an EL layer. Thus, a light-emitting and light-receiving apparatus with a higher resolution or a higher aperture ratio than a conventional one can be achieved. Moreover, EL layers can be formed separately for each color, which enables extremely clear images; thus, a light-emitting and light-receiving apparatus with a high contrast and high display quality can be achieved. Furthermore, provision of a sacrifice layer over an EL layer can reduce damage on the EL layer during the fabrication process and increase the reliability of the light-emitting device.

In FIG. 3A and FIG. 7A, the width of the EL layer 103 is substantially equal to that of the electrode 551 in the light-emitting device 550, and the width of the light-receiving layer 103PS is substantially equal to that of the electrode 551PS in the light-receiving device 550PS; however, one embodiment of the present invention is not limited thereto.

In the light-emitting device 550, the width of the EL layer 103 may be smaller than that of the electrode 551. In the light-receiving device 550PS, the width of the light-receiving layer 103PS may be smaller than that of the electrode 551PS. FIG. 7B illustrates an example where the width of the EL layer 103B is smaller than that of the electrode 551B in the light-emitting device 550B.

In the light-emitting device 550, the width of the light-emitting layer 103 may be larger than that of the electrode 551. In the light-receiving device 550PS, the width of the light-receiving layer 103PS may be larger than that of the electrode 551PS. FIG. 7C illustrates an example where the width of the EL layer 103R is larger than that of the electrode 551R in the light-emitting device 550R.

The structures described in this embodiment can be used in combination with any of the structures described in the other embodiments as appropriate.

### Embodiment 4

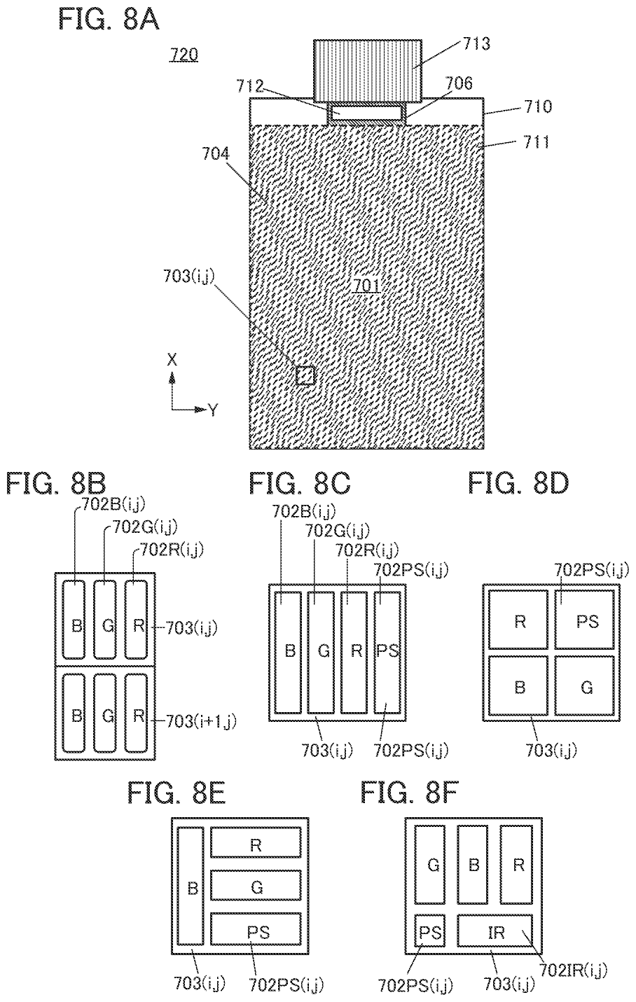

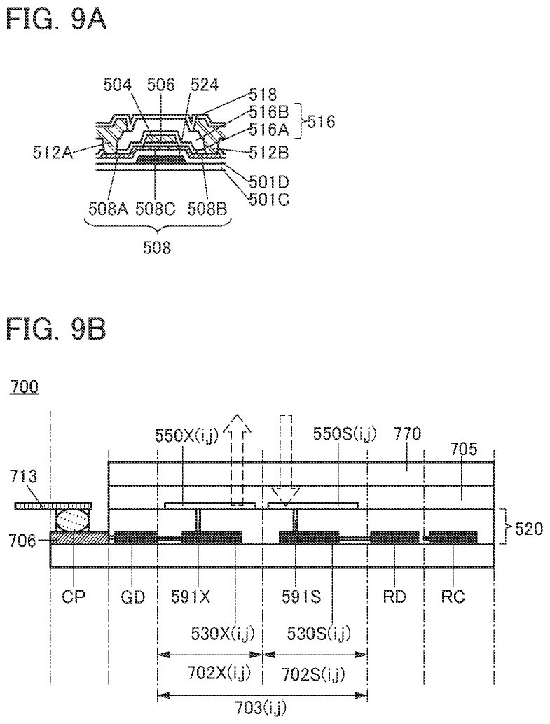

In this embodiment, an apparatus 720 and a light-emitting and light-receiving apparatus 700 are described with reference to FIGS. 8A to 8F and FIGS. 9A and 9B. The apparatuses illustrated in FIGS. 8A to 8F and FIGS. 9A and 9B are each a light-emitting apparatus including a light-emitting device. Furthermore, the apparatuses can each be a display panel or a display apparatus that can be used in a display portion of an electronic device or the like. Moreover, when the apparatuses include the light-emitting device as a light source and a light-receiving device that can receive light from the light-emitting device, the apparatuses can be referred to as a light-emitting and light-receiving apparatus. Note that the light-emitting apparatus, the display panel, the display apparatus, and the light-emitting and light-receiving apparatus each include at least a light-emitting device.

Furthermore, the light-emitting apparatus, the display panel, the display apparatus, and the light-emitting and light-receiving apparatus of this embodiment can each have high definition or a large size. Therefore, the light-emitting apparatus, the display panel, the display apparatus, and the light-emitting and light-receiving apparatus of this embodiment can be used, for example, in display portions of electronic devices such as a digital camera, a digital video camera, a digital photo frame, a mobile phone, a portable game console, a smart phone, a wristwatch terminal, a tablet terminal, a portable information terminal, and an audio reproducing apparatus, in addition to display portions of electronic devices with a relatively large screen, such as a television device, a desktop or laptop personal computer, a monitor of a computer or the like, digital signage, and a large game machine such as a pachinko machine.

FIG. 8A is a top view of the apparatus 720.

In FIG. 8A, the apparatus 720 has a structure in which a substrate 710 and a substrate 711 are attached to each other. In addition, the apparatus 720 includes a display region 701, a circuit 704, a wiring 706, and the like. Note that the display region 701 includes a plurality of pixels. As illustrated in FIG. 8B, a pixel 703(i,j) illustrated in FIG. 8A and a pixel 703(i+1, j) are adjacent to each other.

Furthermore, in the example of the apparatus 720 illustrated in FIG. 8A, the substrate 710 is provided with an integrated circuit (IC) 712 by a chip on glass (COG) method, a chip on film (COF) method, or the like. As the IC 712, an IC including a scan line driver circuit, a signal line driver circuit, or the like can be used, for example. In the structure illustrated in FIG. 8A, an IC including a signal line driver circuit is used as the IC 712, and a scan line driver circuit is used as the circuit 704.

The wiring 706 has a function of supplying signals and power to the display region 701 and the circuit 704. The signals and power are input to the wiring 706 from the outside through a flexible printed circuit (FPC) 713 or to the wiring 706 from the IC 712. Note that the apparatus 720 is not necessarily provided with the IC. The IC may be mounted on the FPC by a COF method or the like.

FIG. 8B illustrates the pixel 703(i,j) and the pixel 703(i+1, j) of the display region 701. A plurality of kinds of subpixels including light-emitting devices that emit light of different colors can be included in the pixel 703(i,j). Alternatively, a plurality of subpixels including light-emitting devices that emit light of the same color may be included in addition to the above-described subpixels. For example, three kinds of subpixels can be included. The three subpixels can be of three colors of red (R), green (G), and blue (B) or of three colors of yellow (Y), cyan (C), and magenta (M), for example. Alternatively, the pixel can include four kinds of subpixels. The four subpixels can be of four colors of R, G, B, and white (W) or of four colors of R, G, B, and Y, for example. Specifically, the pixel 703(i,j) can include a subpixel 702B(i,j) for blue display, a subpixel 702G(i,j) for green display, and a subpixel 702R(i,j) for red display.

Other than the subpixels including the light-emitting devices, a subpixel including a light-receiving device may also be provided. In the case where the subpixel includes a light-receiving device, the apparatus 720 is also referred to as a light-emitting and light-receiving apparatus.

FIGS. 8C to 8F illustrate various layout examples of the pixel 703(i,j) including a subpixel 702PS(i,j) including alight-receiving device. The pixel arrangement in FIG. 8C is stripe arrangement, and the pixel arrangement in FIG. 8D is matrix arrangement. The pixel arrangement in FIG. 8E has a structure where three subpixels (the subpixels R, G, and PS) are vertically arranged next to one subpixel (the subpixel B).

Furthermore, as illustrated in FIG. 8F, a subpixel 702IR(i,j) that emits infrared rays may be added to any of the above-described sets of subpixels in the pixel 703(i,j). In the pixel arrangement in FIG. 8F, three vertically-long subpixels G, B, and R are arranged laterally, and the subpixel PS and a horizontally-long subpixel IR are arranged laterally below the three subpixels. Specifically, the subpixel 702IR(i,j) that emits light including light with a wavelength ranging from 650 nm to 1000 nm, inclusive, may be used in the pixel 703(i,j). Note that the wavelength of light detected by the subpixel 702PS(i,j) is not particularly limited; however, the light-receiving device included in the subpixel 702PS(i,j) preferably has sensitivity to light emitted from the light-emitting device included in the subpixel 702R(i,j), the subpixel 702G(i,j), the subpixel 702B(i,j), or the subpixel 702IR(i,j). For example, the light-receiving device preferably detects one or more kinds of light in blue, violet, bluish violet, green, yellowish green, yellow, orange, red, and infrared wavelength ranges, for example.

Note that the arrangement of subpixels is not limited to the structures illustrated in FIGS. 8B to 8F and a variety of arrangement methods can be employed. The arrangement of subpixels may be stripe arrangement, S stripe arrangement, matrix arrangement, delta arrangement, Bayer arrangement, or PenTile arrangement, for example.

Furthermore, top surfaces of the subpixels may have a triangular shape, a quadrangular shape (including a rectangular shape and a square shape), a polygonal shape such as a pentagonal shape, a polygonal shape with rounded corners, an elliptical shape, or a circular shape, for example. The top surface shape of a subpixel herein refers to a top surface shape of a light-emitting region of a light-emitting device.

In the case where not only a light-emitting device but also a light-receiving device is included in a pixel, the pixel has a light-receiving function and thus can detect a contact or approach of an object while displaying an image. For example, an image can be displayed by using all the subpixels included in a light-emitting apparatus, or light can be emitted by some of the subpixels as a light source and an image can be displayed by using the remaining subpixels.

Note that the light-receiving area of the subpixel 702PS(i,j) is preferably smaller than the light-emitting areas of the other subpixels. A smaller light-receiving area leads to a narrower image-capturing range, suppresses a blur in a captured image, and improves the definition. Thus, by using the subpixel 702PS(i,j), high-resolution or high-definition image capturing is possible. For example, image capturing for personal authentication with the use of a fingerprint, a palm print, the iris, the shape of a blood vessel (including the shape of a vein and the shape of an artery), a face, or the like is possible by using the subpixel 702PS(i,j).

Moreover, the subpixel 702PS(i,j) can be used in a touch sensor (also referred to as a direct touch sensor), a near touch sensor (also referred to as a hover sensor, a hover touch sensor, a contactless sensor, or a touchless sensor), or the like. For example, the subpixel 702PS(i,j) preferably detects infrared light. Thus, touch sensing is possible even in a dark place.

Here, the touch sensor or the near touch sensor can detect an approach or contact of an object (e.g., a finger, a hand, or a pen). The touch sensor can detect the object when the light-emitting and light-receiving apparatus and the object come in direct contact with each other. Furthermore, the near touch sensor can detect the object even when the object is not in contact with the light-emitting and light-receiving apparatus. For example, the light-emitting and light-receiving apparatus can preferably detect the object when the distance between the light-emitting and light-receiving apparatus and the object is more than or equal to 0.1 mm and less than or equal to 300 mm, preferably more than or equal to 3 mm and less than or equal to 50 mm. With this structure, the light-emitting and light-receiving apparatus can be controlled without the object directly contacting with the light-emitting and light-receiving apparatus. In other words, the light-emitting and light-receiving apparatus can be controlled in a contactless (touchless) manner. With the above-described structure, the light-emitting and light-receiving apparatus can be controlled with a reduced risk of being dirty or damaged, or without direct contact between the object and a dirt (e.g., dust, bacteria, or a virus) attached to the light-emitting and light-receiving apparatus.

In the case where the subpixel 702PS(i,j) is used for high-resolution image capturing, the subpixel 702PS(i,j) is preferably provided in every pixel. Meanwhile, in the case where the subpixel 702PS(i,j) is used in a touch sensor, a near touch sensor, or the like, high accuracy is not required as compared to the case of capturing an image of a fingerprint or the like; accordingly, the subpixel 702PS(i,j) can be provided in some subpixels. When the number of subpixels 702PS(i,j) is smaller than the number of subpixels 702R(i,j) or the like, higher detection speed can be achieved.

FIG. 9A illustrates an example of a specific structure of a transistor that can be used in the pixel circuit of the subpixel including the light-emitting device. As the transistor, a bottom-gate transistor, a top-gate transistor, or the like can be used as appropriate.

The transistor illustrated in FIG. 9A includes a semiconductor film 508, a conductive film 504, an insulating film 506, a conductive film 512A, and a conductive film 512B. The transistor is formed over an insulating film 501C, for example. The transistor also includes an insulating film 516 (an insulating film 516A and an insulating film 516B) and an insulating film 518.

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C and has a function of a gate electrode.

The insulating film 506 includes a region interposed between the semiconductor film 508 and the conductive film 504. The insulating film 506 has a function of a first gate insulating film.

The conductive film 512A has one of a function of a source electrode and a function of a drain electrode, and the conductive film 512B has the other thereof.

A conductive film 524 can be used in the transistor. The semiconductor film 508 is interposed between the conductive film 504 and a region included in the conductive film 524. The conductive film 524 has a function of a second gate electrode. An insulating film 501D is interposed between the semiconductor film 508 and the conductive film 524 and has a function of a second gate insulating film.

The insulating film 516 functions as, for example, a protective film covering the semiconductor film 508. Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 516, for example.

For the insulating film 518, a material that has a function of inhibiting diffusion of oxygen, hydrogen, water, an alkali metal, an alkaline earth metal, and the like is preferably used. Specifically, the insulating film 518 can be formed using silicon nitride, silicon oxynitride, aluminum nitride, or aluminum oxynitride, for example. In each of silicon oxynitride and aluminum oxynitride, the number of nitrogen atoms contained is preferably larger than the number of oxygen atoms contained.

Note that in a step of forming the semiconductor film used in the transistor of the pixel circuit, the semiconductor film used in the transistor of the driver circuit can be formed. A semiconductor film having the same composition as the semiconductor film used in the transistor of the pixel circuit can be used in the driver circuit, for example.

The semiconductor film 508 preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

In particular, an oxide containing In, Ga, and Zn (also referred to as IGZO) is preferably used as the semiconductor film 508. Alternatively, it is preferable to use an oxide containing In, Sn, and Zn. Further alternatively, it is preferable to use an oxide containing In, Ga, Sn, and Zn. Further alternatively, it is preferable to use an oxide containing In, Al, and Zn (also referred to as IAZO). Further alternatively, it is preferable to use an oxide containing In, Al, Ga, and Zn (also referred to as IAGZO).

When the semiconductor film is an In-M-Zn oxide, the atomic proportion of In is preferably greater than or equal to the atomic proportion of M in the In-M-Zn oxide. Examples of the atomic ratio of the metal elements in such an In-M-Zn oxide are In:M:Zn=1:1:1, 1:1:1.2, 1:3:2, 1:3:4, 2:13, 3:1:2, 4:23, 4:2:4.1, 5:13, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the vicinity thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the vicinity thereof, the case is included where the atomic proportion of Ga is greater than 0.1 and less than or equal to 2 and the atomic proportion of Zn is greater than 0.1 and less than or equal to 2 with the atomic proportion of In being 1.

There is no particular limitation on the crystallinity of a semiconductor material used in the transistor, and an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be reduced.

In the case of using a metal oxide for the semiconductor film 508, a light-emitting apparatus including the transistor illustrated in FIG. 9A includes a light-emitting device including a metal oxide in its semiconductor film and having a metal maskless (MML) structure. With this structure, the leakage current that might flow through the transistor and the leakage current that might flow between adjacent light-emitting devices (also referred to as a lateral leakage current, a side leakage current, or the like) can be extremely low. With the structure, a viewer can observe any one or more of the image crispness, the image sharpness, a high chroma, and a high contrast ratio in an image displayed on the display apparatus. Owing to a structure in which the leakage current that might flow through the transistor and the lateral leakage current that might flow between light-emitting devices are extremely low, it is possible to perform display in which light leakage at black display (black-level degradation) or the like can be minimized (such display is also referred to as completely black display).

Alternatively, silicon may be used for the semiconductor film 508. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors using silicon such as LTPS transistors, a circuit required to be driven at a high frequency (e.g., a source driver circuit) can be formed on the same substrate as the display portion. This allows simplification of an external circuit mounted on the light-emitting apparatus and a reduction in component costs and component-mounting costs.

The structure of the transistors used in the display panel may be selected as appropriate depending on the size of the screen of the display panel. For example, single crystal S₁ transistors can be used in the display panel with a screen diagonal greater than or equal to 0.1 inches and less than or equal to 3 inches. In addition, LTPS transistors can be used in the display panel with a screen diagonal greater than or equal to 0.1 inches and less than or equal to 30 inches, preferably greater than or equal to 1 inch and less than or equal to 30 inches. In addition, an LTPO structure (where an LTPS transistor and an OS transistor are used in combination) can be used in the display panel with a screen diagonal greater than or equal to 0.1 inches and less than or equal to 50 inches, preferably greater than or equal to 1 inch and less than or equal to 50 inches. In addition, OS transistors (transistors including a metal oxide in a semiconductor where a channel is formed) can be used in the display panel with a screen diagonal greater than or equal to 0.1 inches and less than or equal to 200 inches, preferably greater than or equal to 50 inches and less than or equal to 100 inches.

With the use of single crystal Si transistors, an increase in screen size is extremely difficult due to the size of a single crystal Si substrate. Furthermore, since a laser crystallization apparatus is used in the fabrication process, LTPS transistors are unlikely to respond to an increase in screen size (typically to a screen diagonal greater than 30 inches). By contrast, since the fabrication process does not necessarily require a laser crystallization apparatus or the like or can be performed at a relatively low temperature (typically, lower than or equal to 450° C.), OS transistors can be applied to a display panel with a relatively large area (typically, a screen diagonal greater than or equal to 50 inches and less than or equal to 100 inches). In addition, LTPO can be applied to a display panel with a size (typically, a screen diagonal greater than or equal to 1 inch and less than or equal to 50 inches) between the size of a display panel using LTPS transistors and the size of a display panel using OS transistors.

Next, a cross-sectional view of a light-emitting and light-receiving apparatus is illustrated. FIG. 9B is a cross-sectional view of the light-emitting and light-receiving apparatus illustrated in FIG. 8A.

FIG. 9B is a cross-sectional view of part of a region including the FPC 713 and the wiring 706 and part of the display region 701 including the pixel 703(i,j).

In FIG. 9B, the light-emitting and light-receiving apparatus 700 includes the functional layer 520 between the first substrate 510 and the second substrate 770. The functional layer 520 includes, as well as the above-described transistors, the capacitors, and the like, wirings electrically connected to these components, for example. Although the functional layer 520 includes a pixel circuit 530X(i,j), a pixel circuit 530S(i,j), and a circuit GD in FIG. 9B, one embodiment of the present invention is not limited thereto.

Furthermore, each pixel circuit (e.g., the pixel circuit 530X(i,j) and the pixel circuit 530S(i,j) in FIG. 9B) included in the functional layer 520 is electrically connected to alight-emitting device and a light-receiving device (e.g., a light-emitting device 550X(i, j) and a light-receiving device 550S(i,j) in FIG. 9B) formed over the functional layer 520. Specifically, the light-emitting device 550X(i,j) is electrically connected to the pixel circuit 530X(i,j) through a wiring 591X, and the light-receiving device 550S(i,j) is electrically connected to the pixel circuit 530S(i,j) through a wiring 591S. The insulating layer 705 is provided over the functional layer 520, the light-emitting devices, and the light-receiving device, and has a function of attaching the second substrate 770 and the functional layer 520 to each other.

As the second substrate 770, a substrate where touch sensors are arranged in a matrix can be used. For example, a substrate provided with capacitive touch sensors or optical touch sensors can be used as the second substrate 770. Thus, the light-emitting and light-receiving apparatus of one embodiment of the present invention can be used as a touch panel.

The structures described in this embodiment can be used in appropriate combination with any of the structures described in the other embodiments.

### Embodiment 5

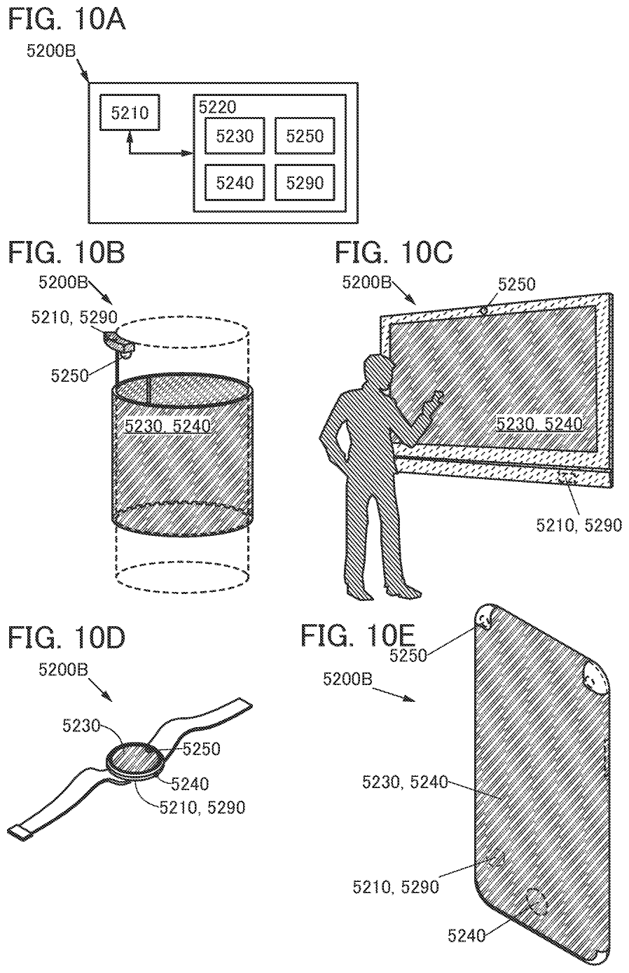

This embodiment will describe structures of electronic devices of embodiments of the present invention with reference to FIGS. 10A to 10E, FIGS. 11A to 11E, and FIGS. 12A and 12B.

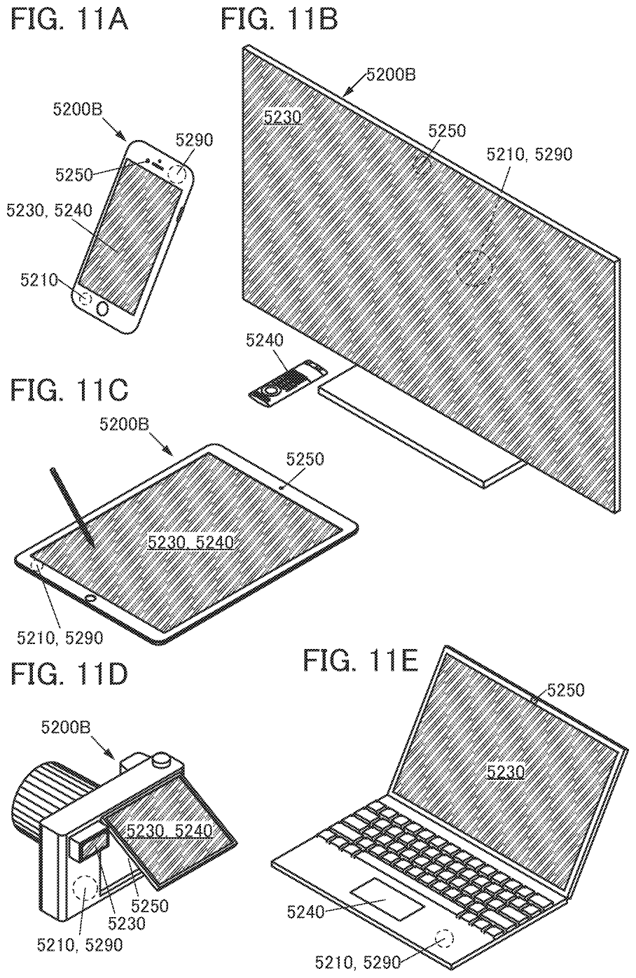

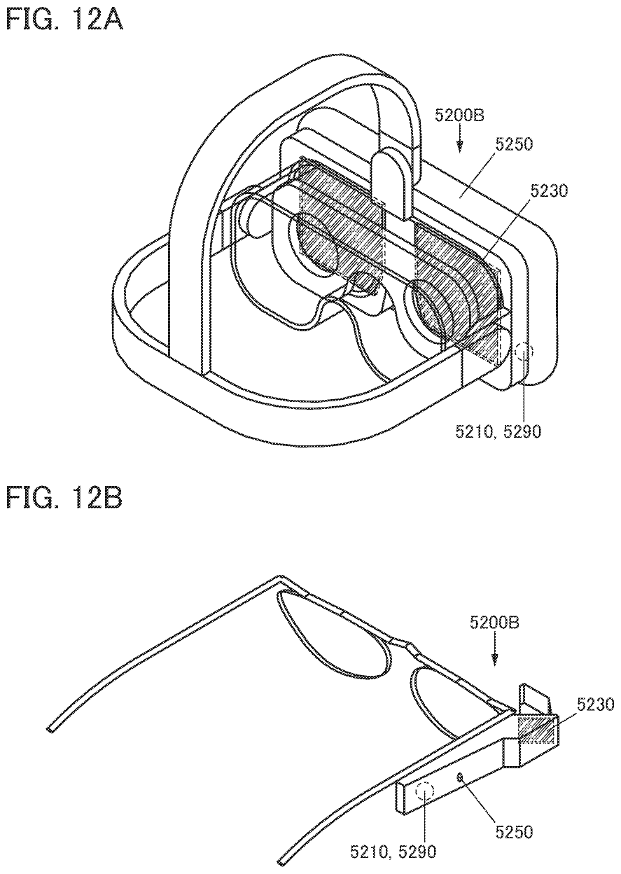

FIGS. 10A to 10E, FIGS. 11A to 11E, and FIGS. 12A and 12B each illustrate a structure of an electronic device of one embodiment of the present invention. FIG. 10A is a block diagram of an electronic device, and FIGS. 10B to 10E are perspective views illustrating structures of the electronic device. FIGS. 11A to 11E are perspective views illustrating structures of electronic devices. FIGS. 12A and 12B are perspective views illustrating structures of electronic devices.

An electronic device 5200B described in this embodiment includes an arithmetic device 5210 and an input/output device 5220 (see FIG. 10A).

The arithmetic device 5210 has a function of receiving handling data and a function of supplying image data on the basis of the handling data.

The input/output device 5220 includes a display portion 5230, an input portion 5240, a sensor portion 5250, and a communication portion 5290, and has a function of supplying handling data and a function of receiving image data. The input/output device 5220 also has a function of supplying sensing data, a function of supplying communication data, and a function of receiving communication data.

The input portion 5240 has a function of supplying handling data. For example, the input portion 5240 supplies handling data on the basis of handling by a user of the electronic device 5200B.

Specifically, a keyboard, a hardware button, a pointing device, a touch sensor, an illuminance sensor, an imaging device, an audio input device, an eye-gaze input device, an attitude sensing device, or the like can be used as the input portion 5240.

The display portion 5230 includes a display panel and has a function of displaying image data. For example, the display panel described in the foregoing embodiment can be used for the display portion 5230.

The sensor portion 5250 has a function of supplying sensing data. For example, the sensor portion 5250 has a function of sensing a surrounding environment where the electronic device is used and supplying the sensing data.

Specifically, an illuminance sensor, an imaging device, an attitude sensing device, a pressure sensor, a human motion sensor, or the like can be used as the sensor portion 5250.

The communication portion 5290 has a function of receiving and supplying communication data. For example, the communication portion 5290 has a function of being connected to another electronic device or a communication network by wireless communication or wired communication. Specifically, the communication portion 5290 has a function of wireless local area network communication, telephone communication, near field communication, or the like.

FIG. 10B illustrates an electronic device having an outer shape along a cylindrical column or the like. An example of such an electronic device is digital signage. The display panel of one embodiment of the present invention can be used for the display portion 5230. The electronic device may have a function of changing its display method in accordance with the illuminance of a usage environment. The electronic device has a function of changing the displayed content when sensing the existence of a person. Thus, for example, the electronic device can be provided on a column of a building. The electronic device can display advertising, guidance, or the like.

FIG. 10C illustrates an electronic device having a function of generating image data on the basis of the path of a pointer used by the user. Examples of such an electronic device include an electronic blackboard, an electronic bulletin board, and digital signage. Specifically, a display panel with a diagonal size of 20 inches or longer, preferably 40 inches or longer, further preferably 55 inches or longer can be used. A plurality of display panels can be arranged and used as one display region. Alternatively, a plurality of display panels can be arranged and used as a multiscreen.

FIG. 10D illustrates an electronic device that is capable of receiving data from another device and displaying the data on the display portion 5230. An example of such an electronic device is a wearable electronic device. Specifically, the electronic device can display several options, and the user can choose some from the options and send a reply to the data transmitter. As another example, the electronic device has a function of changing its display method in accordance with the illuminance of a usage environment. Thus, for example, power consumption of the wearable electronic device can be reduced. As another example, the wearable electronic device can display an image so as to be suitably used even in an environment under strong external light, e.g., outdoors in fine weather.

FIG. TOE illustrates an electronic device including the display portion 5230 having a surface gently curved along a side surface of a housing. An example of such an electronic device is a mobile phone. The display portion 5230 includes a display panel that has a function of displaying images on the front surface, the side surfaces, the top surface, and the rear surface, for example. Thus, the mobile phone can display data on not only its front surface but also its side surfaces, top surface, and rear surface, for example.

FIG. 11A illustrates an electronic device that is capable of receiving data via the Internet and displaying the data on the display portion 5230. An example of such an electronic device is a smartphone. For example, the user can check a created message on the display portion 5230 and send the created message to another device. As another example, the electronic device has a function of changing its display method in accordance with the illuminance of a usage environment. Thus, power consumption of the smartphone can be reduced. As another example, the smartphone can display an image so as to be suitably used even in an environment under strong external light, e.g., outdoors in fine weather.

FIG. 11B illustrates an electronic device that can use a remote controller as the input portion 5240. An example of such an electronic device is a television system. For example, data received from a broadcast station or via the Internet can be displayed on the display portion 5230. The electronic device can take an image of the user with the sensor portion 5250 and transmit the image of the user. The electronic device can acquire a viewing history of the user and provide it to a cloud service. The electronic device can acquire recommendation data from a cloud service and display the data on the display portion 5230. A program or a moving image can be displayed on the basis of the recommendation data. As another example, the electronic device has a function of changing its display method in accordance with the illuminance of a usage environment. Accordingly, for example, the television system can display an image so as to be suitably used even under strong external light entering the room from the outside in fine weather.

FIG. 11C illustrates an electronic device that is capable of receiving an educational material via the Internet and displaying it on the display portion 5230. An example of such an electronic device is a tablet computer. The user can input an assignment with the input portion 5240 and send it via the Internet. The user can obtain a corrected assignment or the evaluation from a cloud service and have it displayed on the display portion 5230. The user can select a suitable educational material on the basis of the evaluation and have it displayed.

For example, an image signal can be received from another electronic device and displayed on the display portion 5230. When the electronic device is placed on a stand or the like, the display portion 5230 can be used as a sub-display. Thus, for example, the tablet computer can display an image so as to be suitably used even in an environment under strong external light, e.g., outdoors in fine weather.

FIG. 11D illustrates an electronic device including a plurality of display portions 5230. An example of such an electronic device is a digital camera. For example, the display portion 5230 can display an image that the sensor portion 5250 is capturing. A captured image can be displayed on the sensor portion. A captured image can be decorated using the input portion 5240. A message can be attached to a captured image. A captured image can be transmitted via the Internet. The electronic device has a function of changing shooting conditions in accordance with the illuminance of a usage environment. Accordingly, for example, the digital camera can display a subject such that an image is favorably viewed even in an environment under strong external light, e.g., outdoors in fine weather.

FIG. 11E illustrates an electronic device in which the electronic device of this embodiment is used as a master to control another electronic device used as a slave. An example of such an electronic device is a portable personal computer. For example, part of image data can be displayed on the display portion 5230 and another part of the image data can be displayed on a display portion of another electronic device. Image signals can be supplied. Data written from an input portion of another electronic device can be obtained with the communication portion 5290. Thus, a large display region can be utilized in the case of using a portable personal computer, for example.

FIG. 12A illustrates an electronic device including the sensor portion 5250 that senses an acceleration or a direction. An example of such an electronic device is a goggles-type electronic device. The sensor portion 5250 can supply data on the position of the user or the direction in which the user faces. The electronic device can generate image data for the right eye and image data for the left eye in accordance with the position of the user or the direction in which the user faces. The display portion 5230 includes a display region for the right eye and a display region for the left eye. Thus, a virtual reality image that gives the user a sense of immersion can be displayed on the goggles-type electronic device, for example.

FIG. 12B illustrates an electronic device including an imaging device and the sensor portion 5250 that senses an acceleration or a direction. An example of such an electronic device is a glasses-type electronic device. The sensor portion 5250 can supply data on the position of the user or the direction in which the user faces. The electronic device can generate image data in accordance with the position of the user or the direction in which the user faces. Accordingly, the data can be shown together with a real-world scene, for example. Alternatively, an augmented reality image can be displayed on the glasses-type electronic device.

Note that this embodiment can be combined with any of the other embodiments in this specification as appropriate.

### Embodiment 6

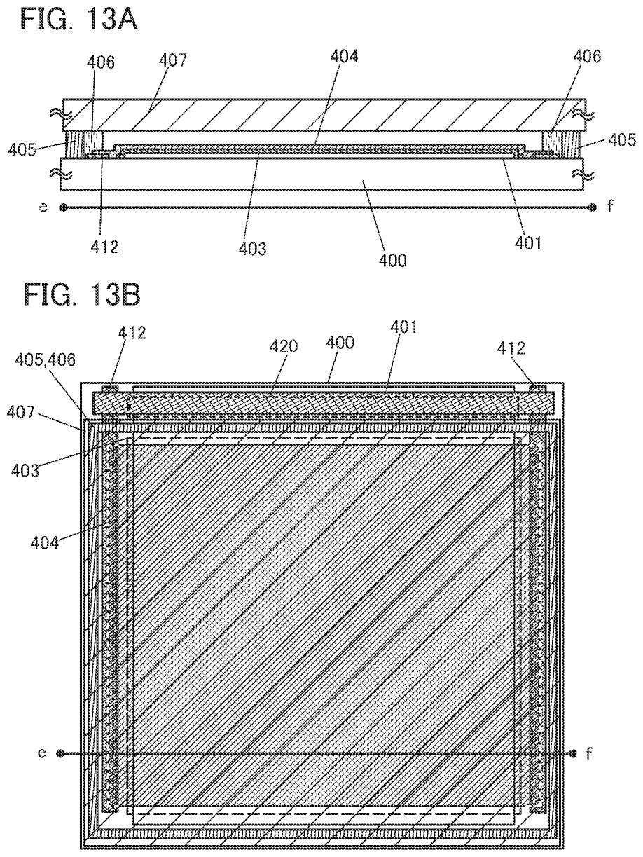

This embodiment will describe a structure in which any of the light-emitting devices described in the foregoing embodiment is used as a lighting device with reference to FIGS. 13A and 13B. FIG. 13A is a cross-sectional view taken along the line e-f in a top view of the lighting device in FIG. 13B.

In the lighting device in this embodiment, a first electrode 401 is formed over a substrate 400 that is a support and has a light-transmitting property. The first electrode 401 corresponds to the first electrode 101 in the foregoing embodiment. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to the structure of the EL layer 103 in the foregoing embodiment. Refer to the corresponding description for these structures.

The second electrode 404 is formed to cover the EL layer 403. The second electrode 404 corresponds to the second electrode 102 described in the foregoing embodiment. The second electrode 404 is formed using a material having high reflectance when light is extracted from the first electrode 401 side. The second electrode 404 is connected to the pad 412 so that voltage is supplied to the second electrode 404.

As described above, the lighting device described in this embodiment includes a light-emitting device including the first electrode 401, the EL layer 403, and the second electrode 404. Since the light-emitting device has high emission efficiency, the lighting device in this embodiment can have low power consumption.

The substrate 400 provided with the light-emitting device having the above structure and a sealing substrate 407 are fixed and sealed with sealing materials 405 and 406, whereby the lighting device is completed. It is possible to use only either the sealing material 405 or the sealing material 406. In addition, the inner sealing material 406 (not illustrated in FIG. 13B) can be mixed with a desiccant that enables moisture to be adsorbed, leading to an improvement in reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

### Embodiment 7

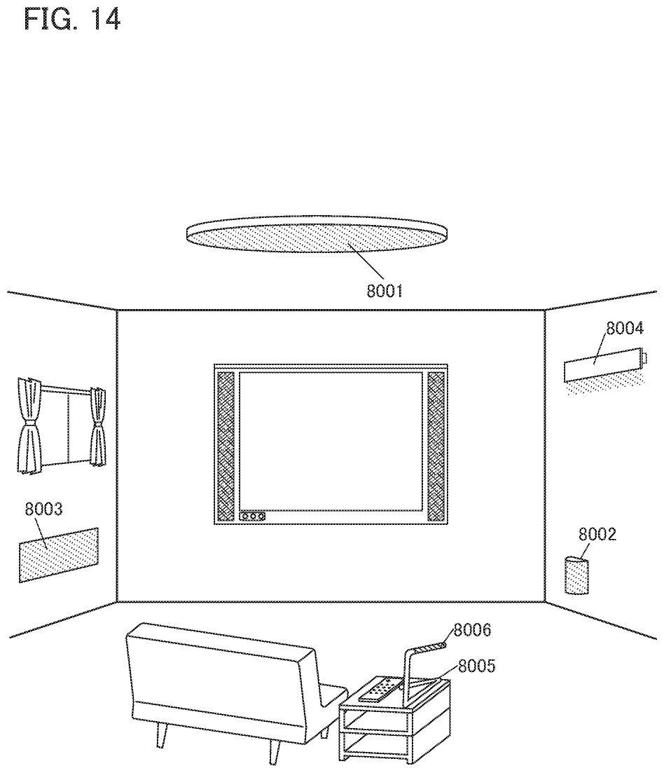

This embodiment will describe application examples of lighting devices fabricated using the light-emitting apparatus of one embodiment of the present invention or the light-emitting device, which is part of the light-emitting apparatus with reference to FIG. 14.

A ceiling light 8001 can be used as an indoor lighting device. Examples of the ceiling light 8001 include a direct-mount light and an embedded light. Such lighting devices are fabricated using the light-emitting apparatus in combination with a housing and a cover. Application to a cord pendant light (light that is suspended from a ceiling by a cord) is also possible.

Afoot light 8002 lights a floor so that safety on the floor can be improved. For example, it can be effectively used in a bedroom, on a staircase, and on a passage. In such cases, the size and shape of the foot light can be changed in accordance with the dimensions and structure of a room. The foot light can be a stationary lighting device using the light-emitting apparatus and a support in combination.

A sheet-like lighting 8003 is a thin sheet-like lighting device. The sheet-like lighting, which is attached to a wall when used, is space-saving and thus can be used for a wide variety of uses. Furthermore, the area of the sheet-like lighting can be easily increased. The sheet-like lighting can also be used on a wall or a housing that has a curved surface.

A lighting device 8004 in which the direction of light from a light source is controlled to be only a desired direction can be used.

A desk lamp 8005 includes a light source 8006. As the light source 8006, the light-emitting apparatus of one embodiment of the present invention or the light-emitting device, which is part of the light-emitting apparatus, can be used.

Besides the above examples, when the light-emitting apparatus of one embodiment of the present invention or the light-emitting device, which is part of the light-emitting apparatus, is used as part of furniture in a room, a lighting device having a function of the furniture can be obtained.

As described above, a variety of lighting devices that include the light-emitting apparatus can be obtained. Note that these lighting devices are also embodiments of the present invention.

The structures described in this embodiment can be used in appropriate combination with any of the structures described in the other embodiments.

### Example 1

In this example, light-emitting devices 1 to 3, which are light-emitting devices of embodiments of the present invention, and a comparative light-emitting device 4 were fabricated, and various kinds of measurements were performed in this example. The measurement results are described. As a first substance included in a light-emitting layer of each of the light-emitting devices 1 to 3, a NEST material, 2,5-bis(2,4-dimetylphenyl)-8-(2,2,2-trifluoroethoxy)-1,3,4,6,7,9,9b-heptaazaphenalene (abbreviation: HzTFEX₂) (Structural Formula (105)) was used. HzTFEX₂ was also used as a light-emitting substance included in a light-emitting layer of the comparative light-emitting device 4. HzTFEX₂ is a NEST material, and thus, the delayed fluorescence lifetime of HzTFEX₂ becomes shorter as the temperature decreases in the range of 10 K to 300 K, inclusive (see Non-Patent Document 2).

Structural formulas of organic compounds used for each of the light-emitting devices are shown below. The device structures of the light-emitting devices are shown below.

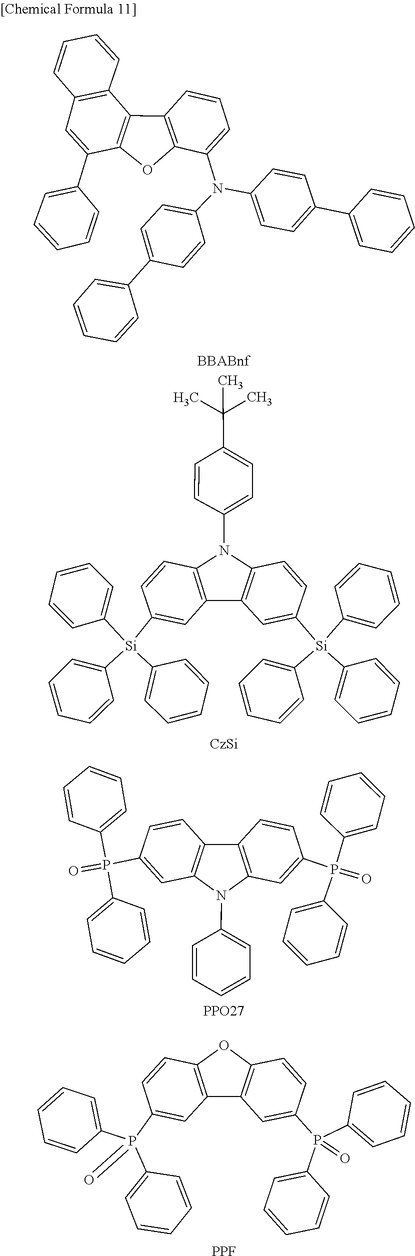

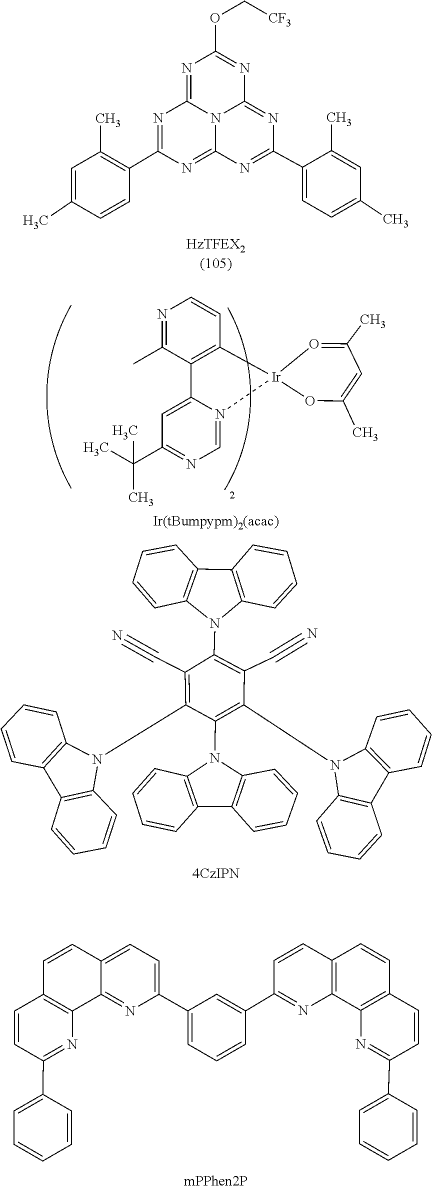

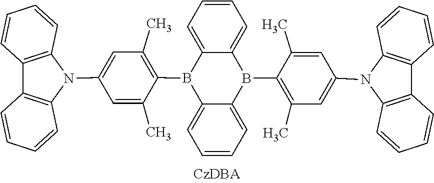 [SMILES: Cc1cc(-n2c3ccccc3c3ccccc32)cc(C)c1B1c2ccccc2B(c2c(C)cc(-n3c4ccccc4c4ccccc43)cc2C)c2ccccc21]

TABLE 1

| | | |
|---|---|---|
| | Light- | Light- |
| | emitting | emitting |
| Thickness | device 1 | device 2 |

| Second electrode | | 200 nm | Al |
|---|---|---|---|
| Electron-injection layer | | 1 nm | LiF |
| Electron- | 2 | 30 nm | mPPhen2P |
| transport | 1 | 10 nm | PPF |
| layer | | | |

| | | | |
|---|---|---|---|
| Light-emitting layer | 15 nm | HzTFEX₂:PPO27:4CzIPN | HzTFEX₂:PPO27:CzDBA |
| | | (0.05:0.95:0.10) | (0.05:0.95:0.10) |

| | | | |
|---|---|---|---|
| Hole- | 2 | 10 nm | CzSi |
| transport | 1 | — | BBABnf (40 nm) |
| layer | | | |

| | | |
|---|---|---|
| Hole-injection layer | 10 nm | BBABnf:p-dopant (1:0.1) |
| First electrode | 70 nm | ITSO |

| | | | Comparative |
|---|---|---|---|
| | | Light- | light- |
| | | emitting | emitting |
| | | device 3 | device 4 |
| Second electrode | | Al | |
| Electron-injection layer | | LiF | |
| Electron- | 2 | mPPhen2P | |
| transport | 1 | PPF | |
| layer | | | |
| Light-emitting layer | | HzTFEX₂:PPO27:Ir(tBumpypm)₂(acac) | HzTFEX₂:PPO27 |
| | | (0.05:0.95:0.10) | (0.05:0.95) |
| Hole- | 2 | CzSi | |
| transport | 1 | BBABnf (40 nm) | BBABnf (25 nm) |
| layer | | | |

| | |
|---|---|
| Hole-injection layer | BBABnf:p-dopant (1:0.1) |
| First electrode | ITSO |

### <<Fabrication of Light-Emitting Device 1>>

The light-emitting device 1 described in this example has a structure in which a hole-injection layer, a hole-transport layer (a first hole-transport layer and a second hole-transport layer), a light-emitting layer, an electron-transport layer (a first electron-transport layer and a second electron-transport layer), and an electron-injection layer are stacked sequentially over a first electrode formed over a substrate, and a second electrode is stacked over the electron-injection layer.

First, the first electrode was formed over the substrate. The electrode area was set to 4 mm² (2 mm×2 mm). A glass substrate was used as the substrate. As the first electrode, an indium tin oxide containing silicon oxide (ITSO) was deposited to a thickness of 70 nm by a sputtering method. In this example, the first electrode serves as an anode.

For pretreatment, a surface of the substrate was washed with water, baking was performed at 200° C. for one hour, and then UV ozone treatment was performed for 370 seconds. After that, the substrate was transferred into a vacuum evaporation apparatus where the pressure had been reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the hole-injection layer was formed over the first electrode. The hole-injection layer was deposited to a thickness of 10 nm by co-evaporation of N,N-bis(4-biphenyl)-6-phenylbenzo[b]naphtho[1,2-d]furan-8-amine (abbreviation: BBABnf) and an electron acceptor material containing fluorine with a molecular weight of 672 (OCHD-003) at a weight ratio of 1:0.1 (=BBABnf: OCHD-003).

Then, the hole-transport layer was formed over the hole-injection layer. BBABnf was deposited to a thickness of 40 nm as the first hole-transport layer and then, 9-(4-tert-butylphenyl)-3,4-bis(triphenylsilyl)-9H-carbazole (abbreviation: CzSi) was deposited to a thickness of 10 nm as the second hole-transport layer.

Next, the light-emitting layer was formed over the hole-transport layer. The light-emitting layer was formed to a thickness of 15 nm by co-evaporation of HzTFEX₂ as the first substance and 2,7-bis(diphenylphosphoryl)-9-phenyl-9H-carbazole (abbreviation: PPO27) as the second substance, and 2,4,5,6-tetrakis(9H-carbazol-9-yl) benzene-1,3-dicarbonitrile (abbreviation: 4CzIPN) as the light-emitting substance at the weight ratio of 0.05:0.95:0.10 (=HzTFEX₂:PPO27:4CzIPN).

After that, the electron-transport layer was formed over the light-emitting layer. 2,8-bis(diphenylphosphoryl)dibenzo[b,d]furan (abbreviation: PPF) was deposited to a thickness of 10 nm as the first electron-transport layer and then, 2,2′-(1,3-phenylene)bis(9-phenyl-1,10-phenanthroline) (abbreviation: mPPhen2P) was deposited to a thickness of 30 nm as the second electron-transport layer.

Then, the electron-injection layer was formed over the electron-transport layer. The electron-injection layer was deposited to a thickness of 1 nm by evaporation of lithium fluoride (LiF).

Next, the second electrode was formed over the electron-injection layer. The second electrode was deposited to a thickness of 200 nm by evaporation of aluminum (Al). In this example, the second electrode serves as a cathode.

Through the above process, the light-emitting device 1 was fabricated. Next, methods for fabricating the light-emitting devices 2 and 3 and the comparative light-emitting device 4 are described.

### <<Fabrication of Light-Emitting Device 2>>

The light-emitting device 2 was fabricated in the same manner as the light-emitting device 1, except that 4CzIPN used as the light-emitting substance of the light-emitting layer in the light-emitting device 1 was replaced with 9,10-bis(4-(9H-carbazol-9-yl)-2,6-dimethylphenyl)-9,10-diboraanthracene (abbreviation: CzDBA).

### <<Fabrication of Light-Emitting Device 3>>

The light-emitting device 3 was fabricated in the same manner as the light-emitting device 1, except that 4CzIPN used as the light-emitting substance of the light-emitting layer in the light-emitting device 1 was replaced with bis[2-(6-tert-butyl-4-pyrimidinyl-κN3)-3-methylpyridinyl-κC](2,4-pentadionato-κ²O,O′)iridium(III) (abbreviation: Ir(tBumpypm)₂(acac)).

### <<Fabrication of Comparative Light-Emitting Device 4>>

The comparative light-emitting device 4 is a light-emitting device in which HzTFEX₂ was used as a light-emitting substance in the light-emitting layer. Specifically, the light-emitting layer of the comparative light-emitting device 4 was deposited to a thickness of 15 nm by co-evaporation of HzTFEX₂ and PPO27 at a weight ratio of 0.05:0.95 (=HzTFEX₂:PPO27). The first hole-transport layer of the comparative light-emitting device 4 was formed to a thickness of 25 nm. The other components were fabricated in a manner similar to those of the light-emitting device 1.

This fabricated light-emitting devices each were sealed using a glass substrate in a glove box containing a nitrogen atmosphere so as not to be exposed to the air (a sealing material was applied to surround the device and UV treatment and heat treatment at 80° C. for 1 hour were performed at the time of sealing). Then, the initial characteristics of the light-emitting device 1 were measured.

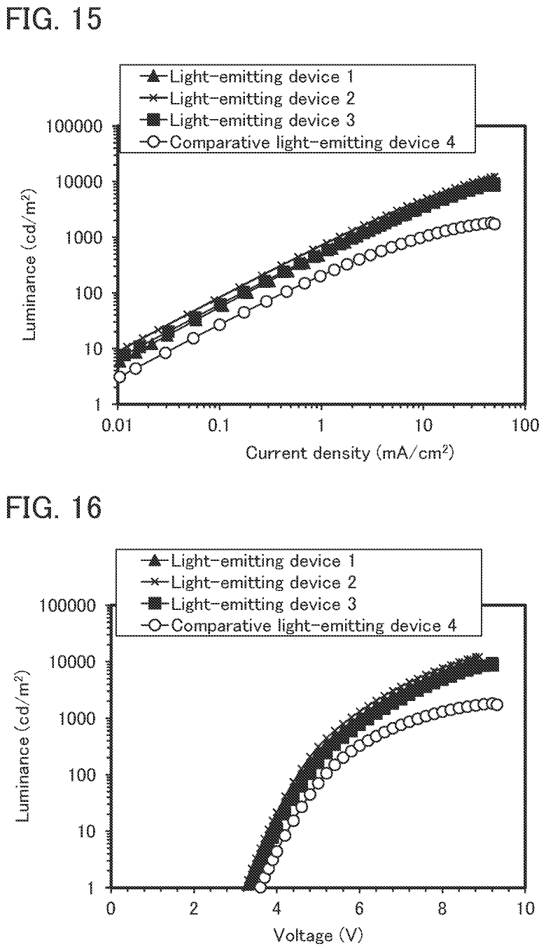

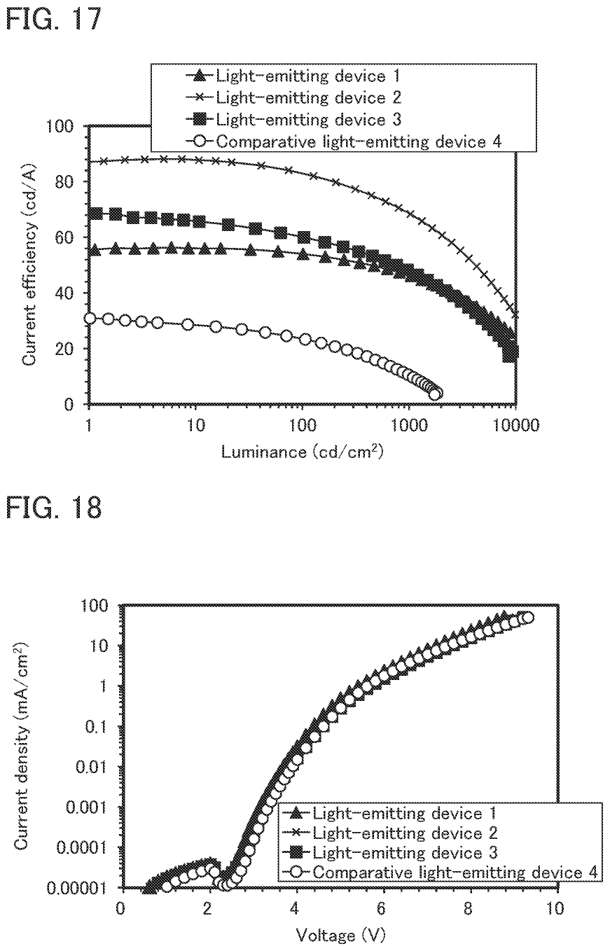

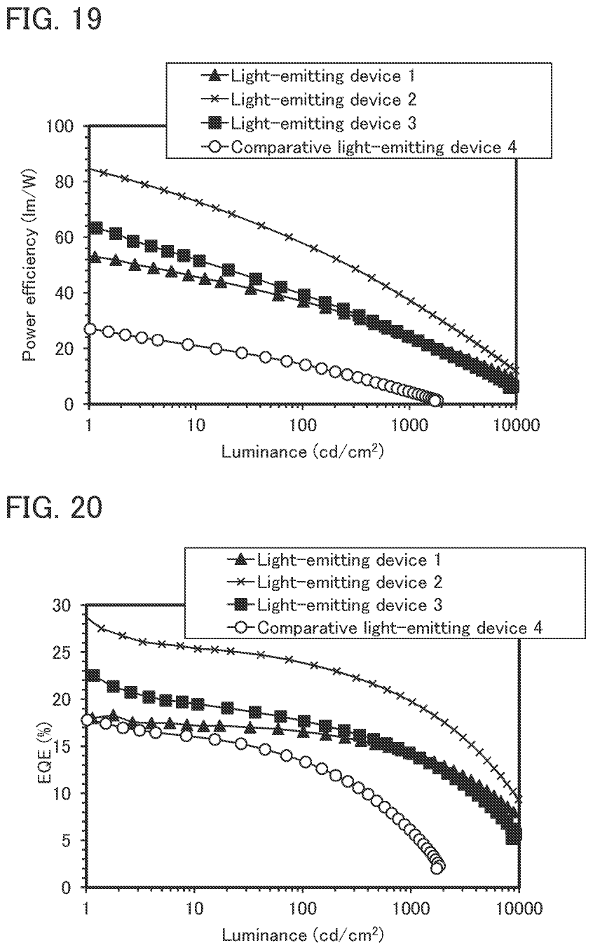

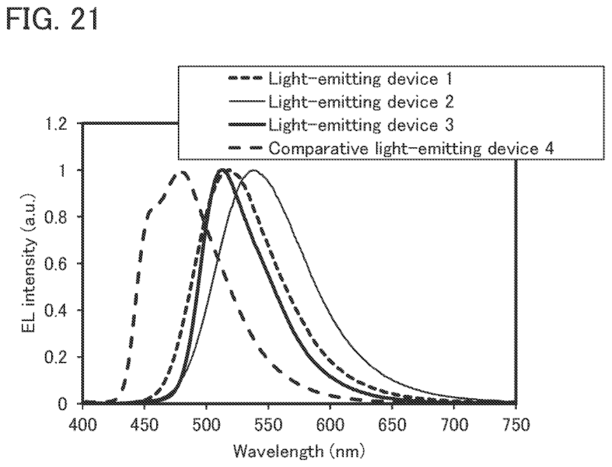

Various characteristics of the light-emitting devices 1 to 3 and the comparative light-emitting device 4 are shown as follows: FIG. 15 shows luminance-current density characteristics, FIG. 16 shows luminance-voltage characteristics, FIG. 17 shows current efficiency-luminance characteristics, FIG. 18 shows current density-voltage characteristics, FIG. 19 shows power efficiency-luminance, FIG. 20 shows external quantum efficiency-luminance characteristics, and FIG. 21 shows electroluminescence spectra in the case where current flows at a current density of 2.5 mA/cm².

Table 2 shows the main characteristics of the light-emitting devices 1 to 3 and the comparative light-emitting device 4 at a luminance of about 1000 cd/m². The luminance, CIE chromaticity, and electroluminescence spectra were measured at normal temperature with a spectroradiometer (SR-UL1R, TOPCON TECHNOHOUSE CORPORATION). The external quantum efficiency was calculated from the luminance and the electroluminescence spectrum measured with the spectroradiometer, on the assumption that the device had Lambertian light-distribution characteristics.

TABLE 2

| | | | Current | | | | Current | Power | |
|---|---|---|---|---|---|---|---|---|---|
| | Voltage | Current | density | Chromaticity | Chromaticity | Luminance | efficiency | efficiency | EQE |
| | (V) | (mA) | (mA/cm²) | x | y | (cd/m²) | (cd/A) | (lm/W) | (%) |
| Light-emitting | 6.0 | 0.090 | 2.3 | 0.27 | 0.59 | 1042 | 46 | 24 | 14 |
| device 1 | | | | | | | | | |
| Light-emitting | 5.8 | 0.060 | 1.5 | 0.36 | 0.59 | 1032 | 68 | 37 | 20 |
| device 2 | | | | | | | | | |
| Light-emitting | 6.2 | 0.080 | 2.0 | 0.25 | 0.63 | 966 | 48 | 24 | 14 |
| device 3 | | | | | | | | | |
| Comparative | 7.4 | 0.37 | 9.3 | 0.15 | 0.25 | 979 | 11 | 4.5 | 6.1 |
| light-emitting | | | | | | | | | |
| device 4 | | | | | | | | | |

As can be seen from FIG. 15 to FIG. 21, and Table 2, the light-emitting devices 1 to 3 each emit green light originating from 4CzIPN, CzDBA, and Ir(tBumpypm)₂(acac), respectively, serving as the light-emitting substances, and have favorable emission characteristics. On the other hand, the comparative light-emitting device 4 emits blue light originating from HzTFEX₂.

As compared with the comparative light-emitting device 4, the light-emitting devices 1 to 3 have high luminance at the same voltage (see FIG. 16), high luminance at the same current density (see FIG. 15), and high current efficiency, high power efficiency, and high external quantum efficiency (EQE), which are indicators of emission efficiency, at the same luminance (see FIGS. 17, 19, and 20).

The light-emitting devices 1 to 3 have higher EQE than the comparative light-emitting device 4, which indicates that HzTFEX₂ is preferably used as the first substance rather than as the light-emitting substance to increase EQE of the light-emitting devices.

The peak wavelengths and full width at half maximum (FWHM) of the light-emitting devices 1 to 3 and the comparative light-emitting device 4 are shown in Table 3.

TABLE 3

| | Peak wavelength | FWHM | FWHM |
|---|---|---|---|
| | (nm) | (nm) | (eV) |
| Light-emitting | 519 | 76 | 0.34 |
| device 1 | | | |
| Light-emitting | 538 | 85 | 0.36 |
| device 2 | | | |
| Light-emitting | 513 | 61 | 0.28 |
| device 3 | | | |
| Comparative light- | 477 | 74 | 0.40 |
| emitting device 4 | | | |

As can be seen from Table 3, FWHM (eV) of each of the light-emitting devices 1 to 3 is lower than FWHM (eV) of the comparative light-emitting device 4, which indicates that the light-emitting devices 1 to 3 exhibit higher color purity than the comparative light-emitting device 4.

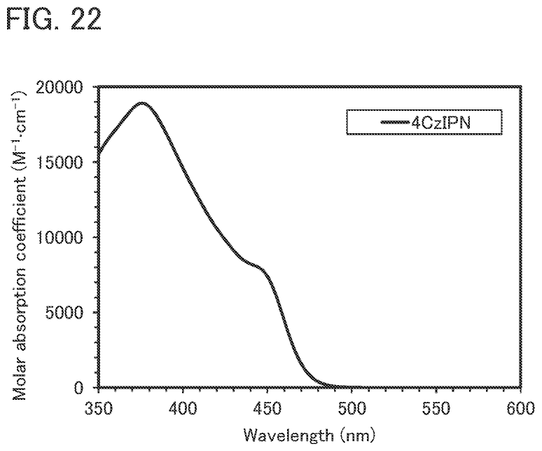

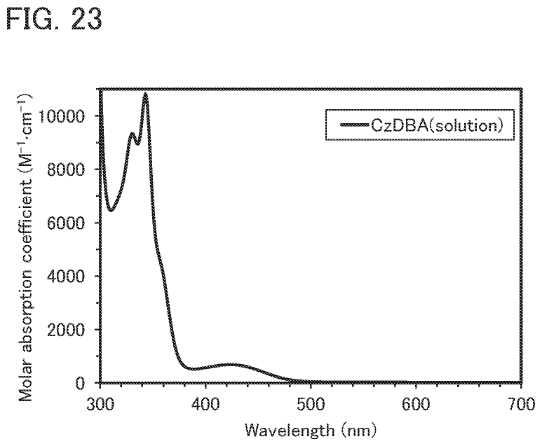

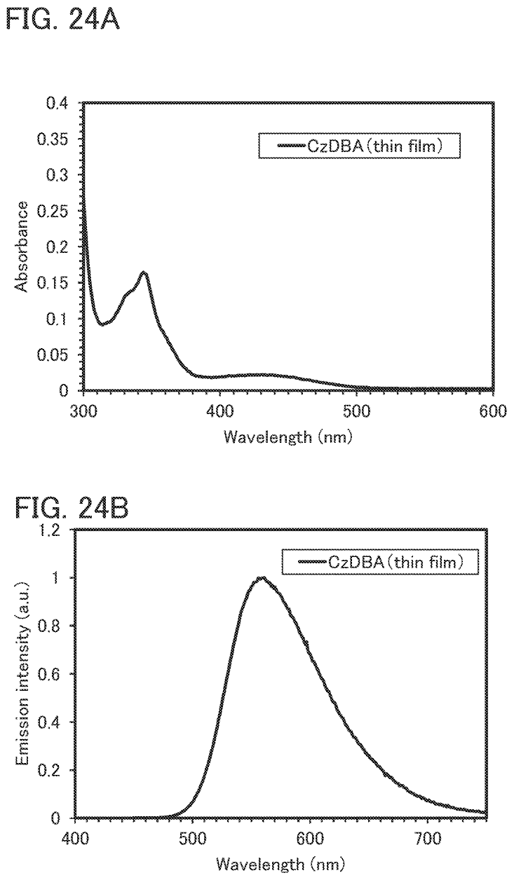

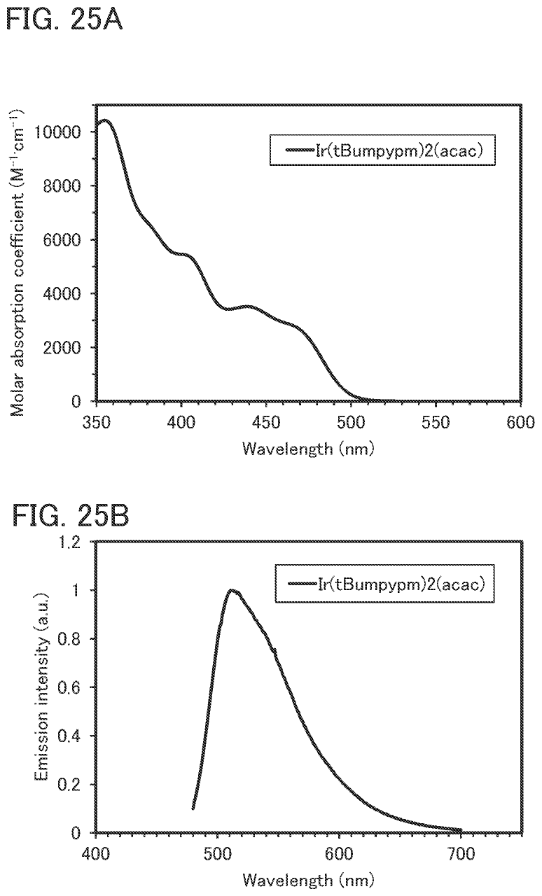

FIG. 22 shows an absorption spectrum of 4CzIPN in a toluene solution which is a light-emitting substance used for the light-emitting device 1. FIG. 23 shows an absorption spectrum of CzDBA in a toluene solution, which is a light-emitting substance used for the light-emitting device 2, and FIGS. 24A and 24B show respectively an absorption spectrum and an emission spectrum of CzDBA in a thin film state. FIGS. 25A and 25B show respectively an absorption spectrum and an emission spectrum of Ir(tBumpypm)₂(acac) in a dichloromethane solution, which is a light-emitting substance used in the light-emitting device 3.

The solid thin film was formed over a quartz substrate by a vacuum evaporation method. FIG. 22, FIG. 23, and FIG. 24A show the absorption spectra in solution states, which were each obtained by subtracting the measured absorption spectrum of only a solvent put in a quartz cell from the measured absorption spectrum of the solution with each sample put in a quartz cell. The emission spectra of the solution were measured with a fluorescence spectrophotometer (FS920, Hamamatsu Photonics K.K.). The absorption spectra of the solution were measured with a UV-visible spectrophotometer (V-550, JASCO Corporation). The absorption spectra in film states were measured with a UV-visible spectrophotometer (U-4100, Hitachi)., and the emission spectra were measured with the fluorescence spectrophotometer (FS920, Hamamatsu Photonics K.K.).

As shown in FIG. 22, the absorption edge of 4CzIPN is 473 nm, and the S₁ level of 4CzIPN is calculated to be 2.62 eV. The absorption edge is calculated as the intersection of the base line and a tangent at a point at which the negative slope of the spectrum has a maximum absolute value on the long wavelength side of the longest-wavelength peak or shoulder peak of the absorption spectrum. It is found that the molar absorption coefficient at the maximum peak wavelength of the longest-wavelength absorption band of 4CzIPN is as high as 8000 M⁻¹·cm⁻¹, which is 1000 M⁻¹·cm⁻¹ or higher. As shown in FIG. 23, the absorption edge of CzDBA is 485 nm, and the S₁ level of CzDBA is calculated to be 2.57 eV. In addition, the molar absorption coefficient of the maximum peak wavelength in the longest-wavelength absorption band of CzDBA is as high as 690 M⁻¹·cm⁻¹, which is 500 M⁻¹·cm⁻¹ or higher. As shown in FIG. 25A, the absorption edge of Ir(tBumpypm)₂(acac) is 497 nm. Ir(tBumpypm)₂(acac) is a phosphorescent material and has an absorption band of a triplet Metal to Ligand Charge Transfer (MLCT) transition. Accordingly, the T₁ level of Ir(tBumpypm)₂(acac) is calculated to be 2.49 eV. Furthermore, the molar absorption coefficient of the maximum peak wavelength of the longest-wavelength absorption band of Ir(tBumpypm)₂(acac) is as high as 2800 M⁻¹·cm⁻¹, which is 1000 M⁻¹·cm⁻¹ or higher. Since the molar absorption coefficient of the maximum peak wavelength of the longest-wavelength absorption band of the light-emitting substance is high, energy is efficiently transferred from the first substance and the second substance to the light-emitting substance in each of the light-emitting devices 1 to 3, whereby the light-emitting devices 1 to 3 can exhibit high efficiency.

As shown in FIG. 24B, the emission edge of the fluorescent spectrum of CzDBA is 504 nm, and the S₁ level of CzDBA is calculated to be 2.46 eV. Furthermore, as shown in FIG. 24B, the peak wavelength of the fluorescent spectrum of CzDBA is 561 nm (excitation wavelength: 440 nm) and FWHM of the fluorescent spectrum of CzDBA is 93 nm and 0.35 eV. As shown in FIG. 25B, the emission edge of the phosphorescent spectrum of Ir(tBumpypm)₂(acac) is 481 nm, and the T₁ level of the phosphorescent spectrum of Ir(tBumpypm)₂(acac) is calculated to be 2.58 eV. In addition, FWHM of the phosphorescent spectrum of Ir(tBumpypm)₂(acac) is 74 nm and 0.33 eV. The emission edge is calculated as the intersection of the base line and a tangent at a point at which the slope of the spectrum has a maximum value on the shorter wavelength side of the shortest-wavelength peak or shoulder peak of the fluorescent spectrum and the phosphorescent spectrum.

The luminescence quantum yield of 4CzIPN in a toluene solution was measured at room temperature with the use of an absolute PL quantum yield measurement system (C11347-01, Hamamatsu Photonics K. K.). The luminescence quantum yield of 4CzIPN excited by light with a wavelength of 400 nm was 71%, which is 60% or higher. The luminescence quantum yield of CzDBA in a toluene solution excited by light with a wavelength of 450 nm was 89%, which is 60% or higher. Moreover, the luminescence quantum yield of Ir(tBumpypm)₂(acac) in a toluene solution excited by light with a wavelength of 380 nm was 84%, which is 60% or higher.

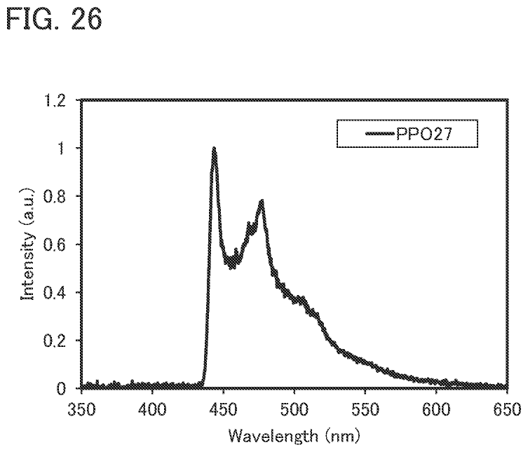

FIG. 26 shows a measurement result of a phosphorescence (PL) spectrum at a low temperature (10K) of PPO27 used as the second substance in the light-emitting devices 1 to 3. The PL spectrum measurement was performed on a thin film (a deposited film with a thickness of 50 nm) of PPO27 with a microscope PL spectrometer, LabRAM HR-PL (HORIBA Scientific). The wavelength (or energy) of an emission edge of the phosphorescence spectrum can be the intersection of the base line and a tangent at the point where the slope of the spectrum has a maximum value on the short wavelength side of the shortest-wavelength peak of the phosphorescent spectrum, and the T₁ level can be calculated from the wavelength of the emission edge.

As a result, the emission edge on the short wavelength side of the PL spectrum of PPO27 is 437 nm and the T₁ level of PPO27 is calculated to be 2.84 eV. PPO27 has a high T₁ level and is preferable as the second substance.

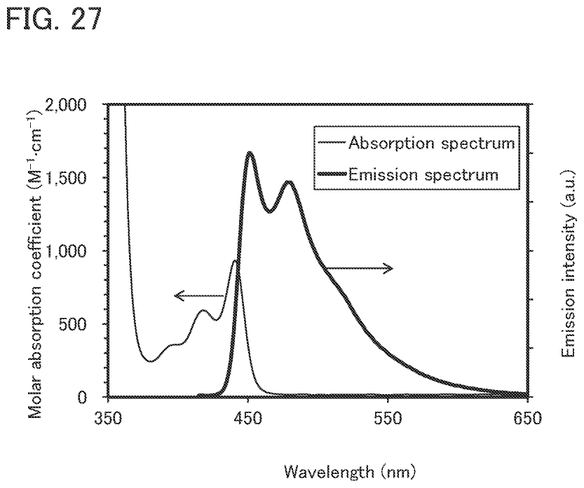

FIG. 27 show measurement results of an absorption spectrum and an emission spectrum of HzTFEX₂ in a toluene solution at room temperature. The absorption spectrum and the emission spectrum were measured with use of a fluorescence spectrophotometer (FP-8600, JASCO Corporation) and a UV-visible spectrophotometer (V-770DS, JASCO Corporation), respectively. The absorption spectrum was obtained by subtracting the measured absorption spectrum of only toluene put in a quartz cell from the measured absorption spectrum of the toluene solution with HzTFEX₂ put in a quartz cell.

As apparent from FIG. 27, the emission edge at the short wavelength side of HzTFEX₂ is 437 nm, and the S₁ level thereof is estimated to be 2.83 eV, which is higher than the S₁ level (2.62 eV) calculated from the absorption edge of 4CzIPN and the S₁ level (2.57 eV) calculated from the absorption edge of CzDBA and the S₁ level (2.46 eV) calculated from the emission edge of CzDBA, which is preferable. According to Non-Patent Document 2, ΔE_{ST} is −11 meV, and the T₁ level of HzTFEX₂ is estimated to be 2.84 eV, which is higher than the T₁ level (2.49 eV) calculated from the adsorption edge of Ir(tBumpypm)₂(acac) and the T₁ level (2.58 eV) calculated from the emission edge of Ir(tBumpypm)₂(acac), which is preferable. Therefore, HzTFEX₂ is preferably used as the first substance. It is found that FWHM of the fluorescent spectrum of HzTFEX₂ is 65 nm and 0.36 eV.

These results indicate that in the light-emitting devices 1 to 3, the S₁ level and the T₁ level of the first substance are higher than the S₁ level and the T₁ level of the corresponding light-emitting substances, whereby the singlet excitation energy and the triplet excitation energy of the first substance can be transferred efficiently to the light-emitting substances, so that the light-emitting substances can emit light.

The above results show that the light-emitting devices of one embodiment of the present invention have high efficiency and exhibit favorable color purity.

### Example 2

In this example, a light-emitting device 5, which is a light-emitting device of one embodiment of the present invention, and comparative light-emitting devices 6 and 7 were fabricated, and various kinds of measurements were performed in this example. The measurement results are described. Note that as the first substance included in the light-emitting layer of the light-emitting device 5, HzTFEX₂, which is a NEST material, was used. HzTFEX₂ was also used as a light-emitting substance included in the light-emitting layer of the comparative light-emitting device 6. HzTFEX₂ is a NEST material, and thus, the delayed fluorescence lifetime of HzTFEX₂ becomes shorter as the temperature decreases in the range of 10 K to 300 K, inclusive (see Non-Patent Document 2).

Structural formulas of organic compounds used for each of the light-emitting devices are shown below. The device structures of the light-emitting devices are shown below.

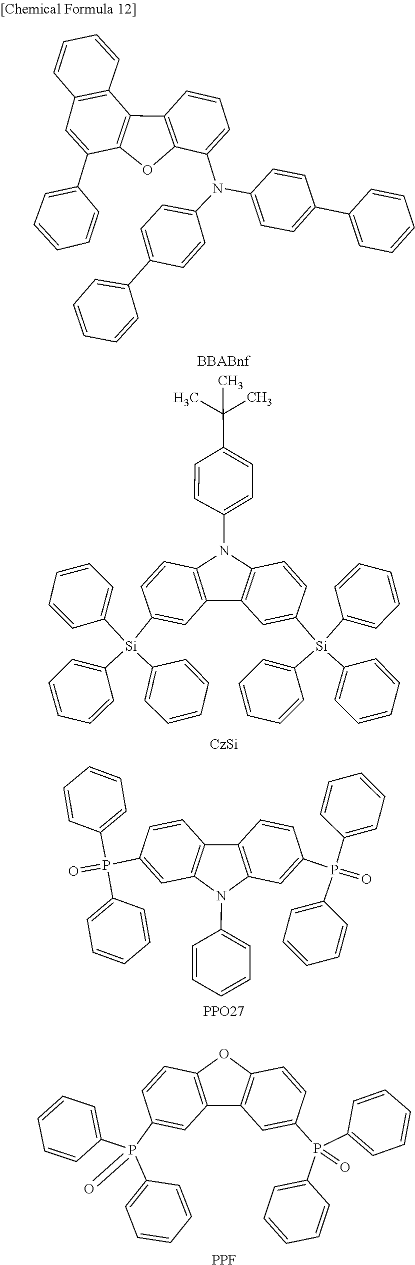

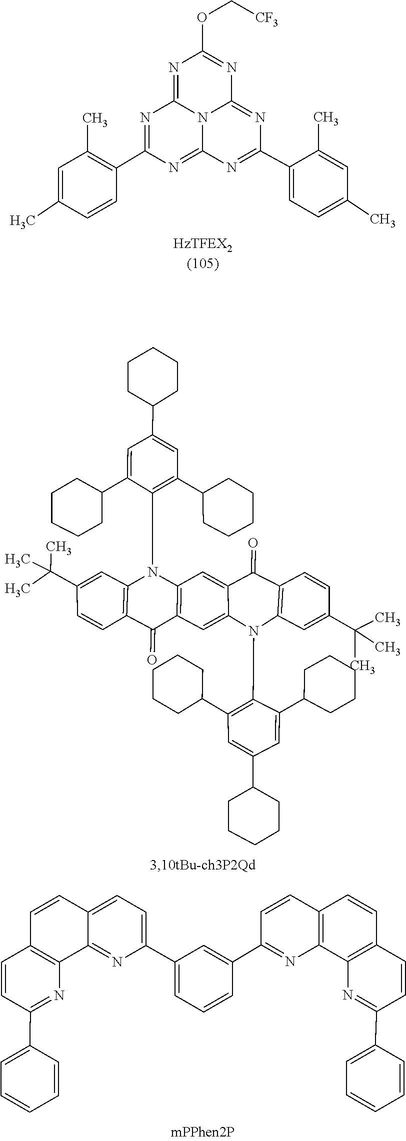

TABLE 4

| | | | |
|---|---|---|---|
| | Light-emitting | Comparative light- | Comparative light- |
| Thickness | device 5 | emitting device 6 | emitting device 7 |

| Second electrode | | 200 nm | Al |
|---|---|---|---|
| Electron-injection layer | | 1 nm | LiF |
| Electron-transport | 2 | 30 nm | mPPhen2P |
| layer | 1 | 10 nm | PPF |

| | | | | |
|---|---|---|---|---|
| Light-emitting layer | 15 nm | HzTFEX₂:PPO27:3,10tBu- | PPO27:HzTFEX₂ | PPO27:3,10tBu- |

| | | |
|---|---|---|
| ch3P2Qd | (0.95:0.05) | ch3P2Qd |
| (0.05:0.95:0.025) | | (1:0.025) |

| | | | |
|---|---|---|---|
| Hole-transport | 2 | 10 nm | CzSi |
| layer | 1 | 40 nm | BBABnf |

| | | |
|---|---|---|
| Hole-injection layer | 10 nm | BBABnf:p-dopant (1:0.1) |
| First electrode | 70 nm | ITSO |

### <<Fabrication of Light-Emitting Device 5>>

The light-emitting device 5 was fabricated in the same manner as the light-emitting device 1, except that 4CzIPN used as the light-emitting substance in the light-emitting layer of the light-emitting device 1 was replaced with 3,10-di-tert-butyl-5,12-bis(2,4,6-tricyclohexylphenyl)-5,12-dihydroquino[2,3-b]acridine-7,14-dione (abbreviation: 3,10tBu-ch3P2Qd). That is, HzTFEX₂ was used as the first substance, PPO27 was used as the second substance, and 3,10tBu-ch3P2Qd was used as the light-emitting substance.

### <<Fabrication of Comparative Light-Emitting Device 6>>

In the comparative light-emitting device 6, HzTFEX₂ is used as a light-emitting substance of a light-emitting layer. Specifically, the light-emitting layer of the comparative light-emitting device 6 was deposited to a thickness of 15 nm by co-evaporation of PPO27 and HzTFEX₂ at a weight ratio of 0.95:0.05 (=PPO27:HzTFEX₂). The other components were fabricated in a manner similar to those of the light-emitting device 1.

### <<Fabrication of Comparative Light-Emitting Device 7>>

In the comparative light-emitting device 7, HzTFEX₂ is not included in the light-emitting layer, and as in the light-emitting device 5, 3,10tBu-ch3P2Qd is used as a light-emitting substance in the light-emitting layer. Specifically, the light-emitting layer of the comparative light-emitting device 7 was deposited to a thickness of 15 nm by co-evaporation of PPO27 and 3,10tBu-ch3P2Qd at a weight ratio of 1:0.025 (=PPO27:3,10tBu-ch3P2Qd). The other components were fabricated in a manner similar to those of the light-emitting device 1.

This fabricated light-emitting devices each were sealed using a glass substrate in a glove box containing a nitrogen atmosphere so as not to be exposed to the air (a sealing material was applied to surround the device and UV treatment and heat treatment at 80° C. for 1 hour were performed at the time of sealing). Then, the initial characteristics of the light-emitting devices were measured.

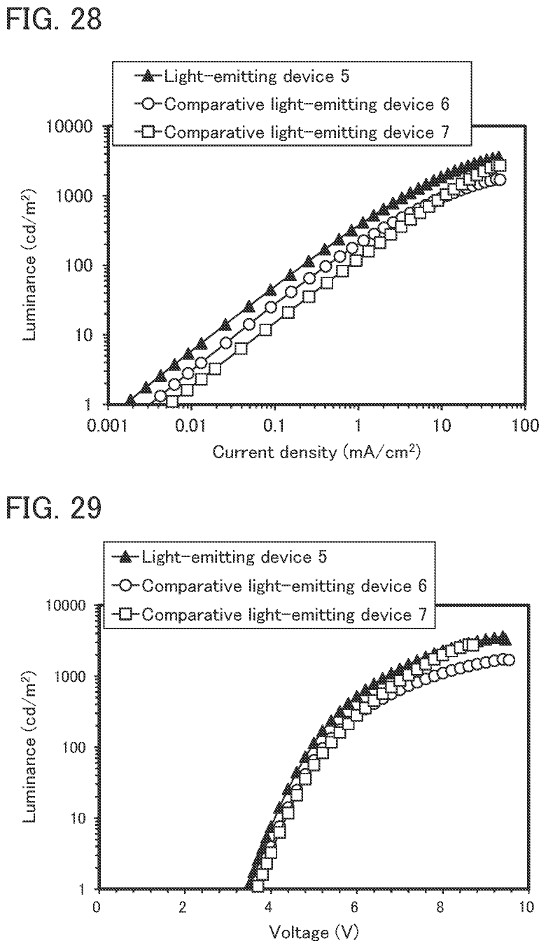

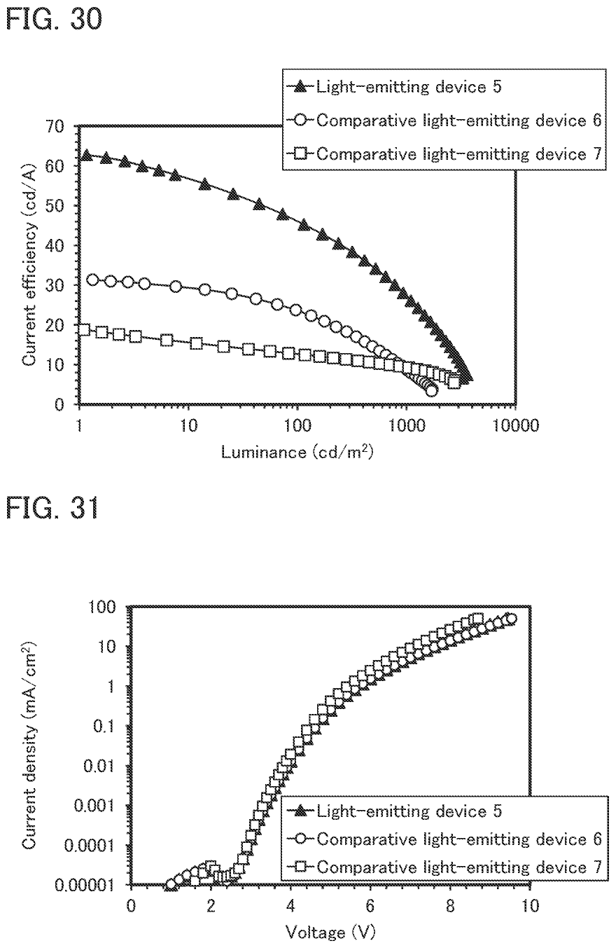

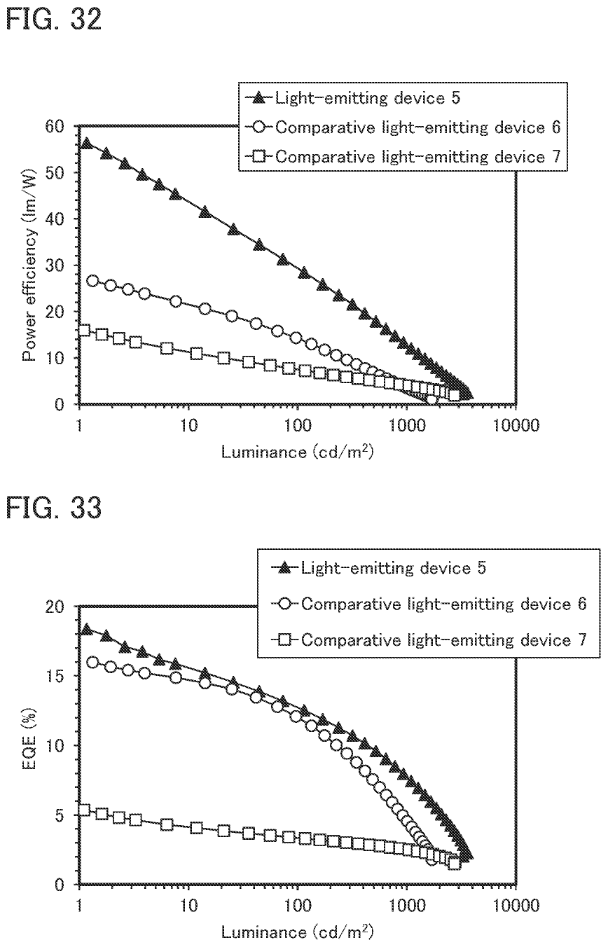

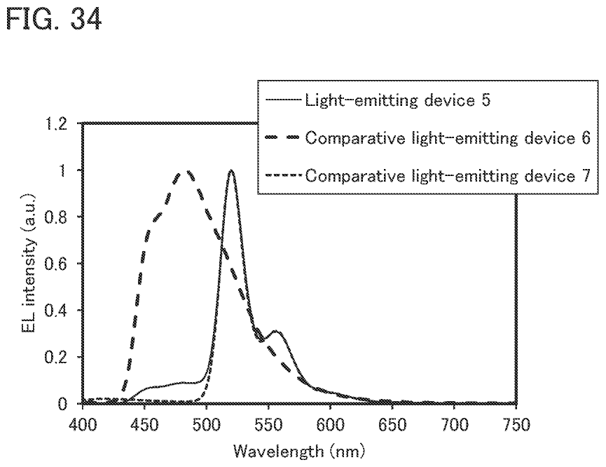

Various characteristics of the light-emitting device 5 and the comparative light-emitting devices 6 and 7 are shown as follows: FIG. 28 shows luminance-current density characteristics, FIG. 29 shows luminance-voltage characteristics, FIG. 30 shows current efficiency-luminance characteristics, FIG. 31 shows current density-voltage characteristics, FIG. 32 shows power efficiency-luminance, FIG. 33 shows external quantum efficiency-luminance characteristics, and FIG. 34 shows electroluminescence spectra in the case where current flows at a current density of 2.5 mA/cm².

Table 5 shows the main characteristics of the light-emitting device 5, and the comparative light-emitting devices 6 and 7 at a luminance of about 1000 cd/m². The luminance, CIE chromaticity, and electroluminescence spectra were measured at normal temperature with a spectroradiometer (SR-UL1R, TOPCON TECHNOHOUSE CORPORATION). The external quantum efficiency was calculated from the luminance and the electroluminescence spectrum measured with the spectroradiometer, on the assumption that the device had Lambertian light-distribution characteristics.

TABLE 5

| | | | Current | | | | Current | Power | |
|---|---|---|---|---|---|---|---|---|---|
| | Voltage | Current | density | Chromaticity | Chromaticity | Luminance | efficiency | efficiency | EQE |
| | (V) | (mA) | (mA/cm²) | x | y | (cd/m²) | (cd/A) | (lm/W) | (%) |
| Light-emitting | 6.6 | 0.13 | 3.3 | 0.23 | 0.61 | 932 | 28.0 | 13.3 | 8.0 |
| device 5 | | | | | | | | | |
| Comparative light- | 7.8 | 0.46 | 11.6 | 0.16 | 0.28 | 1009 | 8.7 | 3.5 | 4.5 |
| emitting device 6 | | | | | | | | | |
| Comparative light- | 7.2 | 0.45 | 11.2 | 0.24 | 0.67 | 1044 | 9.3 | 4.0 | 2.5 |
| emitting device 7 | | | | | | | | | |

As can be seen from FIG. 28 to FIG. 34, and Table 5, the light-emitting device emits green light originating from 3,10tBu-ch3P2Qd serving as the light-emitting substance, and has favorable emission characteristics. In addition, the comparative light-emitting device 6 emits blue light originating from HzTFEX₂. The comparative light-emitting device 7 emits green light originating from 3,10tBu-ch3P2Qd.

Moreover, as compared with the comparative light-emitting devices 6 and 7, the light-emitting device 5 has high luminance at the same current density (see FIG. 28) and high luminance, and high current efficiency, high power efficiency, and high external quantum efficiency, which are indicators of emission efficiency, at the same luminance (see FIGS. 30, 32 and 33).

Since the external quantum efficiency (EQE) of the light-emitting device 5 is higher than that of the comparative light-emitting device 6, the light-emitting device 5 can have high external quantum efficiency by using HzTFEX₂ as the first substance rather than as the light-emitting substance.

The comparative light-emitting device 7 is a general fluorescent light-emitting device that does not include a NEST material as a host (an energy donor or the first substance). The light-emitting device 5 has a higher external quantum efficiency than the comparative light-emitting device 7. The light-emitting device 5 shows the external quantum efficiency exceeding 7.0%, which is higher than that of general fluorescent light-emitting devices (for example, the maximum external quantum efficiency of 7.0% is obtained by the formula: PL emission efficiency of a light-emitting substance, 93%, ×the proportion of generated singlet excitons, 25%, ×carrier balance factor, 100%, ×light extraction efficiency, 30%). The high external quantum efficiency was obtained because the triplet excitation energy of HzTFEX₂ serving as the NEST material was converted to a singlet excitation energy and transferred to the light-emitting substance.

The peak wavelengths and FWHM of the light-emitting device 5 and the comparative light-emitting devices 6 and 7 are shown in Table 6.

TABLE 6

| | Peak wavelength | FWHM | FWHM |
|---|---|---|---|
| | (nm) | (nm) | (eV) |
| Light-emitting | 520 | 23 | 0.10 |
| device 5 | | | |
| Comparative light- | 482 | 80 | 0.42 |
| emitting device 6 | | | |
| Comparative light- | 520 | 23 | 0.10 |
| emitting device 7 | | | |

As can be seen from Table 6, FWHM (eV) of the light-emitting device 5 is lower than FWHM (eV) of the comparative light-emitting device 6, which indicates that the light-emitting device 5 exhibits higher color purity than the comparative light-emitting device 6.

As can be seen from Table 6, the peak wavelength and FWHM of the light-emitting device 5 are similar to those of the comparative light-emitting device 7. As described above, the light-emitting device 5 has higher luminance at the same current density and higher emission efficiency at the same luminance than the comparative light-emitting device 7. Here, the light-emitting device 5 is different from the comparative light-emitting device 7, in that HzTFEX₂ is used for the light-emitting layer as the first substance (energy donor). Accordingly, it is found that in the light-emitting device 5, light can be emitted from the light-emitting substance at high luminance and with high efficiency, as a result of the use of HzTFEX₂ as the light-emitting layer.

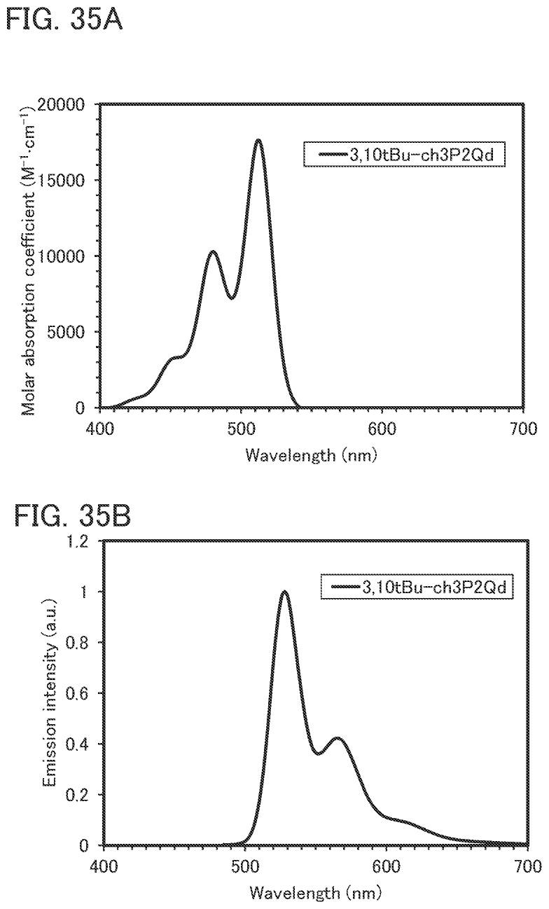

FIGS. 35A and 35B show respectively an absorption spectrum and an emission spectrum of 3,10tBu-ch3P2Qd in a dichloromethane solution, which serves as the light-emitting substances used for the light-emitting device 5 and the comparative light-emitting device 7. The emission and absorption spectra were measured by a method similar to that in Example 1.

As shown in FIG. 35A, the absorption edge of 3,10tBu-ch3P2Qd is 531 nm, and the S₁ level is calculated to be 2.34 eV. Note that the absorption edge is the intersection of the base line and a tangent at a point at which the negative slope of the spectrum has a maximum absolute value on the long wavelength side of the longest-wavelength peak or shoulder peak of the absorption spectrum. Furthermore, the molar absorption coefficient in the maximum peak wavelength of the longest-wavelength absorption band of 3,10tBu-ch3P2Qd is as high as 17600 M⁻¹·cm⁻¹, which is 1000 M⁻¹·cm⁻¹ or higher. Since the molar absorption coefficient in the maximum peak wavelength of the longest-wavelength absorption band of 3,10tBu-ch3P2Qd is high, energy is efficiently transferred from the first substance and the second substance to the light-emitting substance in the light-emitting device 5, whereby the light-emitting device 5 can exhibit high efficiency.

As seen in FIG. 35B, the emission edge of the fluorescent spectrum of 3,10tBu-ch3P2Qd is 509 nm and the S₁ level is calculated to be 2.44 eV. In FIG. 35B, it is found that the emission peak of the fluorescent spectrum of 3,10tBu-ch3P2Qd is 528 nm (excitation wavelength: 480 nm) and FWHM is 26 nm (0.11 eV). Note that the emission edge is the intersection of the base line and a tangent at a point at which the slope of the spectrum has a maximum value on the shorter wavelength side of the shortest-wavelength peak or shoulder peak of the fluorescent spectrum.

The luminescence quantum yield of 3,10tBu-ch3P2Qd in a dichloromethane solution was measured at room temperature with the use of an absolute PL quantum yield measurement system (C11347-01, Hamamatsu Photonics K. K.). The luminescence quantum yield of 3,10tBu-ch3P2Qd excited by light with a wavelength of 460 nm was 93%, which is 60% or higher.

As calculated in Example 1, PPO27 exhibits a high T₁ level, 2.84 eV, of the phosphorescent spectrum and thus, is suitable for the second substance. In addition, the S₁ level of HzTFEX₂ is 2.83 eV, which is higher than the S₁ level (2.34 eV) calculated from the absorption edge of 3,10tBu-ch3P2Qd and the S₁ level (2.44 eV) calculated from the emission edge of 3,10tBu-ch3P2Qd, which is preferable.

These results indicate that in the light-emitting device 5, the S₁ level of the first substance is higher than the S₁ level of the light-emitting substance, whereby the singlet excitation energy and the triplet excitation energy of the first substance (HzTFEX₂) can be transferred efficiently to the light-emitting substance, so that the light-emitting substance can emit light.

A change in the luminance of each of the light-emitting device 5 and the comparative light-emitting devices 6 and 7 with respect to driving time in constant current driving at the current density of 10 mA/cm² was measured. The measurement results are shown in Table 7. As a result of the measurement, the time (LT40) at which the luminance reached 40% of the initial luminance of 1900 cd/m² set as 100% was 0.50 hour in the light-emitting device 5, LT40 at which the luminance reached 40% of the initial luminance of 850 cd/m² set as 100% was 0.47 hour in the comparative light-emitting device 6, and LT40 at which the luminance reached 40% of the initial luminance of 860 cd/m² set as 100% was 0.30 hour in the comparative light-emitting device 7.

TABLE 7

| | Initial luminance (cd/m²) | LT40 (h) |
|---|---|---|
| Light-emitting | 1900 | 0.50 |
| device 5 | | |
| Comparative light- | 850 | 0.47 |
| emitting device 6 | | |
| Comparative light- | 860 | 0.30 |
| emitting device 7 | | |

Current density 10 mA/m²

The light-emitting device 5 has a lifetime that is longer than that of the comparative light-emitting device 7 and that is substantially equal to or longer than that of the comparative light-emitting device 6, although the light-emitting device 5 has an initial luminance twice or more those of the comparative light-emitting devices 6 and 7. In other words, it is found that at the same luminance, the light-emitting device 5 has a higher reliability than the comparative light-emitting devices 6 and 7. As compared with the comparative light-emitting device 7 not including the NEST material as a host, the light-emitting device 5 has a long lifetime, for the light-emitting device 5 includes the NEST material as the first substance to obtain light emission from the light-emitting substance. As compared with the comparative light-emitting device 6, the light-emitting device 5 has a narrow FWHM of its electroluminescent spectrum. Thus, in the case of employing a microcavity structure to enhance color purity, a light-emitting substance having a narrow FWHM of an emission spectrum is used and the NEST material is used as the first substance, which can increase a luminance at the same current density, leading to a higher reliability at the same luminance.

The above results show that the light-emitting device of one embodiment of the present invention has high efficiency, high color purity, and high reliability.

This application is based on Japanese Patent Application Serial No. 2022-177394 filed with Japan Patent Office on Nov. 4, 2022, the entire contents of which are hereby incorporated by reference.

What is claimed is:

1. A light-emitting device comprising:
a light-emitting layer between a first electrode and a second electrode,
wherein the light-emitting layer comprises at least a light-emitting substance and a first substance,
wherein a half width of an emission spectrum of the light-emitting substance is 0.35 eV or less,
wherein a luminescence lifetime of delayed fluorescence caused by photoexcitation of the first substance is shorter at a first temperature than at a second temperature,
wherein the first temperature is lower than the second temperature, and
wherein the first temperature and the second temperature are each higher than or equal to 10 K and lower than or equal to 300 K.

2. The light-emitting device according to claim 1,
wherein the half width of the emission spectrum of the light-emitting substance is narrower than a half width of an emission spectrum of the first substance.

3. The light-emitting device according to claim 1,
wherein a luminescence quantum yield of the light-emitting substance is higher than a luminescence quantum yield of the first substance.

4. The light-emitting device according to claim 1,
wherein a luminescence quantum yield of the light-emitting substance is 60% or higher.

5. The light-emitting device according to claim 1,
wherein a Stokes shift of the light-emitting substance is 0.35 eV or less.

6. The light-emitting device according to claim 1,
wherein the light-emitting substance emits fluorescent light and an S₁ level of the first substance is higher than an S₁ level of the light-emitting substance.

7. The light-emitting device according to claim 1,
wherein the first substance is an organic compound comprising an azaphenalene ring.

8. The light-emitting device according to claim 7,
wherein the azaphenalene ring is any one of a pyridoquinolizine ring, a pyrimidoquilolizine ring, a triazaphenalene ring, a tetraazaphenalene ring, a pentaazaphenalene ring, a hexaazaphenalene ring, and a heptaazaphenalene ring.

9. The light-emitting device according to claim 1,
wherein the first substance is an organic compound represented by General Formula (G1), 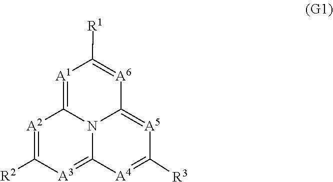
wherein A¹ to A⁶ each independently represent carbon or nitrogen, and A¹ to A⁶ each independently representing carbon are each independently bonded to any one of hydrogen, halogen, an alkyl group having 1 to 10 carbon atoms, a cycloalkyl group having 6 to 10 carbon atoms, a haloalkyl group having 1 to 10 carbon atoms, an alkoxy group having 1 to 10 carbon atoms, a haloalkoxy group having 1 to 10 carbon atoms, and a substituted or unsubstituted aryl group having 6 to 13 carbon atoms, and
wherein R¹ to R³ each independently represent any one of hydrogen, halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 14 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group.

10. A light-emitting device comprising:
a light-emitting layer between a first electrode and a second electrode,
wherein the light-emitting layer comprises at least a light-emitting substance and a first substance,
wherein the light-emitting substance emits phosphorescent light,
wherein a luminescence lifetime of delayed fluorescence caused by photoexcitation of the first substance is shorter at a first temperature than at a second temperature,
wherein the first temperature is lower than the second temperature, and
wherein the first temperature and the second temperature are each higher than or equal to 10 K and lower than or equal to 300 K.

11. The light-emitting device according to claim 10,
wherein a T₁ level of the first substance is higher than a T₁ level of the light-emitting substance.

12. The light-emitting device according to claim 11,
wherein an S₁ level of the first substance is higher than or equal to a T₁ level of the light-emitting substance.

13. The light-emitting device according to claim 10,
wherein the first substance is an organic compound comprising an azaphenalene ring.

14. The light-emitting device according to claim 13,
wherein the azaphenalene ring is any one of a pyridoquinolizine ring, a pyrimidoquilolizine ring, a triazaphenalene ring, a tetraazaphenalene ring, a pentaazaphenalene ring, a hexaazaphenalene ring, and a heptaazaphenalene ring.

15. The light-emitting device according to claim 10,
wherein the first substance is an organic compound represented by General Formula (G1), 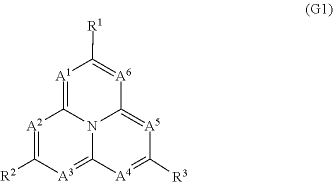
wherein A¹ to A⁶ each independently represent carbon or nitrogen, and A¹ to A⁶ each independently representing carbon are each independently bonded to any one of hydrogen, halogen, an alkyl group having 1 to 10 carbon atoms, a cycloalkyl group having 6 to 10 carbon atoms, a haloalkyl group having 1 to 10 carbon atoms, an alkoxy group having 1 to 10 carbon atoms, a haloalkoxy group having 1 to 10 carbon atoms, and a substituted or unsubstituted aryl group having 6 to 13 carbon atoms, and
wherein R¹ to R³ each independently represent any one of hydrogen, halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 14 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group.

16. A light-emitting device comprising:
a light-emitting layer between a first electrode and a second electrode,
wherein the light-emitting layer comprises at least a light-emitting substance, a first substance, a second substance, and a third substance,
wherein a luminescence lifetime of delayed fluorescence caused by photoexcitation of the first substance becomes shorter as a temperature decreases in a range of 10 K to 300 K, inclusive, and
wherein the second substance and the third substance form an exciplex.

17. The light-emitting device according to claim 16,
wherein a difference between a maximum peak wavelength energy of an emission spectrum of the exciplex and a wavelength energy at an absorption edge of an absorption spectrum of the first substance is less than or equal to 0.20 eV.

18. The light-emitting device according to claim 16,
wherein a difference between a maximum peak wavelength energy of an emission spectrum of the exciplex and a maximum peak wavelength energy of a longest-wavelength absorption band of an absorption spectrum of the first substance is less than or equal to 0.20 eV.

19. The light-emitting device according to claim 16,
wherein an S₁ level of the exciplex is higher than an S₁ level or a T₁ level of the first substance.

20. The light-emitting device according to claim 16,
wherein the first substance is an organic compound comprising an azaphenalene ring.

21. The light-emitting device according to claim 20,
wherein the azaphenalene ring is any one of a pyridoquinolizine ring, a pyrimidoquilolizine ring, a triazaphenalene ring, a tetraazaphenalene ring, a pentaazaphenalene ring, a hexaazaphenalene ring, and a heptaazaphenalene ring.

22. The light-emitting device according to claim 16,
wherein the first substance is an organic compound represented by General Formula (G1), 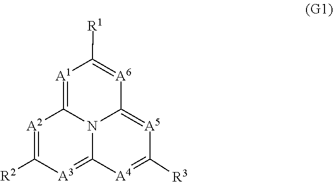
wherein A¹ to A⁶ each independently represent carbon or nitrogen, and A¹ to A⁶ each independently representing carbon are each independently bonded to any one of hydrogen, halogen, an alkyl group having 1 to 10 carbon atoms, a cycloalkyl group having 6 to 10 carbon atoms, a haloalkyl group having 1 to 10 carbon atoms, an alkoxy group having 1 to 10 carbon atoms, a haloalkoxy group having 1 to 10 carbon atoms, and a substituted or unsubstituted aryl group having 6 to 13 carbon atoms, and
wherein R¹ to R³ each independently represent any one of hydrogen, halogen, an alkyl group having 1 to 10 carbon atoms, a haloalkyl group having 1 to 10 carbon atoms, an alkoxy group having 1 to 10 carbon atoms, a haloalkoxy group having 1 to 10 carbon atoms, a substituted or unsubstituted aryloxy group having 6 to 13 carbon atoms, an acyloxy group having 2 to 14 carbon atoms, an alkoxycarbonyl group having 2 to 11 carbon atoms, a haloalkoxycarbonyl group having 2 to 11 carbon atoms, a substituted or unsubstituted aryloxycarbonyl group having 7 to 14 carbon atoms, a substituted or unsubstituted aryl group having 6 to 13 carbon atoms, and a substituted or unsubstituted azaphenalenyl group.
